(19) United States
(12) Patent Application Publication
(10) Pub. No.: US 2026/0006767 A1
(43) Pub. Date: Jan. 1, 2026

(54) SEMICONDUCTOR DEVICE, MEMORY DEVICE, AND ELECTRONIC DEVICE

(71) Applicant: Semiconductor Energy Laboratory Co., Ltd., Atsugi-shi, Kanagawa-ken (JP)

(72) Inventors: Hajime KIMURA, Atsugi (JP); Shunpei YAMAZAKI, Setagaya (JP)

(21) Appl. No.: 19/113,592

(22) PCT Filed: Oct. 2, 2023
(86) PCT No.: PCT/IB2023/059838

§ 371 Date: Mar. 20, 2025

(30) Foreign Application Priority Data
Oct. 7, 2022 (JP) 2022-162397

(51) Int. Cl. H10B 12/00

(52) U.S. Cl. CPC H10B 12/00

(57) ABSTRACT

A semiconductor device having high storage density is provided. The semiconductor device includes a first layer and a second layer above the first layer. The first layer includes first to fourth conductors, first to fifth insulators, and a first semiconductor, and the second layer includes fifth to seventh conductors, sixth and seventh insulators, and a second semiconductor. The first insulator, the second conductor, the second insulator, and the third conductor are formed in this order over the first conductor, and a first opening having a bottom surface of the first conductor is provided in the first insulator, the second insulator, and the third conductor. In the first opening, a first semiconductor, the fourth insulator, and the fourth conductor are formed in this order. The third insulator is positioned on a side surface of the third conductor and a top surface of the second insulator. The fifth conductor is positioned on a top surface of the fourth conductor and a top surface of the fifth insulator. The sixth insulator and the sixth conductor are formed in this order over the fifth conductor, and a second opening with a bottom surface of the fifth conductor is provided in the sixth insulator and the sixth conductor. In the second opening, a second semiconductor, a seventh insulator, and a seventh conductor are formed in this order.

### TECHNICAL FIELD

One embodiment of the present invention relates to a semiconductor device, a storage device, and an electronic device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting apparatus, a power storage device, an imaging device, a memory device, a signal processing device, a sensor, a processor, an electronic device, a system, a driving method thereof, a manufacturing method thereof, and a testing method thereof.

### BACKGROUND ART

In recent years, the amount of data subjected to processing has been increasing, which makes a demand for a memory device having a higher memory capacity. To increase memory capacity per unit area, stacking memory cells as in the case of a 3D NAND memory device or the like is effective (see Patent Document 1 to Patent Document 3). Stacking memory cells can increase memory capacity per unit area in accordance with the number of stacked memory cells.

### REFERENCES

### Patent Documents

[Patent Document 1] United States Patent Application Publication No. 2011/0065270
[Patent Document 2] United States Patent Application Publication No. 2016/0149004
[Patent Document 3] United States Patent Application Publication No. 2013/0069052

### SUMMARY OF THE INVENTION

### Problems to be Solved by the Invention

To manufacture a memory device with high memory capacity, miniaturization of a memory cell has been promoted. Downsizing or eliminating a capacitor enables the miniaturization of a memory cell but reduces the electrostatic capacitance value of the memory cell, which makes the writing, retaining, and reading of data difficult. When the electrostatic capacitance value is small, susceptibility to noise is high and the value of retained data is likely to vary.

An object of one embodiment of the present invention is to provide a semiconductor device with a small circuit area. Another object of one embodiment of the present invention is to provide a semiconductor device with high memory capacity. Another object of one embodiment of the present invention is to provide a semiconductor device having high storage density. Another object of one embodiment of the present invention is to provide a novel semiconductor device or the like. Another object of one embodiment of the present invention is to provide a memory device including the above semiconductor device. Another object of one embodiment of the present invention is to provide an electronic device including the above memory device.

Note that the objects of one embodiment of the present invention are not limited to the above objects. The above objects do not preclude the presence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the above objects and the other objects. Note that one embodiment of the present invention does not necessarily achieve all of the above objects and the other objects.

### Means for Solving the Problems

In view of the above problems, one embodiment of the present invention is a semiconductor device including two stacked transistors in each of which a gate electrode and a channel formation region are provided along a vertical direction. The transistors can each occupy a smaller area than a planar transistor (in which a channel formation region is provided along a lateral direction).

Since the gate electrode is provided along a vertical direction, a capacitor can be formed of the gate electrode and a conductive layer that is provided around an opening. Thus, the two transistors and the capacitor overlap with each other.

Typical structure examples of a processing device of one embodiment of the present invention are described below.
(1) One embodiment of the present invention is a semiconductor device including a first layer including a first opening and a second layer including a second opening. The second layer is positioned above the first layer.

The first layer includes a first conductor, a second conductor, a third conductor, a fourth conductor, a first insulator, a second insulator, a third insulator, a fourth insulator, a fifth insulator, and a first semiconductor. The second layer includes a fifth conductor, a sixth conductor, a seventh conductor, a sixth insulator, a seventh insulator, and a second semiconductor.

The first opening is positioned above the first conductor, the first insulator is positioned on a top surface of the first conductor and an outer side surface of the first opening, the second conductor is positioned on a top surface of the first insulator and an outer side surface of the first opening, the second insulator is positioned on a top surface of the second conductor and an outer side surface of the first opening, and the third conductor is positioned on a top surface of the second insulator and an outer side surface of the first opening. The third insulator is positioned on a top surface of the second insulator and a side surface of the third conductor. The first semiconductor is positioned on a top surface of the first conductor, a side surface of the first insulator, a side surface of the second conductor, a side surface of the second insulator, and a side surface of the third conductor in an inner part of the first opening. The fourth insulator is positioned on a top surface of the third insulator, a top surface of the third conductor, and a top surface of the first semiconductor. The fourth conductor is positioned on a top surface of the fourth insulator and is in the inner part of the first opening and above the first opening. The fifth insulator is positioned above the fourth insulator and on a side surface of the fourth conductor, and the fifth conductor is positioned on a top surface of the fourth conductor and a top surface of the fifth insulator.

The second opening is positioned above the fifth conductor. The sixth insulator is positioned on a top surface of the fifth insulator, a top surface of the fifth conductor, and an outer side surface of the second opening, and the sixth conductor is positioned on a top surface of the sixth insulator and an outer side surface of the second opening. The second semiconductor is positioned on a top surface of the fifth conductor, a side surface of the sixth insulator, and a side surface of the sixth conductor in an inner part of the second opening and positioned on a top surface of the sixth conductor in an outer part of the second opening. The seventh insulator is positioned on a top surface of the sixth insulator, a top surface of the sixth conductor, and a top surface of the second semiconductor, and the seventh conductor is positioned on a top surface of the seventh insulator and the top surface is partly in the inner part of the second opening.
(2) Another embodiment of the present invention is a semiconductor device that includes a first layer including a first opening and a second layer including a second opening and differs in structure from (1) described above. The second layer is positioned above the first layer.

The first layer includes a first conductor, a second conductor, a third conductor, a fourth conductor, a first insulator, a second insulator, a third insulator, a fourth insulator, a fifth insulator, and a first semiconductor. The second layer includes a sixth conductor, a seventh conductor, a sixth insulator, a seventh insulator, and a second semiconductor.

The first opening is positioned above the first conductor, the first insulator is positioned on a top surface of the first conductor and an outer side surface of the first opening, the second conductor is positioned on a top surface of the first insulator and an outer side surface of the first opening, the second insulator is positioned on a top surface of the second conductor and an outer side surface of the first opening, and the third conductor is positioned on a top surface of the second insulator and an outer side surface of the first opening. The third insulator is positioned on a top surface of the second insulator and a side surface of the third conductor. The first semiconductor is positioned on a top surface of the first conductor, a side surface of the first insulator, a side surface of the second conductor, a side surface of the second insulator, and a side surface of the third conductor in an inner part of the first opening. The fourth insulator is positioned on a top surface of the third insulator, a top surface of the third conductor, and a top surface of the first semiconductor. The fourth conductor is positioned on a top surface of the fourth insulator and is in the inner part of the first opening and above the first opening. The fifth insulator is positioned above the fourth insulator and on a side surface of the fourth conductor.

The second opening is positioned above the fourth conductor. The sixth insulator is positioned on a top surface of the fifth insulator, a top surface of the fourth conductor, and an outer side surface of the second opening, and the sixth conductor is positioned on a top surface of the sixth insulator and an outer side surface of the second opening. The second semiconductor is positioned on a top surface of the fourth conductor, a side surface of the sixth insulator, and a side surface of the sixth conductor in an inner part of the second opening, and positioned on a top surface of the sixth conductor in an outer part of the second opening. The seventh insulator is positioned on a top surface of the sixth insulator, a top surface of the sixth conductor, and a top surface of the second semiconductor, and the seventh conductor is positioned on a top surface of the seventh insulator and the top surface is partly in the inner part of the second opening.
(3) Another embodiment of the present invention may have a structure in which the first semiconductor and the second semiconductor each include one or more selected from indium, zinc, and an element M in (1) or (2) described above.

Note that the element M is one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.
(4) Another embodiment of the present invention may have a structure in which a taper angle of a side surface of the second opening is greater than or equal to 45° and less than or equal to 90° in (3) described above.
(5) Another embodiment of the present invention may have a structure in which the first conductor and the sixth conductor extend in a first direction and the second conductor, the third conductor, and the seventh conductor extend in a second direction in (4) described above.
(6) Another embodiment of the present invention is a memory device including the semiconductor device according to any one of the above (1) to (5) and a driver circuit. The driver circuit is positioned below the semiconductor device. The driver circuit is formed on a semiconductor substrate including silicon. The driver circuit includes a transistor including the silicon in a channel formation region.
(7) Another embodiment of the present invention is an electronic device including the memory device according to the above (6) and a housing.

### Effect of the Invention

The structure in which the two transistors and the capacitor overlap with each other as described above can reduce the occupied area. Accordingly, the storage density can be increased. In addition, this structure enables the capacitor to be provided without increasing the circuit area.

According to one embodiment of the present invention, a semiconductor device with a small circuit area can be provided. According to one embodiment of the present invention, a semiconductor device with high memory capacity can be provided. According to another embodiment of the present invention, a semiconductor device having high storage density can be provided. According to another embodiment of the present invention, a novel semiconductor device or the like can be provided. According to another embodiment of the present invention, a memory device including the above semiconductor device can be provided. According to another embodiment of the present invention, an electronic device including the above memory device can be provided.

Note that the effects of one embodiment of the present invention are not limited to the effects listed above. The effects described above do not preclude the presence of other effects. The other effects are effects that are not described in this section and will be described below. The effects that are not described in this section can be derived from the description of the specification, the drawings, and the like and can be extracted as appropriate from the description by those skilled in the art. One embodiment of the present invention has at least one of the above effects and the other effects. Accordingly, one embodiment of the present invention does not have the above effects in some cases.

### BRIEF DESCRIPTION OF THE DRAWINGS

FIG. 1A to FIG. 1C are circuit diagrams each illustrating an example of a semiconductor device.

FIG. 2A is a schematic plan view illustrating a structure example of a semiconductor device, and FIG. 2B and FIG. 2C are schematic cross-sectional views illustrating the structure example of the semiconductor device.

FIG. 3A and FIG. 3B are block diagrams each illustrating an example of a memory device.

FIG. 4A and FIG. 4B are schematic plan views illustrating an example of a cell array.

FIG. 5A and FIG. 5B are schematic plan views illustrating an example of a cell array.

FIG. 6A and FIG. 6B are schematic plan views illustrating an example of a cell array.

FIG. 7A and FIG. 7B are schematic plan views illustrating an example of a cell array.

FIG. 8A and FIG. 8B are timing charts each showing an operation example of a semiconductor device.

FIG. 9A is a schematic plan view illustrating an example of a method for manufacturing a semiconductor device, and FIG. 9B and FIG. 9C are schematic cross-sectional views illustrating the example of a method for manufacturing a semiconductor device.

FIG. 10A is a schematic plan view illustrating an example of a method for manufacturing a semiconductor device, and FIG. 10B and FIG. 10C are schematic cross-sectional views illustrating the example of a method for manufacturing a semiconductor device.

FIG. 11A is a schematic plan view illustrating an example of a method for manufacturing a semiconductor device, and FIG. 11B and FIG. 11C are schematic cross-sectional views illustrating the example of a method for manufacturing a semiconductor device.

FIG. 12A is a schematic plan view illustrating an example of a method for manufacturing a semiconductor device, and FIG. 12B and FIG. 12C are schematic cross-sectional views illustrating the example of a method for manufacturing a semiconductor device.

FIG. 13A is a schematic plan view illustrating an example of a method for manufacturing a semiconductor device, and FIG. 13B and FIG. 13C are schematic cross-sectional views illustrating the example of a method for manufacturing a semiconductor device.

FIG. 14A is a schematic plan view illustrating an example of a method for manufacturing a semiconductor device, and FIG. 14B and FIG. 14C are schematic cross-sectional views illustrating the example of a method for manufacturing a semiconductor device.

FIG. 15A is a schematic plan view illustrating an example of a method for manufacturing a semiconductor device, and FIG. 15B and FIG. 15C are schematic cross-sectional views illustrating the example of a method for manufacturing a semiconductor device.

FIG. 16A is a schematic plan view illustrating an example of a method for manufacturing a semiconductor device, and FIG. 16B and FIG. 16C are schematic cross-sectional views illustrating the example of a method for manufacturing a semiconductor device.

FIG. 17A is a schematic plan view illustrating an example of a method for manufacturing a semiconductor device, and FIG. 17B and FIG. 17C are schematic cross-sectional views illustrating the example of a method for manufacturing a semiconductor device.

FIG. 18A is a schematic plan view illustrating an example of a method for manufacturing a semiconductor device, and FIG. 18B and FIG. 18C are schematic cross-sectional views illustrating the example of a method for manufacturing a semiconductor device.

FIG. 19A is a schematic plan view illustrating an example of a method for manufacturing a semiconductor device, and FIG. 19B and FIG. 19C are schematic cross-sectional views illustrating the example of a method for manufacturing a semiconductor device.

FIG. 20A is a schematic plan view illustrating an example of a method for manufacturing a semiconductor device, and FIG. 20B and FIG. 20C are schematic cross-sectional views illustrating the example of a method for manufacturing a semiconductor device.

FIG. 21A is a schematic plan view illustrating an example of a method for manufacturing a semiconductor device, and FIG. 21B and FIG. 21C are schematic cross-sectional views illustrating the example of a method for manufacturing a semiconductor device.

FIG. 22A is a schematic plan view illustrating an example of a method for manufacturing a semiconductor device, and FIG. 22B and FIG. 22C are schematic cross-sectional views illustrating the example of a method for manufacturing a semiconductor device.

FIG. 23A is a schematic plan view illustrating an example of a method for manufacturing a semiconductor device, and FIG. 23B and FIG. 23C are schematic cross-sectional views illustrating the example of a method for manufacturing a semiconductor device.

FIG. 24A is a schematic plan view illustrating an example of a method for manufacturing a semiconductor device, and FIG. 24B and FIG. 24C are schematic cross-sectional views illustrating the example of a method for manufacturing a semiconductor device.

FIG. 25A is a schematic plan view illustrating an example of a method for manufacturing a semiconductor device, and FIG. 25B and FIG. 25C are schematic cross-sectional views illustrating the example of a method for manufacturing a semiconductor device.

FIG. 26A is a schematic plan view illustrating an example of a method for manufacturing a semiconductor device, and FIG. 26B and FIG. 26C are schematic cross-sectional views illustrating the example of a method for manufacturing a semiconductor device.

FIG. 27A is a schematic plan view illustrating an example of a method for manufacturing a semiconductor device, and FIG. 27B and FIG. 27C are schematic cross-sectional views illustrating the example of a method for manufacturing a semiconductor device.

FIG. 28A is a schematic plan view illustrating an example of a method for manufacturing a semiconductor device, and FIG. 28B and FIG. 28C are schematic cross-sectional views illustrating the example of a method for manufacturing a semiconductor device.

FIG. 29A is a schematic plan view illustrating an example of a method for manufacturing a semiconductor device, and FIG. 29B and FIG. 29C are schematic cross-sectional views illustrating the example of a method for manufacturing a semiconductor device.

FIG. 30A is a schematic plan view illustrating an example of a method for manufacturing a semiconductor device, and FIG. 30B and FIG. 30C are schematic cross-sectional views illustrating the example of a method for manufacturing a semiconductor device.

FIG. 31A is a schematic plan view illustrating an example of a method for manufacturing a semiconductor device, and FIG. 31B and FIG. 31C are schematic cross-sectional views illustrating the example of a method for manufacturing a semiconductor device.

FIG. 32A is a schematic plan view illustrating an example of a method for manufacturing a semiconductor device, and FIG. 32B and FIG. 32C are schematic cross-sectional views illustrating the example of a method for manufacturing a semiconductor device.

FIG. 33A is a schematic plan view illustrating a structure example of a semiconductor device, and

FIG. 33B and FIG. 33C are schematic cross-sectional views illustrating the structure example of the semiconductor device.

FIG. 34A is a schematic plan view illustrating a structure example of a semiconductor device, and FIG. 34B and FIG. 34C are schematic cross-sectional views illustrating the structure example of the semiconductor device.

FIG. 35A is a schematic plan view illustrating an example of a method for manufacturing a semiconductor device, and FIG. 35B and FIG. 35C are schematic cross-sectional views illustrating the example of a method for manufacturing a semiconductor device.

FIG. 36A is a schematic plan view illustrating a structure example of a semiconductor device, and FIG. 36B and FIG. 36C are schematic cross-sectional views illustrating the structure example of the semiconductor device.

FIG. 37A is a schematic plan view illustrating a structure example of a semiconductor device, and FIG. 37B and FIG. 37C are schematic cross-sectional views illustrating the structure example of the semiconductor device.

FIG. 38A is a schematic plan view illustrating a structure example of a semiconductor device, and

FIG. 38B and FIG. 38C are schematic cross-sectional views illustrating the structure example of the semiconductor device.

FIG. 39A is a schematic plan view illustrating a structure example of a semiconductor device, and FIG. 39B and FIG. 39C are schematic cross-sectional views illustrating the structure example of the semiconductor device.

FIG. 40A is a schematic plan view illustrating a structure example of a semiconductor device, and FIG. 40B and FIG. 40C are schematic cross-sectional views illustrating the structure example of the semiconductor device.

FIG. 41A is a schematic plan view illustrating an example of a method for manufacturing a semiconductor device, and FIG. 41B and FIG. 41C are schematic cross-sectional views illustrating the example of a method for manufacturing a semiconductor device.

FIG. 42A is a schematic plan view illustrating a structure example of a semiconductor device, and FIG. 42B and FIG. 42C are schematic cross-sectional views illustrating the structure example of the semiconductor device.

FIG. 43A is a schematic plan view illustrating an example of a method for manufacturing a semiconductor device, and FIG. 43B and FIG. 43C are schematic cross-sectional views illustrating the example of a method for manufacturing a semiconductor device.

FIG. 44A is a schematic plan view illustrating an example of a method for manufacturing a semiconductor device, and FIG. 44B and FIG. 44C are schematic cross-sectional views illustrating the example of a method for manufacturing a semiconductor device.

FIG. 45A is a schematic plan view illustrating a structure example of a semiconductor device, and FIG. 45B and FIG. 45C are schematic cross-sectional views illustrating the structure example of the semiconductor device.

FIG. 46A is a schematic plan view illustrating an example of a method for manufacturing a semiconductor device, and FIG. 46B and FIG. 46C are schematic cross-sectional views illustrating the example of a method for manufacturing a semiconductor device.

FIG. 47A is a schematic plan view illustrating an example of a method for manufacturing a semiconductor device, and FIG. 47B and FIG. 47C are schematic cross-sectional views illustrating the example of a method for manufacturing a semiconductor device.

FIG. 48A is a schematic plan view illustrating a structure example of a semiconductor device, and FIG. 48B and FIG. 48C are schematic cross-sectional views illustrating the structure example of the semiconductor device.

FIG. 49A is a schematic plan view illustrating an example of a method for manufacturing a semiconductor device, and FIG. 49B and FIG. 49C are schematic cross-sectional views illustrating the example of a method for manufacturing a semiconductor device.

FIG. 50A is a schematic plan view illustrating a structure example of a semiconductor device, and FIG. 50B and FIG. 50C are schematic cross-sectional views illustrating the structure example of the semiconductor device.

FIG. 51A is a schematic plan view illustrating a structure example of a semiconductor device, and FIG. 51B and FIG. 51C are schematic cross-sectional views illustrating the structure example of the semiconductor device.

FIG. 52A is a schematic plan view illustrating a structure example of a semiconductor device, and FIG. 52B and FIG. 52C are schematic cross-sectional views illustrating the structure example of the semiconductor device.

FIG. 53A is a schematic plan view illustrating a structure example of a semiconductor device, and FIG. 53B and FIG. 53C are schematic cross-sectional views illustrating the structure example of the semiconductor device.

FIG. 54A is a schematic plan view illustrating a structure example of a semiconductor device, and FIG. 54B and FIG. 54C are schematic cross-sectional views illustrating the structure example of the semiconductor device.

FIG. 55A is a schematic plan view illustrating a structure example of a semiconductor device, and

FIG. 55B and FIG. 55C are schematic cross-sectional views illustrating the structure example of the semiconductor device.

FIG. 56A is a schematic plan view illustrating a structure example of a semiconductor device, and FIG. 56B and FIG. 56C are schematic cross-sectional views illustrating the structure example of the semiconductor device.

FIG. 57A is a schematic plan view illustrating a structure example of a semiconductor device, and FIG. 57B and FIG. 57C are schematic cross-sectional views illustrating the structure example of the semiconductor device.

FIG. 58A is a schematic plan view illustrating a structure example of a semiconductor device, and FIG. 58B and FIG. 58C are schematic cross-sectional views illustrating the structure example of the semiconductor device.

FIG. 59A is a schematic plan view illustrating a structure example of a semiconductor device, and FIG. 59B and FIG. 59C are schematic cross-sectional views illustrating the structure example of the semiconductor device.

FIG. 60A is a schematic plan view illustrating a structure example of a semiconductor device, and

FIG. 60B and FIG. 60C are schematic cross-sectional views illustrating the structure example of the semiconductor device.

FIG. 61A is a schematic plan view illustrating a structure example of a semiconductor device, and FIG. 61B and FIG. 61C are schematic cross-sectional views illustrating the structure example of the semiconductor device.

FIG. 62A is a schematic plan view illustrating a structure example of a semiconductor device, and FIG. 62B and FIG. 62C are schematic cross-sectional views illustrating the structure example of the semiconductor device.

FIG. 63A is a schematic plan view illustrating a structure example of a semiconductor device, and FIG. 63B and FIG. 63C are schematic cross-sectional views illustrating the structure example of the semiconductor device.

FIG. 64A is a schematic plan view illustrating a structure example of a semiconductor device, and FIG. 64B and FIG. 64C are schematic cross-sectional views illustrating the structure example of the semiconductor device.

FIG. 65A is a schematic plan view illustrating an example of a method for manufacturing a semiconductor device, and FIG. 65B and FIG. 65C are schematic cross-sectional views illustrating the example of a method for manufacturing a semiconductor device.

FIG. 66A is a schematic plan view illustrating an example of a method for manufacturing a semiconductor device, and FIG. 66B and FIG. 66C are schematic cross-sectional views illustrating the example of a method for manufacturing a semiconductor device.

FIG. 67A is a schematic plan view illustrating an example of a method for manufacturing a semiconductor device, and FIG. 67B and FIG. 67C are schematic cross-sectional views illustrating the example of a method for manufacturing a semiconductor device.

FIG. 68A is a schematic plan view illustrating a structure example of a semiconductor device, and FIG. 68B and FIG. 68C are schematic cross-sectional views illustrating the structure example of the semiconductor device.

FIG. 69A is a schematic plan view illustrating an example of a method for manufacturing a semiconductor device, and FIG. 69B and FIG. 69C are schematic cross-sectional views illustrating the example of a method for manufacturing a semiconductor device.

FIG. 70A is a schematic plan view illustrating an example of a method for manufacturing a semiconductor device, and FIG. 70B and FIG. 70C are schematic cross-sectional views illustrating the example of a method for manufacturing a semiconductor device.

FIG. 71A is a schematic plan view illustrating a structure example of a semiconductor device, and

FIG. 71B and FIG. 71C are schematic cross-sectional views illustrating the structure example of the semiconductor device.

FIG. 72A is a schematic plan view illustrating a structure example of a semiconductor device, and FIG. 72B and FIG. 72C are schematic cross-sectional views illustrating the structure example of the semiconductor device.

FIG. 73A is a schematic plan view illustrating a structure example of a semiconductor device, and FIG. 73B and FIG. 73C are schematic cross-sectional views illustrating the structure example of the semiconductor device.

FIG. 74 is a schematic plan view illustrating an example of a cell array.

FIG. 75A is a schematic plan view illustrating a structure example of a semiconductor device, and

FIG. 75B and FIG. 75C are schematic cross-sectional views illustrating the structure example of the semiconductor device.

FIG. 76 is a schematic plan view illustrating an example of a cell array.

FIG. 77A is a schematic plan view illustrating an example of a method for manufacturing a semiconductor device, and FIG. 77B and FIG. 77C are schematic cross-sectional views illustrating the example of a method for manufacturing a semiconductor device.

FIG. 78A is a schematic plan view illustrating an example of a method for manufacturing a semiconductor device, and FIG. 78B and FIG. 78C are schematic cross-sectional views illustrating the example of a method for manufacturing a semiconductor device.

FIG. 79A is a schematic plan view illustrating an example of a method for manufacturing a semiconductor device, and FIG. 79B and FIG. 79C are schematic cross-sectional views illustrating the example of a method for manufacturing a semiconductor device.

FIG. 80A is a schematic plan view illustrating a structure example of a semiconductor device, and FIG. 80B and FIG. 80C are schematic cross-sectional views illustrating the structure example of the semiconductor device.

FIG. 81A is a schematic plan view illustrating a structure example of a semiconductor device, and FIG. 81B and FIG. 81C are schematic cross-sectional views illustrating the structure example of the semiconductor device.

FIG. 82A is a schematic plan view illustrating an example of a cell array, and FIG. 82B is a schematic perspective view illustrating a structure example of a transistor.

FIG. 83A is a schematic plan view illustrating a structure example of a semiconductor device, and FIG. 83B and FIG. 83C are schematic cross-sectional views illustrating the structure example of the semiconductor device.

FIG. 84 is a schematic plan view illustrating an example of a cell array.

FIG. 85A is a schematic plan view illustrating a structure example of a semiconductor device, and

FIG. 85B and FIG. 85C are schematic cross-sectional views illustrating the structure example of the semiconductor device.

FIG. 86A is a schematic plan view illustrating an example of a cell array, and FIG. 86B is a schematic perspective view illustrating a structure example of a transistor.

FIG. 87A and FIG. 87B are schematic plan views illustrating an example of a cell array.

FIG. 88A to FIG. 88C are circuit diagrams each illustrating an example of a semiconductor device.

FIG. 89A is a schematic plan view illustrating a structure example of a semiconductor device, and FIG. 89B and FIG. 89C are schematic cross-sectional views illustrating the structure example of the semiconductor device.

FIG. 90A and FIG. 90B are block diagrams each illustrating an example of a memory device.

FIG. 91A is a schematic plan view illustrating a structure example of a semiconductor device, and FIG. 91B and FIG. 91C are schematic cross-sectional views illustrating the structure example of the semiconductor device.

FIG. 92A is a schematic plan view illustrating a structure example of a semiconductor device, and FIG. 92B and FIG. 92C are schematic cross-sectional views illustrating the structure example of the semiconductor device.

FIG. 93A is a schematic plan view illustrating a structure example of a semiconductor device, and FIG. 93B and FIG. 93C are schematic cross-sectional views illustrating the structure example of the semiconductor device.

FIG. 94A is a schematic perspective view illustrating a structure example of a memory device, and FIG. 94B is a block diagram illustrating a structure example of a semiconductor device.

FIG. 95 is a block diagram illustrating a structure example of a memory device.

FIG. 96 is a diagram illustrating a structure example of a memory device.

FIG. 97A and FIG. 97B are diagrams each illustrating an example of an electronic component.

FIG. 98A and FIG. 98B are diagrams each illustrating an example of an electronic device, and

FIG. 98C to FIG. 98E are diagrams illustrating an example of a large computer.

FIG. 99 is a diagram illustrating an example of space equipment.

FIG. 100 is a diagram illustrating an example of a storage system that can be used in a data center.

FIG. 101A is a schematic perspective view illustrating a structure example of a display apparatus, and FIG. 101B is a block diagram illustrating the structure example of a display apparatus.

FIG. 102 is a circuit diagram illustrating a structure example of a pixel circuit included in a display apparatus.

FIG. 103 is a schematic perspective view illustrating a structure example of a stacked-layer structure included in a display apparatus.

FIG. 104A to FIG. 104I are perspective views illustrating electronic device examples.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. An example of a semiconductor device is an integrated circuit. Another example of a semiconductor device is a chip that includes an integrated circuit. Another example of a semiconductor device is an electronic component in which a chip is stored in a package. Moreover, a memory device, a display apparatus, a light-emitting apparatus, a lighting device, an electronic device, and the like themselves are semiconductor devices in some cases and include semiconductor devices in other cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conducting state (on state) or a non-conducting state (off state) to control whether current flows or not.

In the case where an element and a power supply line (e.g., a wiring supplying VDD (high power supply potential), VSS (low power supply potential), GND (the ground potential), or a desired potential) are both provided between X and Y, X and Y are not defined as being electrically connected. In the case where only a power supply line is provided between X and Y, there is no element between X and Y; therefore, X and Y are directly connected. Accordingly, in the case where only a power supply line is provided between X and Y, X and Y can be expressed as being “electrically connected”. However, in the case where an element and a power supply line are both provided between X and Y, X and Y are not defined as being electrically connected, although X and the power supply line are electrically connected (through the element) and Y and the power supply line are electrically connected. Note that in the case where a gate and a source of a transistor are provided between X and Y, X and Y are not defined as being electrically connected. Note that in the case where a gate and a drain of a transistor are provided between X and Y, X and Y are not defined as being electrically connected. That is, in the case where a drain and a source of a transistor are provided between X and Y, X and Y are defined as being electrically connected. Note that in the case where a capacitor is provided between X and Y, X and Y are defined as being electrically connected in some cases and not defined in other cases. For example, in the case where a capacitor is provided between X and Y in a structure of a digital circuit or a logic circuit, X and Y are not defined as being electrically connected in some cases. On the other hand, for example, in the case where a capacitor is provided between X and Y in a structure of an analog circuit, X and Y are defined as being electrically connected in some cases.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of a current, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

For example, an expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used. Alternatively, an expression “a source of a transistor is electrically connected to X; a drain of the transistor is electrically connected to Y; and X, the source of the transistor, the drain of the transistor, and Y are electrically connected to each other in this order” can be used. Alternatively, the expression “X is electrically connected to Y through a source and a drain of a transistor, and X, the source of the transistor, the drain of the transistor, and Y are provided in this connection order” can be used. When the connection order in a circuit structure is defined by an expression like the above examples, a source and a drain of a transistor can be distinguished from each other to specify the technical scope. Note that these expressions are non-limiting examples. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both functions of a wiring and an electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” includes a wiring having a resistance value, a transistor in which a current flows between a source and a drain, a diode, and a coil. Thus, the term “resistor” can sometimes be replaced with the terms “resistance”, “load”, or “region having a resistance value”. Conversely, the terms “resistance”, “load”, or “region having a resistance value” can sometimes be replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. For another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of an off-state current can be reduced, and the breakdown voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and their gates are electrically connected to each other. Similarly, for another example, the case where a single switch is illustrated in a circuit diagram may include a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, a “voltage” and a “potential” can be replaced with each other as appropriate. A “voltage” refers to a potential difference from a reference potential, and when the reference potential is a ground potential, for example, a “voltage” can be replaced with a “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

A “current” means a charge transfer phenomenon (electrical conduction); for example, the description “electrical conduction of positively charged particles occurs” can be rephrased as “electrical conduction of negatively charged particles occurs in the opposite direction”. Therefore, unless otherwise specified, a “current” in this specification and the like refers to a charge transfer phenomenon (electrical conduction) accompanying carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of a current” in a wiring or the like refers to the direction in which a carrier with positive charge moves, and the amount of the current is expressed as a positive value. In other words, the direction in which a carrier with negative charge moves is opposite to the direction of a current, and the amount of the current is expressed as a negative value. Thus, in the case where the polarity of a current (or the direction of a current) is not specified in this specification and the like, the description “a current flows from element A to element B” can be rephrased as “a current flows from element B to element A”. The description “a current is input to element A” can be rephrased as “a current is output from element A”.

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments or the scope of claims. For another example, a “first” component in one embodiment in this specification and the like can be omitted in other embodiments or the scope of claims.

In this specification and the like, the terms for describing positioning, such as “over” and “under”, are sometimes used for convenience to describe the positional relation between components with reference to drawings. The positional relationship between components is changed as appropriate in accordance with the direction in which the components are described. Thus, the positional relation is not limited to the terms described in the specification and the like, and can be described with another term as appropriate depending on the situation. For example, the expression “an insulator located over (on) a top surface of a conductor” can be replaced with the expression “an insulator located under (on) a bottom surface of a conductor” when the direction of a drawing illustrating these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B.

Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relationship are sometimes described using terms such as “row” and “column”. The positional relationship between components is changed as appropriate in accordance with the direction in which the components are described. Thus, the positional relationship is not limited to the terms described in the specification and the like, and can be described with another term as appropriate depending on the situation. For example, the term “row direction” can be replaced with the term “column direction” when the direction of the diagram is rotated by 90°.

In this specification and the like, the terms “film” and “layer” can be interchanged with each other depending on the situation. For example, the term “conductive layer” can be replaced with the term “conductive film” in some cases. For another example, the term “insulating film” can be changed into the term “insulating layer” in some cases. Alternatively, the terms “film” and “layer” are not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where one or more selected from “electrodes”, “wirings”, and “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Similarly, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a timing chart is used in some cases to describe an operation method of a semiconductor device. In this specification and the like, the timing chart shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the situation. For example, even when two periods are shown to have an equal length, the two periods have different lengths in some cases. Furthermore, for example, even when one of two periods is shown long and the other is shown short, the two periods can have the equal length in some cases, or the one period has a short length and the other has a long length in other cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor. In this specification and the like, a metal oxide containing nitrogen is also referred to as a metal oxide in some cases. Alternatively, a metal oxide containing nitrogen may be called a metal oxynitride.

In this specification and the like, an impurity in a semiconductor refers to, for example, an element other than a main component of a semiconductor layer. For example, an element with a concentration of lower than 0.1 atomic % is an impurity. When an impurity is contained, for example, one or more of an increase in the density of defect states in a semiconductor, a decrease in carrier mobility, and a decrease in crystallinity may occur. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen.

In this specification and the like, a switch has a function of being in a conducting state (on state) or a non-conducting state (off state) to control whether current flows or not. Alternatively, a switch has a function of selecting and changing a current path. Thus, a switch may have two terminals or three or more terminals through which current flows, in addition to a control terminal. For example, an electrical switch or a mechanical switch can be used. That is, a switch can be any element capable of controlling current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conducting state” of the transistor refers to a state where a source electrode and a drain electrode of the transistor can be regarded as being electrically short-circuited or a state where a current can be made to flow between the source electrode and the drain electrode. Furthermore, a “non-conducting state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical systems) technology. Such a switch includes an electrode that can be moved mechanically, and operates by controlling conduction and non-conduction with movement of the electrode.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification. Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Thus, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

In the drawings in this specification, the size, the layer thickness, or the region is exaggerated for clarity in some cases. Therefore, the size, the layer thickness, or the region is not limited to the illustrated scale. The drawings are schematic views showing ideal examples, and embodiments of the present invention are not limited to shapes, values, or the like shown in the drawings. For example, variations in a signal, a voltage, or a current due to noise, variations in a signal, a voltage, or a current due to difference in timing, or the like can be included.

### Embodiment 1

In this embodiment, a memory cell that is a semiconductor device of one embodiment of the present invention will be described.

### <Circuit Structure Example of Semiconductor Device>

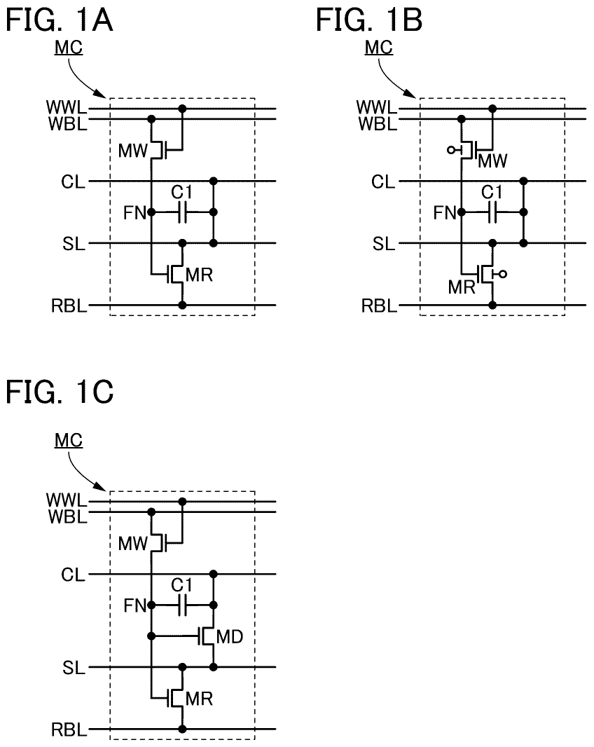

FIG. 1A illustrates an example of a memory cell that is a semiconductor device of one embodiment of the present invention. A memory cell MC is an example of a memory cell called a gain cell and includes a transistor MW, a transistor MR, and a capacitor C1. In particular, in this specification and the like, the structure of the memory cell MC in which OS transistors are used as the transistor MW and the transistor MR is referred to as a NOSRAM (registered trademark) (Nonvolatile Oxide Semiconductor Random Access Memory) in some cases.

The transistor MW functions as a write transistor in the memory cell MC, for example. The transistor MR functions as a read transistor in the memory cell MC, for example.

OS transistors are preferably used as the transistor MW and the transistor MR, for example. In particular, a metal oxide included in a channel formation region of the OS transistor is preferably an In-M-Zn oxide containing indium, the element M, and zinc (the element M is one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony), for example. As each of the transistors, a transistor including silicon in a channel formation region (hereinafter, referred to as a Si transistor) may be used. As the silicon, single crystal silicon, amorphous silicon (referred to as hydrogenated amorphous silicon in some cases), microcrystalline silicon, or polycrystalline silicon can be used, for example. As a transistor other than an OS transistor and a Si transistor, for example, a transistor including germanium (Ge) in a channel formation region, a transistor including a compound semiconductor such as zinc selenide (ZnSe), cadmium sulfide (CdS), gallium arsenide (GaAs), indium phosphide (InP), gallium nitride (GaN), or silicon germanium (SiGe) in a channel formation region, a transistor including a carbon nanotube in a channel formation region, or a transistor including an organic semiconductor in a channel formation region can be used.

A first terminal of the transistor MW is electrically connected to a wiring WBL, a second terminal of the transistor MW is electrically connected to a gate of the transistor MR and a first terminal of the capacitor C1, and a gate of the transistor MW is electrically connected to a wiring WWL. A first terminal of the transistor MR is electrically connected to a wiring SL, and a second terminal of the transistor MR is electrically connected to a wiring RBL. A second terminal of the capacitor C1 is electrically connected to a wiring CL and the wiring SL.

In FIG. 1A, the electrical connection point of the second terminal of the transistor MW, the gate of the transistor MR, and the first terminal of the capacitor C1 is a node FN.

The wiring WBL functions as a write data line (sometimes referred to as a write bit line) that transmits write data to be retained in the memory cell MC, for example.

The wiring WWL functions as a wiring for selecting the memory cell MC to which data is to be written (sometimes referred to as a write word line), for example.

The wiring RBL functions as a read data line (sometimes referred to as a read bit line) that transmits data read from the memory cell MC, for example.

The wiring CL and the wiring SL function as wirings for selecting a memory cell from which data is to be read (sometimes referred to as read word lines), for example. Preferably, the wiring CL and the wiring SL are electrically connected to each other outside the memory cell MC and the same signals are transmitted to the wiring CL and the wiring SL.

The semiconductor device of one embodiment of the present invention does not depend on the structure of a transistor included in the semiconductor device. For example, one or both of the transistor MW and the transistor MR illustrated in FIG. 1A may have a structure with a back gate, i.e., may be a multi-gate transistor in which a channel formation region is vertically interposed between gates.

The memory cell MC in FIG. 1B is a modification example of the memory cell MC in FIG. 1A. Each of the transistor MW and the transistor MR illustrated in FIG. 1B is an n-channel transistor having a multi-gate structure including gates above and below a channel, for example, and includes a first gate and a second gate. Note that in this specification and the like, for convenience, the first gate is referred to as a gate (sometimes referred to as a front gate) and the second gate is referred to as a back gate in some cases so that they are distinguished from each other, for example. In this specification and the like, the first gate and the second gate can be interchanged with each other; thus, the term “gate” can be replaced with the term “back gate”. Similarly, the term “back gate” can be replaced with the term “gate”. As a specific example, a connection structure in which “a gate is electrically connected to a first wiring and a back gate is electrically connected to a second wiring” can be replaced with a connection structure in which “a back gate is electrically connected to the first wiring and a gate is electrically connected to the second wiring”.

Although the back gates of the transistor MW and the transistor MR are illustrated in FIG. 1B, the connection structures of the back gates are not illustrated. Portions to which the back gates are electrically connected can be determined at the design stage. For example, in a transistor including a back gate, a gate and the back gate may be electrically connected to each other to increase the on-state current of the transistor. That is, for example, the gate and the back gate of the transistor MW may be electrically connected to each other, and the gate and the back gate of the transistor MR may be electrically connected to each other. For another example, in a transistor having a back gate, a wiring electrically connecting the back gate of the transistor to an external circuit may be provided and a potential may be supplied to the back gate of the transistor with the external circuit to change the threshold voltage of the transistor or to reduce the off-state current of the transistor.

A transistor with a single-gate structure or a multi-gate structure can be used not only as the transistor in FIG. 1B but also as a transistor described in another part of this specification or a transistor illustrated in another drawing in some cases.

### <Cross-Sectional Structure Example of Semiconductor Device>

Next, plan-view and cross-sectional structure examples of the memory cell MC in FIG. 1A are described.

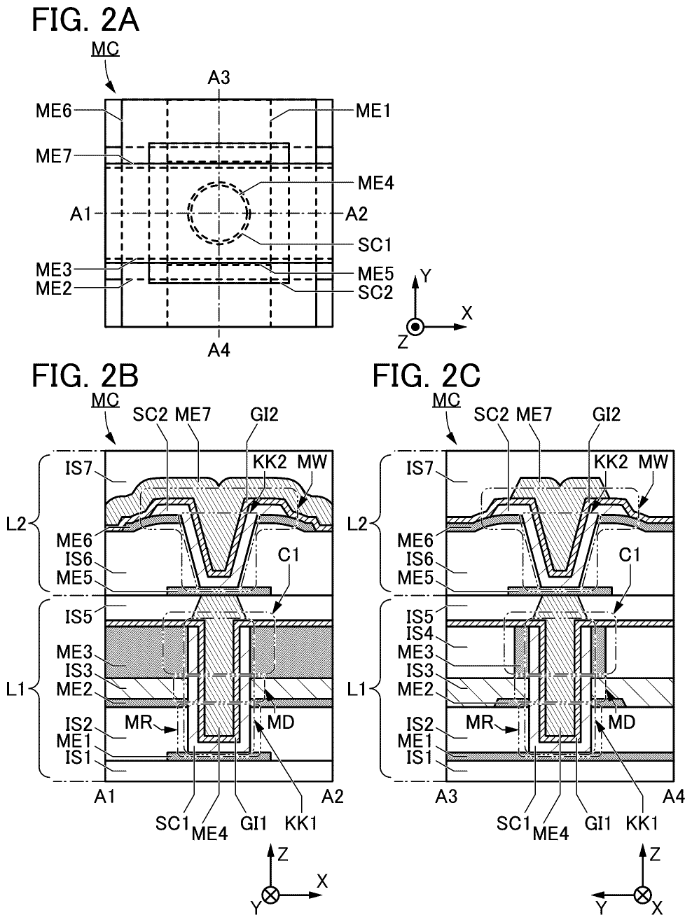

FIG. 2A shows a plan-view structure example of the memory cell MC in FIG. 1A, and each of FIG. 2B and FIG. 2C shows a cross-sectional structure example of the memory cell MC in FIG. 1A. FIG. 2B is a cross-sectional view of a portion indicated by the dashed-dotted line A1-A2 in the schematic plan view in FIG. 2A, and FIG. 2C is a cross-sectional view of a portion indicated by the dashed-dotted line A3-A4 in the schematic plan view in FIG. 2A. For clarity of the drawing, some components are omitted in the schematic plan view in FIG. 2A.

The memory cell MC illustrated in FIG. 2A to FIG. 2C has a three-dimensional structure; thus, the x direction, the y direction, and the z direction are indicated by arrows. Here, the x direction, the y direction, and the z direction are shown as directions orthogonal to each other. In this specification and the like, one of the x direction, the y direction, and the z direction is referred to as a “first direction” in some cases. Another one of the directions is referred to as a “second direction” in some cases. The remaining one of the directions is referred to as a “third direction” in some cases.

In FIG. 2B and FIG. 2C, the memory cell MC includes a layer L1 and a layer L2. The layer L2 is positioned above the layer L1.

The layer L1 includes an insulator IS1, an insulator IS2, an insulator IS3, an insulator IS4, an insulator IS5, an insulator GI1, a conductor ME1, a conductor ME2, a conductor ME3, a conductor ME4, and a semiconductor SC1, for example. When the above materials are formed through a predetermined process, the transistor MR and the capacitor C1 can be provided in the layer L1. The capacitor C1 is positioned above the transistor MR.

Specifically, the transistor MR and the capacitor C1 can be formed by, for example, embedding the semiconductor SC1, the insulator GI1, and the conductor ME4 in the inner part of an opening KK1 provided in the insulator IS2, the conductor ME2, the insulator IS3, and the conductor ME3. In the plan view of the memory cell MC in FIG. 1A, the opening KK1 is formed in a region where the conductor ME1, a conductive film to be the conductor ME2, and a conductive film to be the conductor ME3 overlap with each other.

The layer L2 includes an insulator IS6, an insulator IS7, an insulator GI2, a conductor ME5, a conductor ME6, a conductor ME7, and a semiconductor SC2, for example. When the above materials are formed through a predetermined process, the transistor MW can be provided in the layer L2.

Specifically, the transistor MW can be formed by, for example, embedding the semiconductor SC2, the insulator GI2, and the conductor ME7 in the inner part of an opening KK2 provided in the insulator IS6 and the conductor ME6. In the plan view of the memory cell MC in FIG. 1A, the opening KK2 is formed in a region overlapping with the conductor ME5 and a conductive film to be the conductor ME6.

As described above, the transistor MR, the capacitor C1, and the transistor MW are formed in this order from the bottom in the memory cell MC.

The transistor MR includes, for example, the conductor ME1 functioning as one of a source electrode and a drain electrode, the conductor ME2 functioning as the other of the source electrode and the drain electrode, the semiconductor SC1 functioning as the channel formation region, the insulator GI1 functioning as a gate insulating film, and the conductor ME4 functioning as a gate electrode.

The capacitor C1 includes, for example, the semiconductor SC1 and the conductor ME3 which function as one of a pair of electrodes, the conductor ME4 functioning as the other of the pair of electrodes, and the insulator GI1 functioning as a dielectric between the pair of electrodes.

The electrostatic capacitance value of the capacitor C1 can be increased by increasing a contact area between the conductor ME3 and the semiconductor SC1, in particular. Examples of the way of increasing the contact area include making the opening KK1 deeper and enlarging the opening area of the opening KK1 in the plan view. Another possible way of increasing the electrostatic capacitance value of the capacitor C1 may be using an insulating material with a high dielectric constant for the insulator GI1.

If the electrostatic capacitance value of the capacitor C1 is small, particularly if the parasitic capacitance value of the first terminal and the second terminal of the capacitor C1 is larger than the electrostatic capacitance value, the following consequences might appear: writing and reading in the memory cell MC slow down; the potential supplied to each of the gates of the transistor MW and the transistor MR becomes lower than a desired level; and the like. Thus, in the memory cell MC, the electrostatic capacitance value of the capacitor C1 is preferably greater than or equal to twice, further preferably greater than or equal to four times, still further preferably greater than or equal to eight times the parasitic capacitance value of the first terminal or the second terminal of the capacitor C1, for example.

The transistor MW includes, for example, the conductor ME5 functioning as one of a source electrode and a drain electrode, the conductor ME6 functioning as the other of the source electrode and the drain electrode, the semiconductor SC2 functioning as the channel formation region, the insulator GI2 functioning as a gate insulating film, and the conductor ME7 functioning as a gate electrode.

The structure of the memory cell MC might allow a transistor to be formed above the transistor MR and below the capacitor C1. The transistor is a transistor MD in FIG. 2B and FIG. 2C. The transistor MD includes, for example, the conductor ME2 functioning as one of a source electrode and a drain electrode, the conductor ME3 functioning as the other of the source electrode and the drain electrode, the semiconductor SC1 functioning as the channel formation region, the insulator GI1 functioning as a gate insulating film, and the conductor ME4 functioning as a gate electrode.

FIG. 1C shows an example of the case where the transistor MD is added to the circuit structure of the memory cell MC in FIG. 1A. In FIG. 1C, a first terminal of the transistor MD is electrically connected to the second terminal of the capacitor C1 and the wiring CL, a second terminal of the transistor MD is electrically connected to the wiring SL and the first terminal of the transistor MR, and a gate of the transistor MD is electrically connected to the first terminal of the capacitor C1, the second terminal of the transistor MW, and the gate of the transistor MR.

As illustrated in FIG. 2A to FIG. 2C, the transistor MD may be formed above the transistor MR and below the capacitor C1. However, the transistor MD has no effect on writing operation or reading operation of the memory cell MC in the case where the same signals are transmitted to the wiring CL and the wiring SL in FIG. 1C.

The memory cell that is the semiconductor device of one embodiment of the present invention may be the memory cell MC illustrated in FIG. 1C.

The conductor ME1 also functions as the wiring RBL, for example, and extends in the Y direction in FIG. 2A to FIG. 2C. The conductor ME2 also functions as the wiring SL, for example, and extends in the X direction in FIG. 2A to FIG. 2C. The conductor ME3 also functions as the wiring CL, for example, and extends in the X direction in FIG. 2A to FIG. 2C.

The conductor ME6 also functions as the wiring WBL, for example, and extends in the Y direction in FIG. 2A to FIG. 2C. The conductor ME7 also functions as the wiring WWL, for example, and extends in the X direction in FIG. 2A to FIG. 2C.

### <Structure Example of Memory Device>

Next, a structure example of a memory device including the memory cell MC in FIG. 1A or FIG. 1B is described.

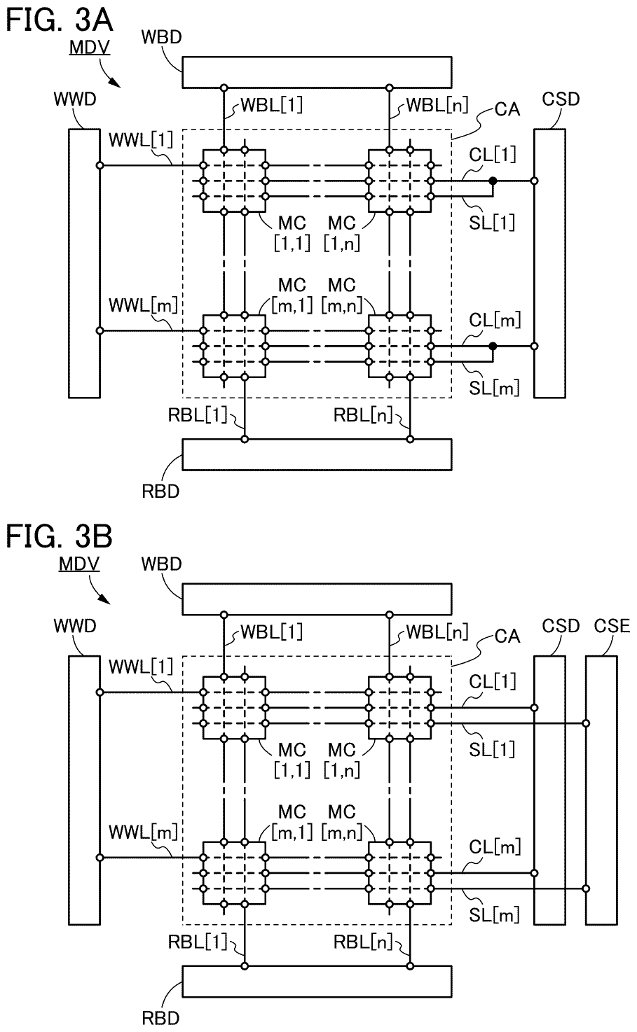

A memory device MDV illustrated in FIG. 3A is a memory device of one embodiment of the present invention and includes a cell array CA, a circuit WBD, a circuit WWD, a circuit CSD, and a circuit RBD.

The cell array CA includes a plurality of memory cells MC. Specifically, the plurality of memory cells MC are arranged in a matrix of m rows and n columns (m is an integer greater than or equal to 1 and n is an integer greater than or equal to 1) in the cell array CA. For example, a memory cell MC[1,1], a memory cell MC[m,1], a memory cell MC[1,n], and a memory cell MC[m,n] in the cell array CA are selectively illustrated in FIG. 3A.

In FIG. 3A, the memory cell MC located in the x-th row and the y-th column is denoted by MC[x,y].

The memory cell MC illustrated in FIG. 1A can be used as each of the memory cell MC[1,1] to the memory cell MC[m,n] illustrated in FIG. 3A.

In the cell array CA, for example, each of a wiring WWL[1] to a wiring WWL[m], which corresponds to the wiring WWL in FIG. 1A, extends in the row direction. In the cell array CA, for example, each of a wiring CL[1] to a wiring CL[m], which corresponds to the wiring CL in FIG. 1A, extends in the row direction. In the cell array CA, for example, each of a wiring SL[1] to a wiring SL[m], which corresponds to the wiring SL in FIG. 1, extends in the row direction.

In FIG. 3A, the wiring WWL extending in the x-th row is denoted by WWL[x]. Similarly, the wiring CL extending in the x-th row is denoted by CL[x]. Similarly, the wiring SL extending in the x-th row is denoted by SL[x].

In the cell array CA, for example, each of a wiring WBL[1] to a wiring WBL[n], which corresponds to the wiring WBL in FIG. 1A, extends in the column direction. In the cell array CA, for example, each of a wiring RBL[1] to a wiring RBL[n], which corresponds to the wiring RBL in FIG. 1A, extends in the column direction.

In FIG. 3A, the wiring WBL extending in the y-th column is denoted by WBL[y]. Similarly, the wiring RBL extending in the y-th column is denoted by RBL[y].

In FIG. 3A, the circuit WWD is electrically connected to the wiring WWL[1] to the wiring WWL[m]. The circuit CSD is electrically connected to the wiring CL[1] to the wiring CL[m]. The wiring CL[1] is electrically connected to the wiring SL[1], and the wiring CL[m] is electrically connected to the wiring SL[m]. The circuit WBD is, for example, electrically connected to a wiring WBL[1] to a wiring WBL[n]. The circuit RBD is electrically connected to the wiring RBL[1] to the wiring RBL[n].

The circuit WWD has a function of selecting the memory cells MC in the row where writing is performed in the cell array CA, for example. The circuit WWD has a function of, specifically, transmitting a selection signal to any one of the wiring WWL[1] to the wiring WWL[m] and transmitting a non-selection signal to the other wirings, for example. In the case where the write transistor included in the memory cell MC is an n-channel transistor, the selection signal is preferably a high-level potential and the non-selected signal is preferably a low-level potential.

The circuit CSD has a function of selecting the memory cells MC in the row where writing or reading is performed in the cell array CA, for example. Like the circuit WWD, the circuit CSD has a function of, specifically, transmitting a selection signal to any one of the wiring CL[1] to the wiring CL[m] and transmitting a non-selection signal to the other wirings, for example. In particular, data written to the memory cells MC is output from the memory cells MC selected by the circuit CSD to the wiring RBL as read data. In the case where the read transistor included in the memory cell MC is an n-channel transistor, the selection signal is preferably a high-level potential and the non-selected signal is preferably a low-level potential. The circuit CSD may have a function of supplying a fixed potential to the wiring CL[1] to the wiring CL[m], for example. The fixed potential can be, for example, a high-level potential, a low-level potential, a ground potential, or a negative potential.

In the structure of the memory device MDV in FIG. 3A, the wiring CL and the wiring SL are electrically connected to each other in the same row. Thus, the selection signal or the non-selection signal transmitted to the wiring CL is also transmitted to the wiring SL in the same row as the wiring CL by the circuit CSD.

The circuit WBD has a function of transmitting data for writing to the memory cell MC selected by the circuit WWD in the cell array CA, for example. Specifically, the circuit WBD transmits data for writing to each of the wiring WBL[1] to the wiring WBL[n], for example. Thus, the data for writing transmitted to each column is written to the memory cell MC in the row selected by the circuit WWD.

The circuit RBD has a function of reading the written data from the memory cells MC in the cell array CA, for example. Specifically, the memory cells MC in one row selected by the circuit CSD output read data to the wiring RBL[1] to the wiring RBL[n], and the circuit RBD obtains the read data from the wiring RBL[1] to the wiring RBL[n]. After that, the circuit RBD converts the read data into digital data or analog data and outputs the data to the outside of the circuit RBD.

Since the circuit RBD converts the read data into digital data or analog data, the circuit RBD preferably includes a current-voltage converter circuit, an analog-digital converter circuit, or a digital-analog converter circuit.

The structure of the memory device of one embodiment of the present invention is not limited to that of the memory device MDV illustrated in FIG. 3A. The memory device of one embodiment of the present invention can have a structure modified from the memory device MDV in FIG. 3A as appropriate. The memory device of one embodiment of the present invention may have a structure in which the wiring CL[1] and the wiring SL[1] are not electrically connected and the wiring CL[m] and the wiring SL[m] are not electrically connected as in the memory device MDV illustrated in FIG. 3B, for example.

In FIG. 3B, the memory device MDV includes a circuit CSE, for example. The circuit CSE is electrically connected to the wiring SL[1] to the wiring SL[m]. The circuit CSE has a function of selecting the memory cells MC in the row where reading is performed in the cell array CA, for example. Like the circuit WWD, the circuit CSE has a function of, specifically, transmitting a selection signal to any one of the wiring SL[1] to the wiring SL[m] and transmitting a non-selection signal to the other wirings, for example. In the case where the read transistor included in the memory cell MC is an n-channel transistor, the selection signal is preferably a high-level potential and the non-selected signal is preferably a low-level potential. The circuit CSE may have a function of supplying a fixed potential to the wiring SL[1] to the wiring SL[m], for example. The fixed potential can be, for example, a high-level potential, a low-level potential, a ground potential, or a negative potential.

### <<Structure Example of Cell Array>>

Next, structure examples of the cell array CA included in the memory device MDV in FIG. 3A and FIG. 3B are described.

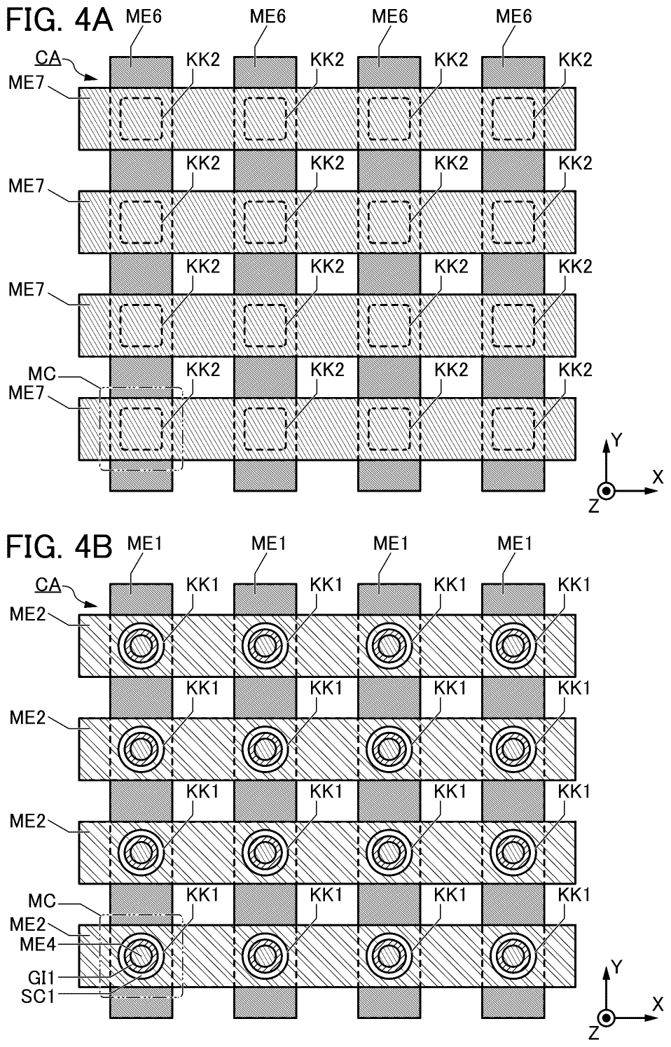

FIG. 4A and FIG. 4B are schematic plan views illustrating a structure example of the cell array CA. Specifically, the cell array CA in FIG. 4A selectively illustrates the conductor ME6, the conductor ME7, and the opening KK2; the cell array CA in FIG. 4B selectively illustrates the conductor ME1, the conductor ME2, and the materials (the conductor ME4, the semiconductor SC1, and the insulator GI1) in the inner part of opening KK1. That is, the schematic plan view in FIG. 4A illustrates a plurality of transistors MW arranged in a matrix in the cell array CA, and the schematic plan view in FIG. 4B illustrates a plurality of transistors MR arranged in a matrix in the cell array CA.

In the cell array CA illustrated in FIG. 4A, the conductor ME6 and the conductor ME7 extend to be in the directions substantially perpendicular to each other. The opening KK2 is formed in a region where the conductor ME6 and the conductor ME7 overlap with each other.

Similarly, in the cell array CA illustrated in FIG. 4B, the conductor ME1 and the conductor ME2 extend to be in the directions substantially perpendicular to each other. The opening KK1 is formed inside a region where the conductor ME1 and the conductor ME2 overlap with each other.

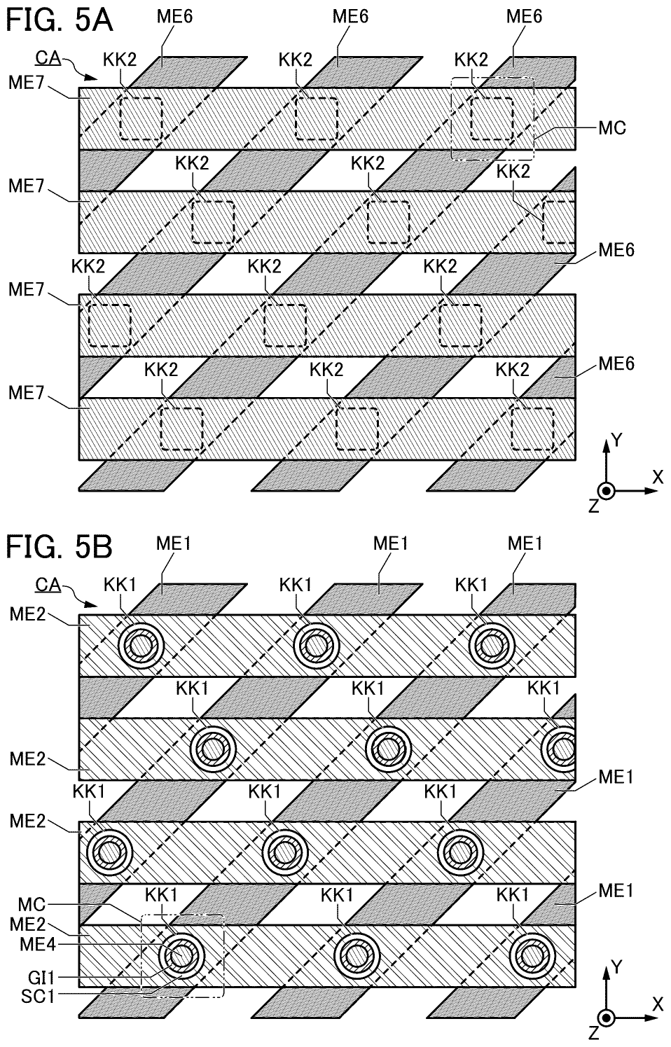

The structure example of the cell array CA in the memory device of one embodiment of the present invention is not limited to that in FIG. 4A and FIG. 4B. The cell array CA in the memory device of one embodiment of the present invention may have a structure example in which, for example, the conductor ME6 and the conductor ME7 are not substantially perpendicular to each other and the conductor ME1 and the conductor ME2 are not substantially perpendicular to each other, as illustrated in FIG. 5A and FIG. 5B. For example, the angle formed between the conductor ME6 and the conductor ME7 can be greater than 0° and less than or equal to 60°, and the angle formed between the conductor ME1 and the conductor ME2 can be greater than 0° and less than or equal to 60°. Note that the conductor ME1 and the conductor ME6 preferably extend in the same direction, and the conductor ME2 and the conductor ME7 preferably extend in the same direction.

With the use of the structure illustrated in FIG. 5A and FIG. 5B for the cell array CA, a larger number of memory cells MC can be arranged in the cell array CA in some cases. In this case, the storage density of the memory device MDV can be increased in some cases.

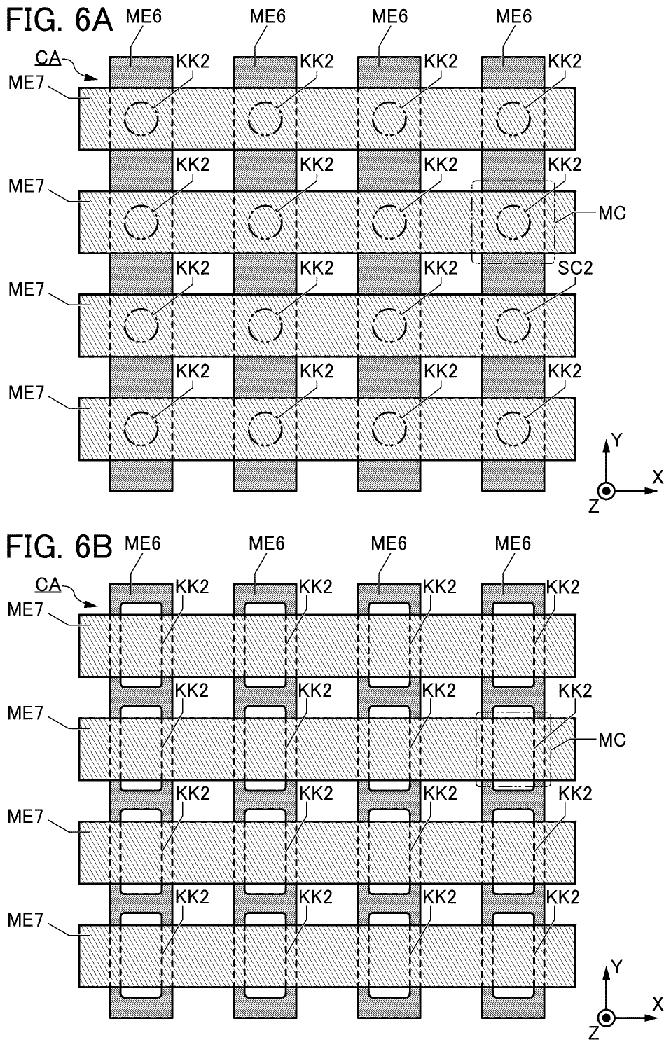

Although the opening KK2 has a quadrangular shape with rounded corners in the plan views in FIG. 4A and FIG. 5A, it may have a shape of circle (including a perfect circle and an ellipse) or a shape close to a circle as illustrated in FIG. 6A. The opening KK2 may be provided, as illustrated in FIG. 6B, not only in a region where the conductor ME6 and the conductor ME7 overlap with each other, but also in a region that overlaps not with the conductor ME7 but with the conductor ME6, in the plan view. Although the opening KK2 has a quadrangular shape with rounded corners as an example in the plan view in FIG. 6B, the opening KK2 may have a shape different from the quadrangular shape.

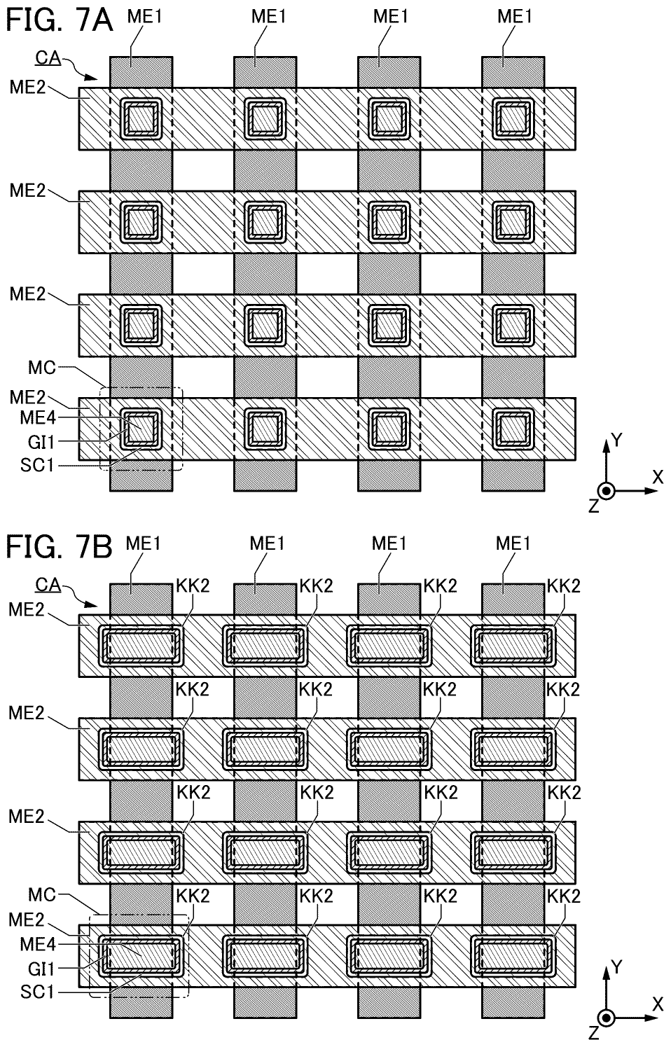

Although the opening KK1 has a circular shape in the plan views in FIG. 4B to FIG. 5B, the opening KK1 may have a quadrangular shape with rounded corners as illustrated in FIG. 7A. The opening KK1 may be provided, as illustrated in FIG. 7B, not only in a region where the conductor ME1 and the conductor ME2 overlap with each other, but also in a region that overlaps not with the conductor ME1 but with the conductor ME2, in the plan view. Although the opening KK1 has a quadrangular shape with rounded corners as an example in the plan view in FIG. 7B, the opening KK2 may have a shape different from the quadrangular shape.

### <Operation Example of Semiconductor Device>

Next, an operation example of the memory cell MC in FIG. 1A (FIG. 2A to FIG. 2C) is described.

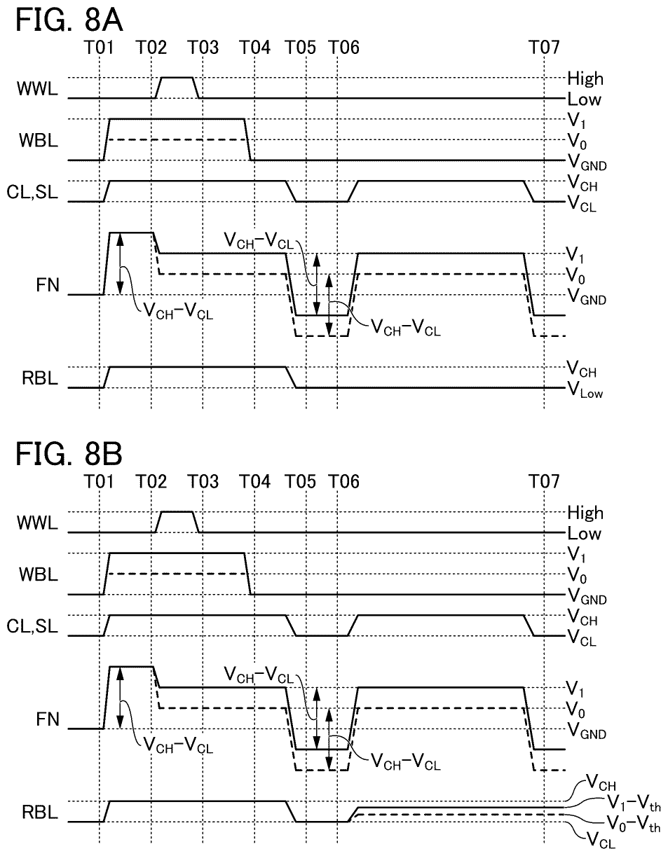

FIG. 8A is a timing chart showing the operation example of the memory cell MC in FIG. 1A. The timing chart in FIG. 8A shows changes in the potentials of the wiring WWL, the wiring WBL, the wiring CL, the wiring SL, the wiring RBL, and the node FN in a period from Time T01 to Time T07 and around the period. In particular, in the period from Time T01 to Time T05, a writing operation is performed in the memory cell MC, and in the period from Time T06 to Time T07, a reading operation is performed in the memory cell MC.

It is assumed that the wiring WWL in FIG. 1A is electrically connected to the circuit WWD illustrated in FIG. 3. It is assumed that the wiring WBL in FIG. 1A is electrically connected to the circuit WBD illustrated in FIG. 3. It is assumed that the wiring CL in FIG. 1A is electrically connected to the circuit CSD illustrated in FIG. 3. It is assumed that the wiring RBL in FIG. 1A is electrically connected to the circuit RBD illustrated in FIG. 3.

The wiring CL and the wiring SL are assumed to be electrically connected to each other as illustrated in FIG. 3A. Accordingly, the potential change of the wiring CL is assumed to be equal to the potential change of the wiring SL.

Before Time T01, the circuit WWD supplies a low-level potential (denoted as Low in FIG. 8A) to the wiring WWL. The circuit WBD supplies a ground potential VGND to the wiring WBL. The circuit CSD supplies a potential V_{CL} to the wiring CL. The circuit RBD supplies V_{Low} as a low-level potential to the wiring RBL.

Note that V_{CL} may be the same potential as the ground potential VGND. Furthermore, V_{Low} may be a potential equal to V_{CL} or the ground potential VGND.

The potential of the node FN is assumed to be the ground potential VGND before Time T01.

The low-level potential from the wiring WWL is supplied to the gate of the transistor MW. Accordingly, the transistor MW is turned off and the node FN is brought into a floating state.

### <<Writing Operation>>

In the period from Time T01 to Time T02, the circuit WBD transmits data for writing to the wiring WBL. The potential of the wiring WBL at this time is assumed to become the potential V₁ or V₀ corresponding to the data for writing. In addition, V₁ is assumed to be a potential higher than V₀.

In the period from Time T01 to Time T04 in the timing chart in FIG. 8A, the potential of the wiring WBL that is V₁ is indicated by a solid line, and the potential of the wiring WBL that is V₀ is indicated by a dashed line.

In the period from Time T01 to Time T02, the circuit CSD supplies a potential VCH to the wiring CL. Note that VCH is assumed to be a potential higher than V_{CL}.

Since the node FN is in a floating state, the change in the potential of the wiring CL from V_{CL} to VCH allows capacitive coupling of the capacitor C1 to cause a change in the potential of the node FN depending on the amount of the change in the potential of the wiring CL. Here, the potential of the node FN is assumed to become V_{GND}+(V_{CH}−V_{CL}). This corresponds to the case where the capacitive coupling coefficient in the periphery of the node FN is 1.

In the period from Time T02 to Time T03, the circuit WWD supplies a high-level potential (denoted as High in FIG. 8A) to the wiring WWL. Accordingly, the transistor MW is turned on, establishing electrical continuity between the wiring WBL, the first terminal of the capacitor C1, and the gate of the transistor MR (node FN). This causes the flow of electric charge between the node FN and the wiring WBL, so that the potential of the node FN is ideally equal to the potential supplied to the wiring WBL (V₁ or V₀).

In the period after Time T02 in the timing chart in FIG. 8A, the potential of the node FN in the case where V₁ is written from the wiring WBL to the node FN is indicated by a solid line and that in the case where V₀ is written from the wiring WBL to the node FN is indicated by a dashed line.

After the circuit WWD supplies the high-level potential to the wiring WWL in the period from Time T02 to Time T03, the circuit WWD supplies a low-level potential to the wiring WWL. Accordingly, the transistor MW is turned off and the node FN is brought into a floating state. Thus, V₁ or V₀ is retained in the first terminal of the capacitor C1 and the gate of the transistor MR (node FN) in the memory cell MC.

In the period from Time T03 to Time T04, the circuit WBD supplies the ground potential V_{GND} to the wiring WBL.

In the period from Time T04 to Time T05, the circuit CSD supplies V_{CL} to the wiring CL.

Since the node FN is in a floating state, the change in the potential of the wiring CL from V_{CH} to V_{CL} allows capacitive coupling of the capacitor C1 to cause a change in the potential of the node FN depending on the amount of change in the potential of the wiring CL. Here, the potential of the node FN is assumed to become V₁−(V_{CH}−V_{CL}) or V₀−(V_{CH}−V_{CL}).

In the period from Time T04 to Time T05, the circuit RBD supplies V_{Low} to the wiring RBL.

Accordingly, the gate-source voltage (V₁−V_{CH}+V_{CL}−V_{Low} or V₀−V_{CH}+V_{CL}−V_{Low}) of the transistor MR is assumed to become lower than the threshold voltage of the transistor MR. That is, the transistor MR is turned off.

In the period from Time T01 to Time T04, the circuit RBD supplies the potential V_{CH} to the wiring RBL. By setting the potential of the wiring RBL to V_{CH}, a voltage (source-drain voltage) between the first terminal (wiring SL) and the second terminal (wiring RBL) of the transistor MR can be set to 0 V. This stops the flow of current between the source and the drain of the transistor MR regardless of the potential of the gate, which can reduce power consumption during the writing operation in the memory cell MC.

Through the above operation, data is written to the memory cell MC.

### <<Reading Operation>>

In the period from Time T06 to Time T07, the circuit CSD supplies V_{CH} to the wiring CL.

Also in the period from Time T06 to Time T07, since the node FN is in a floating state, the change in the potential of the wiring CL from V_{CL} to V_{CH} allows capacitive coupling of the capacitor C1 to cause a change in the potential of the node FN depending on the amount of change in the potential of the wiring CL. Here, the potential of the node FN is assumed to become V₁ or V₀.

Since V_{CH} is supplied to the wiring CL, the potential of the wiring SL also becomes V_{CH}. Thus, the potential V_{CH} from the wiring SL is supplied to the first terminal of the transistor MR. The potential of the gate of the transistor MR is V₁ or V₀.

In the period from Time T06 to Time T07, the circuit RBD supplies the low-level potential V_{Low} to the wiring RBL. Consequently, the gate-source voltage of the transistor MR becomes V₁-V_{Low} or V₀-V_{Low} and drain current corresponding to the gate-source voltage flows between the source and the drain of the transistor MR, so that the drain current from the wiring SL flows to the circuit RBD through the wiring WBL.

The circuit RBD is capable of reading data written to the memory cell MC on the basis of the amount of drain current flowing from the wiring WBL. Specifically, in the case where the circuit RBD includes a current-voltage converter circuit, for example, the circuit RBD can process the read data as a voltage by making the current-voltage converter circuit convert the amount of drain current into the voltage.

In the case where the memory cell MC has the structure in FIG. 1C, the potential of the first terminal of the transistor MD is supplied by the wiring CL and the potential of the second terminal of the transistor MD is supplied by the wiring SL in the period from Time T01 to Time T07. In other words, since the voltage between the first terminal and the second terminal of the transistor MD becomes 0 V, electric charge does not flow between the first terminal and the second terminal of the transistor MD regardless of the potential of the gate of the transistor MD. Moreover, even when a voltage is generated between the first terminal and the second terminal of the transistor MD due to the parasitic resistance of one or the other of the wiring SL and the wiring CL, electric charge is leveled between the wiring SL and the wiring CL through the transistor MD as long as the transistor MD is in an on state, which acts to make the wiring SL and the wiring CL have the same potential. Thus, the voltage between the first terminal and the second terminal of the transistor MD becomes 0 V, which stops the flow of electric charge between the first terminal and the second terminal of the transistor MD. That is, when the memory cell MC has the structure in FIG. 1C, the operation method can be the same as that in the structure in FIG. 1A. The operation method example of the semiconductor device of one embodiment of the present invention is not limited to the above. The above operation example may be modified as appropriate as the operation example of the semiconductor device of one embodiment of the present invention.

In the above reading operation, the circuit RBD supplies V_{Low} to the wiring RBL and reads data retained in the memory cell MC with the use of the amount of current flowing through the wiring RBL, which is the drain current of the transistor MR in the memory cell MC; however, the data retained in the memory cell MC may be read by a reading operation using a different method, for example.

FIG. 8B is a timing chart showing an operation example of the memory cell MC, which is different from that in FIG. 8A. The timing chart in FIG. 8B is different from the timing chart in FIG. 8A in the reading operation (after Time T06). In FIG. 8B, V_{Low} and V_{CL} are equal potentials.

In the reading operation in the timing chart in FIG. 8B, the circuit RBD precharges the wiring RBL with the potential V_{CL} in the period from Time T05 to Time T06. After that, electrical continuity between the circuit RBD and the wiring RBL is broken so that the wiring RBL is brought into a floating state.

In the period from Time T06 to Time T07, V_{CH} is supplied to the wiring CL by the circuit CSD and accordingly the potential of the node FN becomes V₁ or V₀, as in the period from Time T06 to Time T07 in the timing chart in FIG. 8A.

At this time, the transistor MR is turned on, and electric charge flows from the wiring SL to the wiring RBL through the transistor MR. Since the wiring RBL is in a floating state, the potential of the wiring RBL increases until the gate-source voltage of the transistor MR becomes equal to the threshold voltage of the transistor MR (until the transistor MR is turned off). The potential of the wiring RBL reaches V₁-Vₜₕ or V₀-Vₜₕ at last, for example, when the threshold voltage of the transistor MR is set to Vₜₕ.

After that, the circuit RBD is capable of reading the data retained in the memory cell MC by referring to the potential of the wiring RBL.

Although writing of binary data to the memory cell MC or reading of binary data from the memory cell MC is described in this operation example, the data retained in the memory cell MC may be data with three values or more, four values or more, or eight values or more. Alternatively, the data retained in the memory cell MC may be an analog potential (analog data).

Using the semiconductor device described in this embodiment as the memory cell included in the memory device can reduce the area of the memory cell. Furthermore, the reduction in the area of the memory cell can increase the integration degree of the memory cells, leading to the higher storage density of the memory cells. Moreover, increasing the contact area between the conductor ME3 and the semiconductor SC1 enlarges the electrode plate area of the capacitor C1, which increases the electrostatic capacitance value of the capacitor C1 included in the memory cell. The increased electrostatic capacitance value of the capacitor C1 facilitates retention of an analog voltage (multilevel data) in the memory cell, leading to an increase in the storage capacity of the memory cell. The increase in the electrostatic capacitance value of the capacitor C1 extends the data retention time of the memory cell.

The structure described in this embodiment can be combined as appropriate with any of the other structures described in this embodiment. For example, the configurations, structures, methods, and the like described in this embodiment can be used in an appropriate combination with any of the other configurations, structures, methods, and the like described in this embodiment.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 2

In this embodiment, an example of a method for manufacturing the memory cell MC in FIG. 2A to FIG. 2C described in Embodiment 1 and a modification example of the structure of the memory cell MC in FIG. 2A to FIG. 2C are described.

### <Example of Manufacturing Method>

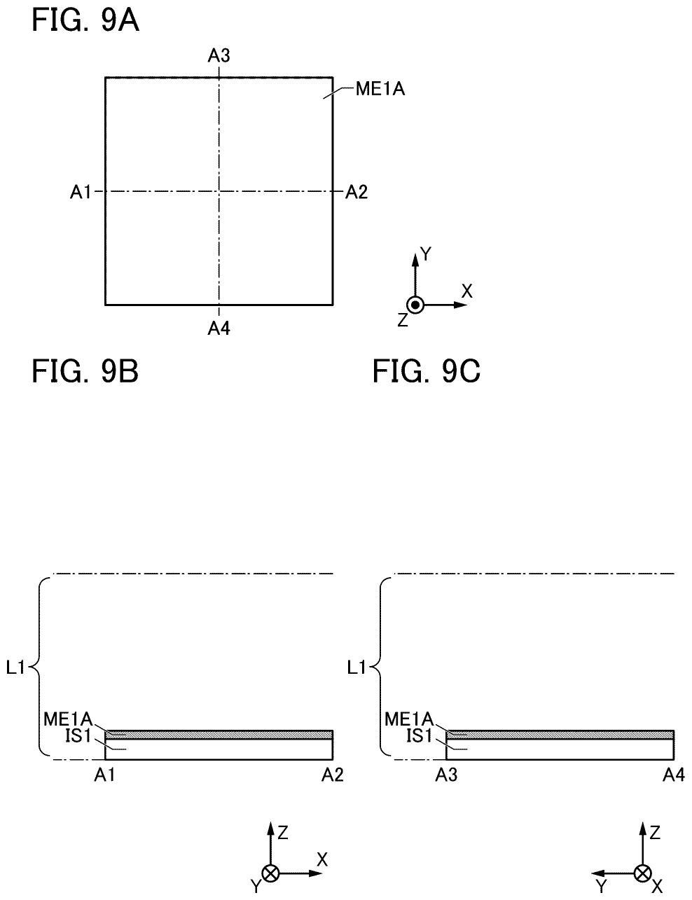

The example of a method for manufacturing the memory cell MC in FIG. 2A to FIG. 2C is described with reference to FIG. 9A to FIG. 32C.

In each of FIG. 9A to FIG. 32C, A of each drawing illustrates a schematic plan view. Moreover, B of each drawing is a schematic cross-sectional view corresponding to a portion along the dashed-dotted line A1-A2 illustrated in A of each drawing, and is also a schematic cross-sectional view in the X direction. Furthermore, C of each drawing is a schematic cross-sectional view illustrating a portion along the dashed-dotted line A3-A4 illustrated in A of the corresponding drawing, and is also a schematic cross-sectional view in the Y direction. Note that for clarity of the drawing, some components are not illustrated in the schematic plan view of A of each drawing.

Hereinafter, an insulating material for forming an insulator, a conductive material for forming a conductor, or a semiconductor material for forming a semiconductor can be deposited by a deposition method such as a sputtering method, a CVD (Chemical Vapor Deposition) method, an MBE (Molecular Beam Epitaxy) method, a PLD (Pulsed Laser Deposition) method, or an ALD (Atomic Layer Deposition) method as appropriate.

First, a method for manufacturing the layer L1 of the memory cell MC is described.

First, a substrate (not illustrated) is prepared, and the insulator IS1 and the conductive film ME1A are formed in this order over the substrate (see FIG. 9A to FIG. 9C).

As the substrate, a semiconductor substrate (e.g., a single crystal substrate containing silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate. Examples of the glass substrate include barium borosilicate glass, aluminoborosilicate glass, and soda lime glass. As examples of the flexible substrate, the attachment film, and the base film, the following is given. Examples include plastic typified by polyethylene terephthalate (PET), polyethylene naphthalate (PEN), polyethersulfone (PES), and polytetrafluoroethylene (PTFE). Another example is a synthetic resin such as an acrylic resin. Other examples are polypropylene, polyester, polyvinyl fluoride, and polyvinyl chloride. Other examples include polyamide, polyimide, aramid, an epoxy resin, an inorganic vapor deposition film, and paper. Note that in the case where the manufacturing process of a display apparatus DSP involves heat treatment, a highly heat-resistant substrate is preferably selected as the substrate. Alternatively, these substrates provided with elements may be used. Examples of the element provided for the substrate include a capacitor, a resistor, a switching element, a light-emitting element, and a storage element.

The insulator IS1 functions as an interlayer film, for example. Thus, an insulating material with a low dielectric constant is preferably used for the insulator IS1. The use of an insulating material with a low dielectric constant for the interlayer film can reduce the parasitic capacitance between wirings.

For the insulator IS1, silicon oxide, silicon oxynitride, silicon nitride oxide, or silicon nitride may be used, for example. For the insulator IS1, for example, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for example, a resin can be used for the insulator IS1. A material combined with any of the above insulating materials as appropriate may be used for the insulator IS1.

The conductor ME1 is formed over the insulator IS1 in a later manufacturing step. For this reason, in order to prevent oxidation of the conductor ME1, for example, silicon nitride is preferably used for the insulator IS1 as a barrier insulating film that inhibits diffusion of oxygen.

The conductive film ME1A is a film to be the conductor ME1 (wiring RBL) in a later step. Part of the conductor ME1 also functions as one of a source electrode and a drain electrode of the transistor MR. Thus, a material having high conductivity is preferably used for the conductive film ME1A.

For the conductive film ME1A, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum or an alloy containing two or more selected from the above metal elements as components or an alloy combining two or more selected from the above metal elements. Alternatively, for the conductive film ME1A, for example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. As the conductor, a semiconductor having high electrical conductivity, typified by polycrystalline silicon containing an impurity element (e.g., phosphorus or arsenic), or silicide (e.g., nickel silicide) may be used.

A plurality of conductive films formed using any of the above materials may be stacked. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

The conductor ME1 may include a first conductor and a second conductor surrounded by the first conductor, for example. For the first conductor, titanium, titanium nitride, tantalum, tantalum nitride, ruthenium, or ruthenium oxide, which is a conductive material having a function of inhibiting diffusion of oxygen, may be used. For the second conductor, a conductive material containing tungsten, copper, or aluminum, which has high conductivity, as its main component may be used. When the second conductor is surrounded by the first conductor, oxidation of the first conductor and the resulting reduction in conductivity can be prevented.

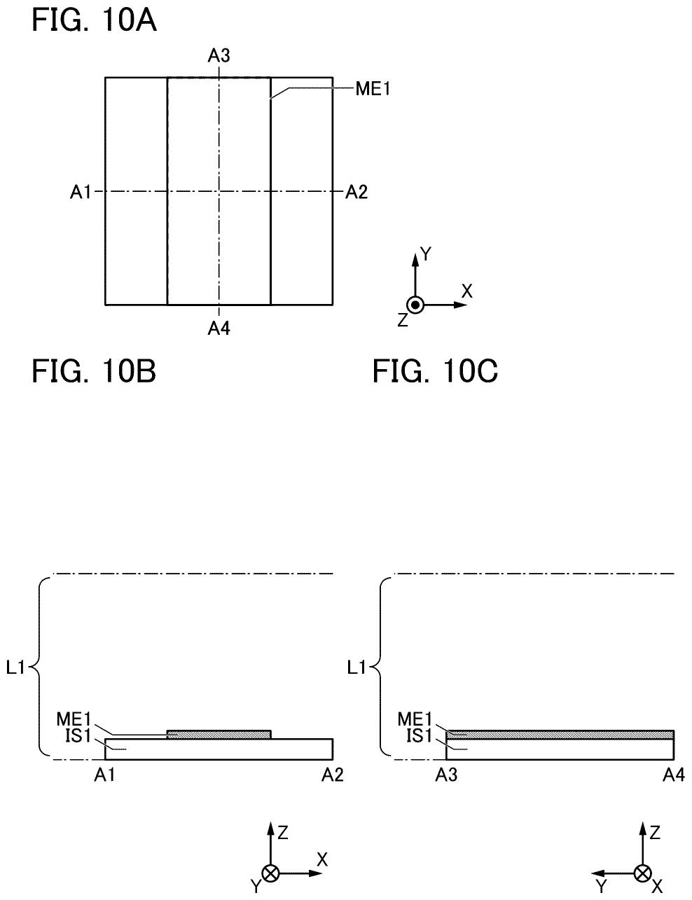

Next, the conductive film ME1A is processed into a belt-like shape by a lithography method to form the conductor ME1 (see FIG. 10A to FIG. 10C). In particular, the conductor ME1 is formed to extend in a direction parallel to the dashed-dotted line A3-A4 (Y direction). A dry etching method or a wet etching method can be employed for the above processing, and processing by a dry etching method is suitable for microfabrication.

In a lithography method, first, a resist is exposed to light through a mask. Next, a region exposed to light is removed or left using a developing solution, so that a resist mask is formed. Then, etching treatment through the resist mask is performed, whereby a conductor, a semiconductor, an insulator, or the like can be processed into a desired shape. The resist mask may be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the conductive film ME1A, a resist mask is formed thereover, and then the hard mask material is etched. The etching of the conductive film ME1A and the like may be performed after or without removal of the resist mask. In the latter case, the resist mask sometimes disappears during the etching. The hard mask may be removed by etching after the etching of the conductive film ME1A and the like. The hard mask does not need to be removed when the hard mask material does not affect the following process or can be utilized in the following process.

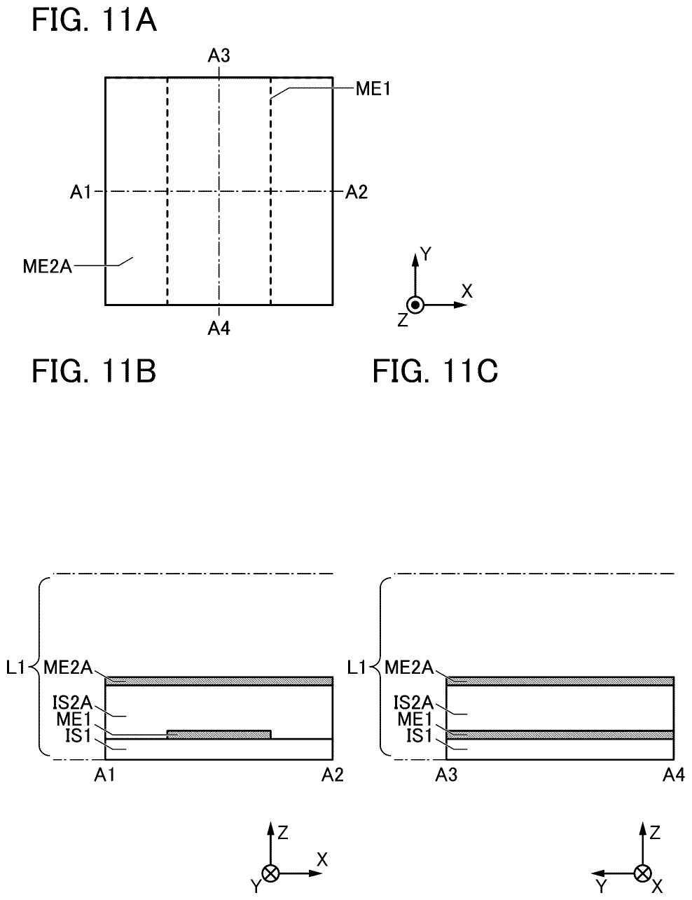

Next, an insulating film IS2A is formed over the conductor ME1 (see FIG. 11A to FIG. 11C). The insulating film IS2A can be formed by a film formation method such as a sputtering method, a CVD method, an MBE method, a PLD method, or an ALD method, for example. After the insulating film IS2A is formed, planarization treatment such as a CMP method may be performed on the insulating film IS2A to planarize the top surface of the insulating film IS2A.

The insulating film IS2A is a film to be the insulator IS2 in a later step. The insulator IS2 functions as an interlayer film, for example. The insulator IS2 preferably includes an insulating material with a low dielectric constant. The use of an insulating material with a low dielectric constant for the interlayer film can reduce the parasitic capacitance between wirings.

Any of the materials that can be used for the insulator IS1 can be used as the insulating film IS2A, for example. In particular, in the case where the semiconductor SC1 formed in a later step is a metal oxide functioning as an oxide semiconductor, for example, silicon oxide, silicon oxynitride, and porous silicon oxide are preferably used for the insulating film IS2A. These materials are capable of easily forming a region containing oxygen that is released by heating, so that the released oxygen can be supplied to the metal oxide. This reduces the carrier concentration of the metal oxide at the interface of the semiconductor SC1 in contact with the insulator IS2 and in the vicinity of the interface, whereby the interface of the semiconductor SC1 and the vicinity of the interface are i-type or substantially i-type. Accordingly, the interface of the semiconductor SC1 and the vicinity of the interface function as the channel formation region of the transistor MR.

Next, a conductive film ME2A is formed over the insulating film IS2A (see FIG. 11A to FIG. 11C).

The conductive film ME2A is a film to be the conductor ME2 (wiring SL) in a later step. Part of the conductor ME2 also functions as one of a source electrode and a drain electrode of the transistor MR. Thus, a material having high conductivity is preferably used for the conductive film ME2A.

A material that is usable for the conductor ME1 can be used for the conductive film ME2A, for example.

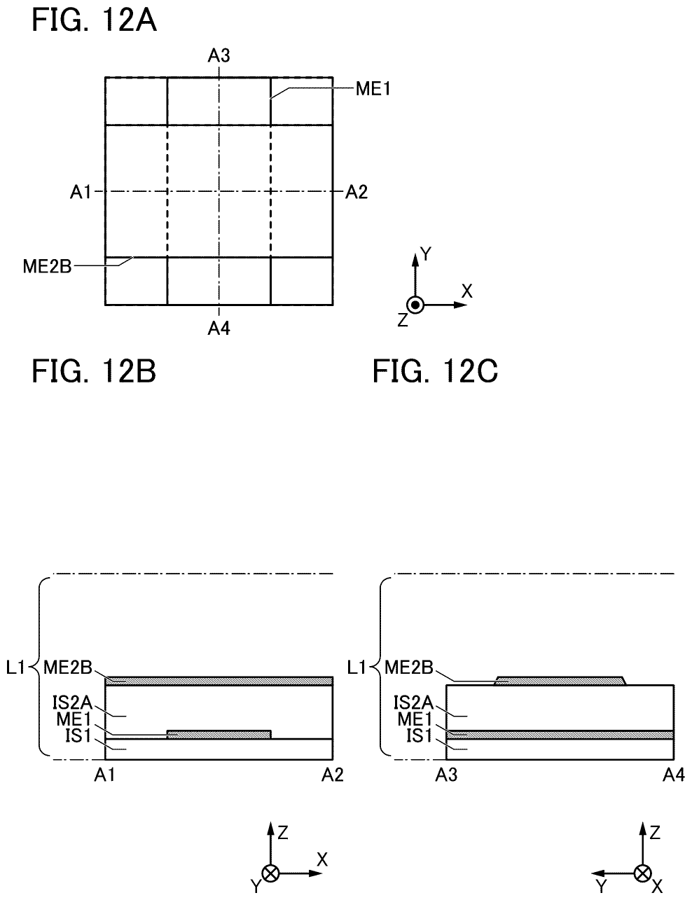

Next, the conductive film ME2A is processed into a belt-like shape by a lithography method to form a conductive film ME2B (see FIG. 12A to FIG. 12C). Specifically, the conductive film ME2B is formed to extend in the direction parallel to the dashed-dotted line A1-A2 (X direction) and to overlap with the conductor ME1. The lithography method described with reference to FIG. 10A to FIG. 10C can be referred to for the lithography method.

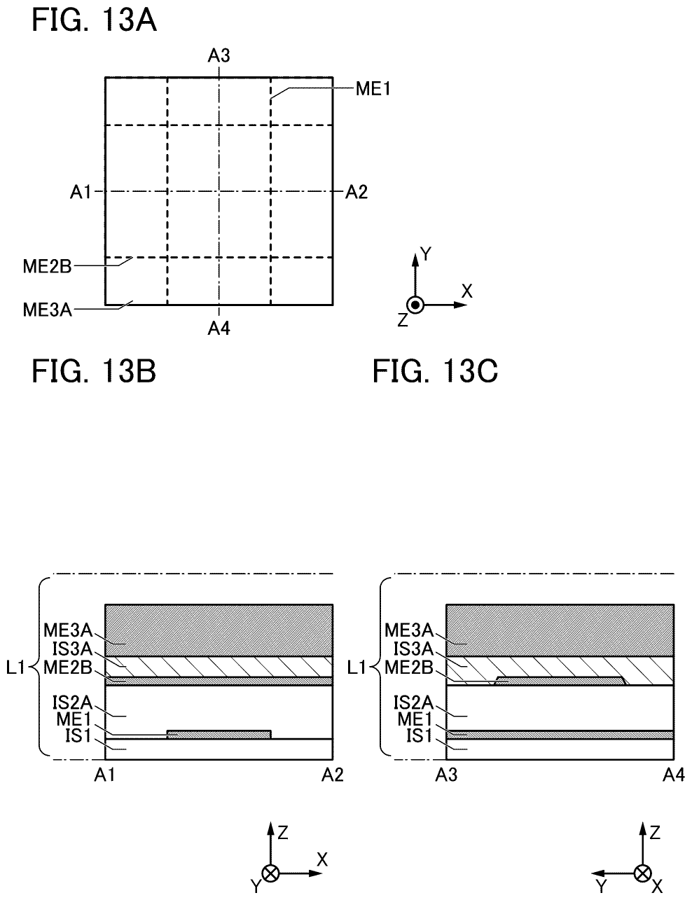

Next, an insulating film IS3A is formed over the conductor ME2B (see FIG. 13A to FIG. 13C). The insulating film IS3A can be formed by a film formation method such as a sputtering method, a CVD method, an MBE method, a PLD method, or an ALD method, for example. After the insulating film IS3A is formed, planarization treatment such as a CMP method may be performed on the insulating film IS3A to planarize the top surface of the insulating film IS3A.

The insulating film IS3A is a film to be the insulator IS3 in a later step. The insulator IS3 functions as an interlayer film, for example. The insulator IS3 preferably includes an insulating material with a low dielectric constant. The use of an insulating material with a low dielectric constant for the interlayer film can reduce the parasitic capacitance between wirings.

Any of the materials that can be used for the insulator IS1 can be used as the insulating film IS3A, for example.

The insulating film IS3A may include an impurity against the semiconductor SC1 (described later in detail) in order to reduce the resistance between the interface of the semiconductor SC1 in contact with the insulator IS3 and the vicinity of the interface. The insulating film IS3A may include an impurity such as water, hydrogen, nitrogen, or a nitride in order to reduce the resistance of an In-M-Zn oxide, for example, in the case where the semiconductor SC1 is a metal oxide such as an In-M-Zn oxide.

In the case where the semiconductor SC1 is a material containing silicon, for example, the insulating film IS3A preferably includes an impurity (e.g., an element or an ion) that is to diffuse into the silicon. As the impurity, an n-type impurity (donor) such as phosphorus or arsenic can be used, for example. Alternatively, a p-type impurity (acceptor) such as boron, aluminum, or gallium can be used as the impurity, for example.

Next, a conductive film ME3A is formed over the conductive film IS3A (see FIG. 13A to FIG. 13C).

The conductive film ME3A is a film to be the conductor ME3 (wiring CL) in a later step. Part of the conductor ME3 also functions as the one of the pair of electrodes of the capacitor C1. Thus, a material having high conductivity is preferably used for the conductive film ME3A.

A material that is usable for the conductor ME1 can be used for the conductive film ME3A, for example.

The conductive film ME3A may include an impurity against the semiconductor SC1 (described later in detail) in order to reduce the resistance between the interface of the semiconductor SC1 in contact with the conductor ME3 and the vicinity of the interface. The conductive film ME3A may include an impurity such as water, hydrogen, nitrogen, or a nitride in order to reduce the resistance of an In-M-Zn oxide, for example, in the case where the semiconductor SC1 is a metal oxide such as an In-M-Zn oxide. In that case, for the conductive film ME3A, for example, a metal film of aluminum, ruthenium, titanium, tantalum, tungsten, chromium, or the like, a nitride film of an Al—Ti nitride, titanium nitride, or the like, or an oxide film of an indium tin oxide, an In-M-Zn oxide, or the like can be used.

In the case where the semiconductor SC1 is a material containing silicon, for example, the conductive film ME3A preferably includes an impurity (e.g., an element or an ion) that is to diffuse into the silicon. As the impurity, an n-type impurity (donor) such as phosphorus or arsenic can be used, for example. Alternatively, a p-type impurity (acceptor) such as boron, aluminum, or gallium can be used as the impurity, for example. For the conductive film ME3A, a material that is capable of forming a metal silicide with silicon contained in the semiconductor SC1 may be used. Examples of the material are nickel, cobalt, molybdenum, tungsten, and titanium. Alternatively, a material having high conductivity may be used for the conductive film ME3A. Specific examples of the material having high conductivity include aluminum, copper, and silver. Alternatively, a material having high heat resistance may be used for the conductive film ME3A. Specific examples of the material having high heat resistance include titanium, molybdenum, tungsten, and tantalum.

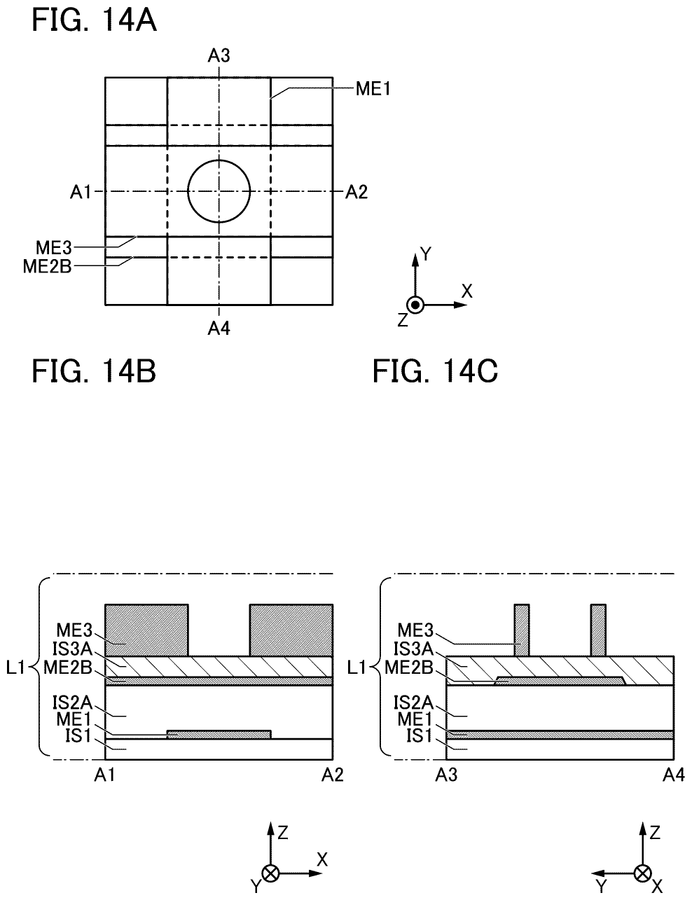

Next, the conductive film ME3A is processed into a belt-like shape including an opening by a lithography method, so that the conductor ME3 is formed. Specifically, the opening is formed in a region where the conductor ME1 and the conductive film ME2B overlap with each other (see FIG. 14A to FIG. 14C). Note that the opening is formed in a region where the opening KK1 described in Embodiment 1 is positioned. The conductor ME3 is formed to extend in a direction parallel to the dashed-dotted line A1-A2 (X direction). The lithography method described with reference to FIG. 10A to FIG. 10C can be referred to for the lithography method.

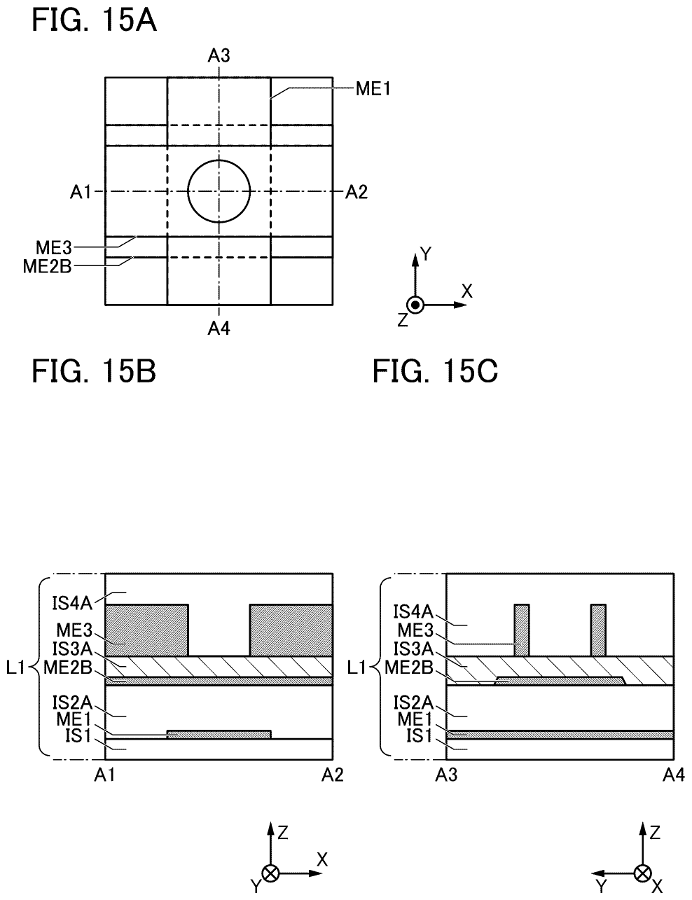

Next, an insulating film IS4A is formed over the conductor ME3 and the insulator IS3A (see FIG. 15A to FIG. 15C). The insulating film IS4A can be formed by a film-formation method such as a sputtering method, a CVD method, an MBE method, a PLD method, or an ALD method, for example.

The insulating film IS4A is a film to be the insulator IS4 in a later step. The insulator IS4 functions as an interlayer film, for example. The insulator IS4 preferably includes an insulating material with a low dielectric constant. The use of an insulating material with a low dielectric constant for the interlayer film can reduce the parasitic capacitance between wirings.

Any of the materials that can be used for the insulator IS1 can be used as the insulating film IS4A, for example.

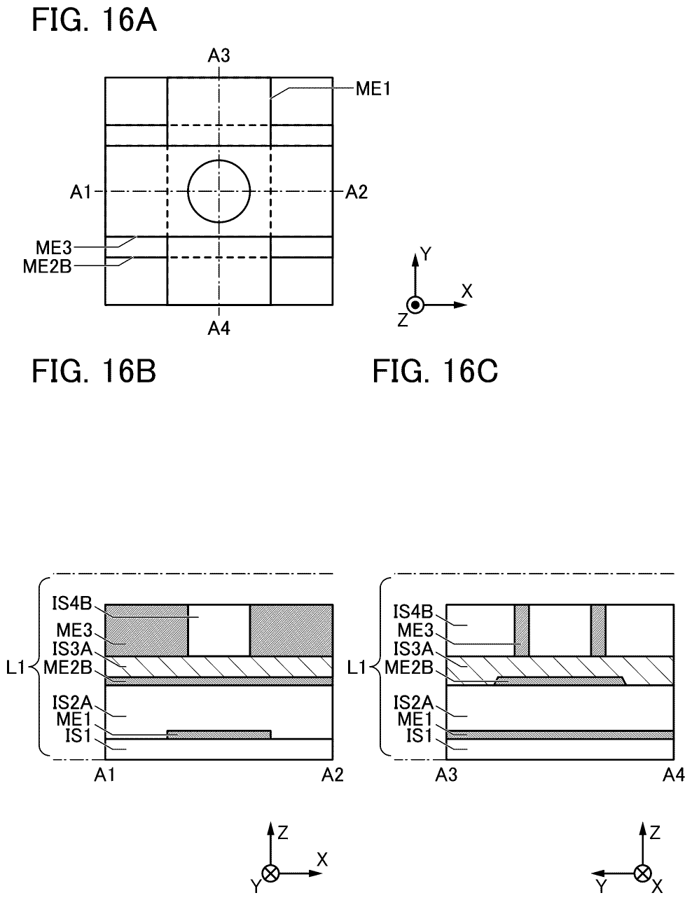

Next, planarization treatment such as a CMP method is performed to polish the insulating film IS4A until the conductor ME3 is exposed. Accordingly, an insulating film IS4B is formed to be embedded in a region of the conductive film ME3A (including the opening described with reference to FIG. 14A to FIG. 14C) that is removed in the step in FIG. 14A to FIG. 14C (see FIG. 16A to FIG. 16C). That is, the insulating film IS4B is provided in contact with a side surface of the conductor ME3 and the top surface of the insulating film IS3A.

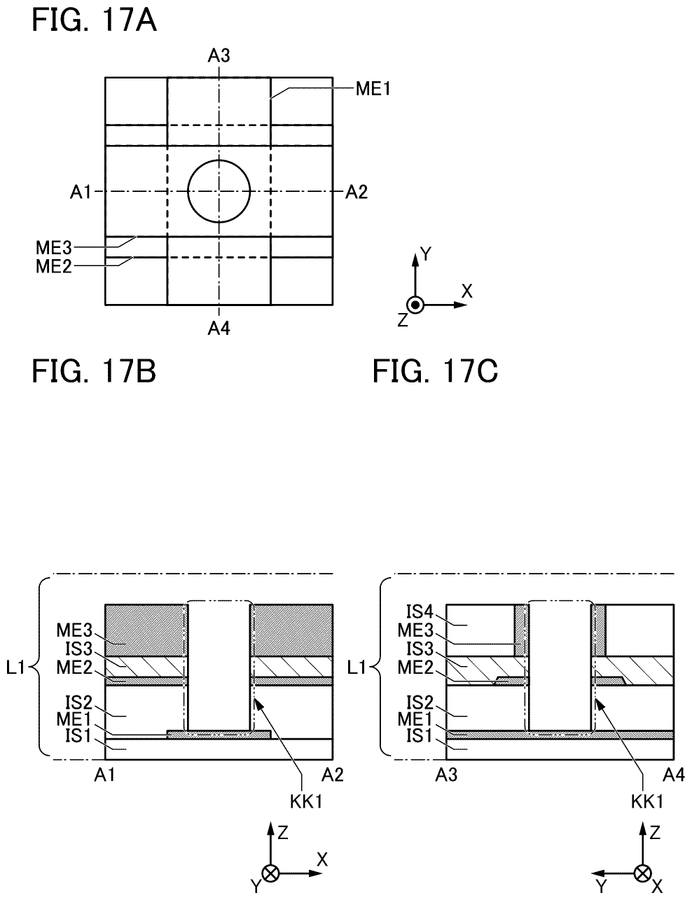

Next, the insulating film IS2A, the conductive film ME2B, the insulating film IS3A, and the insulating film IS4B are processed by a lithography method, thereby forming the insulator IS2, the conductor ME2, and the insulator IS3, which include the opening KK1, and the insulator IS4 (see FIG. 17A to FIG. 17C). Specifically, the opening KK1 is formed in a region overlapping with the opening illustrated in FIG. 14A to FIG. 14C. Thus, part of the conductor ME3A may be removed by this lithography method. A dry etching method or a wet etching method can be employed for the above processing, and processing by a dry etching method is suitable for microfabrication. The insulating film IS2A, the conductive film ME2B, the insulating film IS3A, and the insulating film IS4B may be processed under different conditions.

In FIG. 17A to FIG. 17C, the side surface of the opening KK1 (the side surfaces of the insulator IS2, the conductor ME2, the insulator IS3, and the conductor ME3) is perpendicular to the X-Y plane, whereby the memory cells MC can be reduced in volume and arranged at a higher density.

The side surface of the opening KK1 is perpendicular to the X-Y plane in FIG. 17A to FIG. 17C but may have a tapered shape with a substantially vertical taper angle. Specifically, for example, the side surfaces of the insulator IS2, the conductor ME2, the insulator IS3, and the conductor ME3 may each have a tapered shape with a substantially vertical taper angle. Alternatively, the side surfaces of the insulator IS2, the conductor ME2, the insulator IS3, and the conductor ME3 may have a tapered shape with a taper angle greater than 0° and less than 60°.

Note that in this specification and the like, a tapered shape refers to a shape such that at least part of a side surface of a component is inclined to a substrate surface. An angle formed by an inclined side surface and a substrate surface is referred to as a taper angle. Specifically, in this specification and the like, a tapered shape having a taper angle greater than 0° and less than or equal to 90° is referred to as a forward tapered shape, and a tapered shape having a taper angle greater than 90° and less than 180° is referred to as an inverse tapered shape.

In some cases, a by-product generated in the above etching step is formed into a layered shape on the side surface of the opening KK1 (the side surfaces of the insulator IS2, the conductor ME2, the insulator IS3, and the conductor ME3). In this case, the layered by-product is formed between the insulator IS2, the conductor ME2, the insulator IS3, and the conductor ME3 and a later-described semiconductor film SC1A. The layered by-product formed in contact with the insulator IS2, the conductor ME2, the insulator IS3, and the conductor ME3 is preferably removed.

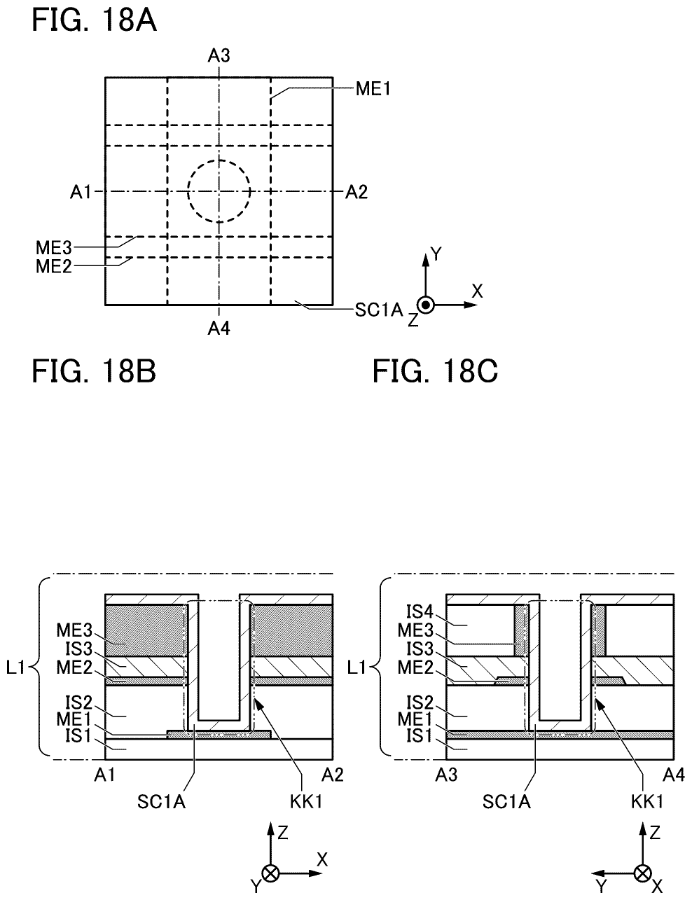

Next, the semiconductor film SC1A is formed over the conductor ME1, the insulator IS2, the conductor ME2, the insulator IS3, the conductor ME3, and the insulator IS4 (see FIG. 18A to FIG. 18C). Specifically, in the opening KK1, the semiconductor film SC1A is formed on the top surface of the conductor ME1, the side surface of the insulator IS2, the side surface of the conductor ME2, the side surface of the insulator IS3, and the side surface of the conductor ME3. In the outer part of the opening KK1, the semiconductor film SC1A is formed on the top surface of the conductor ME3 and the top surface of the insulator IS4. That is, the semiconductor film SC1A is formed on the bottom surface and the inner side surface of the opening KK1 and formed over the conductor ME3 and the insulator IS4. The semiconductor film SC1A can be formed by a film formation method such as a sputtering method, a CVD method, an MBE method, a PLD method, or an ALD method. The semiconductor film SC1A is preferably formed by an ALD method. As described above, the semiconductor film SC1A is preferably formed to have a small thickness and needs to have small variation in thickness. Since an ALD method is a film-formation method in which a precursor and a reactant (e.g., oxidizer) are alternately introduced and the film thickness can be adjusted with the number of repetition times of the cycle, accurate control of the film thickness is possible. As illustrated in FIG. 18B and FIG. 18C, the semiconductor film SC1A needs to be formed on the bottom surface and the inner side surface of the opening KK1 with good coverage. In the opening KK1, in particular, the top surface of the conductor ME1, the side surface of the conductor ME2, and the top surface and the side surface of the conductor ME3 are preferably formed with good coverage. Using an ALD method enables deposition of atomic layers one by one on the bottom surface and the inner side surface of the opening, whereby the semiconductor film SC1A can be formed with good coverage in the opening.

In the case where the side surface of the opening KK1 has a tapered shape, the semiconductor film SC1A is not necessarily formed by an ALD method. For example, a sputtering method may be employed.

The semiconductor film SC1A is a film to be the semiconductor SC1 in a later step. Part of the semiconductor SC1 functions as the channel formation region of the transistor MR formed in a later step. Another part of the semiconductor SC1 functions as the one of the pair of electrodes of the capacitor C1 formed in a later step in some cases.

For example, the semiconductor film SC1A can be a metal oxide functioning as an oxide semiconductor. In this case, the transistor MR is an OS transistor. The metal oxide preferably contains at least indium or zinc, for example. In particular, indium and zinc are preferably contained. In addition to them, an element M is preferably contained. As the element M, one or more selected from aluminum, gallium, silicon, yttrium, tin, copper, vanadium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. The element M further preferably contains one or both of gallium and tin.

For example, an In—Ga—Zn oxide is preferably used for the semiconductor film SC1A. The In—Ga—Zn oxide is preferably a metal oxide with a composition of In:Ga:Zn=1:1:1 [atomic ratio] or in the neighborhood thereof, a composition of In:Ga:Zn=4:2:3 [atomic ratio] or in the neighborhood thereof, or a composition of In:Ga:Zn=3:1:2 [atomic ratio] or in the neighborhood thereof, in particular. For another example, an In—Zn oxide is preferably used for the semiconductor film SC1A. The In—Zn oxide is further preferably a metal oxide with a composition of In:Zn=4:1 [atomic ratio] or in the neighborhood thereof, in particular.

The metal oxide preferably has a stacked-layer structure of a plurality of oxide layers that differ in the atomic ratio of metal atoms. For example, a first metal oxide and a second metal oxide formed over the first metal oxide are assumed as the metal oxide. In the case where each metal oxide contains at least indium (In) and the element M, the proportion of the number of atoms of the element M contained in the first metal oxide to the number of atoms of all elements that constitute the first metal oxide is preferably higher than the proportion of the number of atoms of the element M contained in the second metal oxide to the number of atoms of all elements that constitute the second metal oxide. In addition, the atomic ratio of the element M to In in the first metal oxide is preferably higher than the atomic ratio of the element M to In in the second metal oxide.

The energy of the conduction band minimum of the first metal oxide is preferably higher than the energy of the conduction band minimum of the second metal oxide. In other words, the electron affinity of the first metal oxide is preferably smaller than the electron affinity of the second metal oxide.

Here, the energy level of the conduction band minimum gently changes at junction portions between the first metal oxide and the second metal oxide. In other words, at junction portions between the first metal oxide and the second metal oxide, the energy level of the conduction band minimum continuously changes or the energy levels are continuously connected. This can be achieved by decreasing the density of defect states in a mixed layer formed at the interface between the first metal oxide and the second metal oxide.

Specifically, when the first metal oxide and the second metal oxide contain the same element (as a main component) in addition to oxygen, a mixed layer with a low density of defect states can be formed. For example, an In—Ga—Zn oxide (indium-gallium-zinc oxide), a Ga—Zn oxide, or gallium oxide can be used as the first metal oxide, in the case where the second metal oxide is an In—Ga—Zn oxide.

Specifically, as the first metal oxide, a metal oxide with a composition of In:Ga:Zn=1:3:4 [atomic ratio] or in the neighborhood thereof, a composition of In:Ga:Zn=1:3:2 [atomic ratio] or in the neighborhood thereof, or a composition of In:Ga:Zn=1:1:0.5 [atomic ratio] or in the neighborhood thereof can be used. As the second metal oxide, a metal oxide with In:Ga:Zn=1:1:1 [atomic ratio] or a composition in the neighborhood thereof, In:Ga:Zn=4:2:3 [atomic ratio] or a composition in the neighborhood thereof, or In:Ga:Zn=3:1:2 [atomic ratio] or a composition in the neighborhood thereof is used. Note that a composition in the neighborhood includes the range of ±30% of an intended atomic ratio.

In this case, the second metal oxide serves as a main carrier path. When the first metal oxide has the above structure, the density of defect states at the interface between the first metal oxide and the second metal oxide can be made low. Thus, the influence of interface scattering on carrier conduction is small, and the transistor MR can have a high on-state current and high frequency characteristics.

The metal oxide may have a stacked-layer structure of the second metal oxide and the first metal oxide formed over the second metal oxide. Such a structure can inhibit an increase in contact resistance between the conductor ME1 or the conductor ME2 and the metal oxide. Furthermore, damage to the second metal oxide due to the formation film of the insulator GI1 can be reduced.

Using the metal oxide for the semiconductor film SC1A may reduce the oxygen concentration in the semiconductor SC1 in the vicinity of the conductor, which is the conductor (corresponding to the conductor ME1, the conductor ME2, and the conductor ME3 in FIG. 18A to FIG. 18C) provided in contact with the semiconductor SC1. In addition, a metal compound layer, which contains a metal contained in the conductor and a component of the semiconductor SC1, may be formed in the semiconductor SC1 in the vicinity of the conductor. In such cases, a region of the metal semiconductor SC1 in the vicinity of the conductor has a higher carrier density, thereby becoming a low-resistance region.

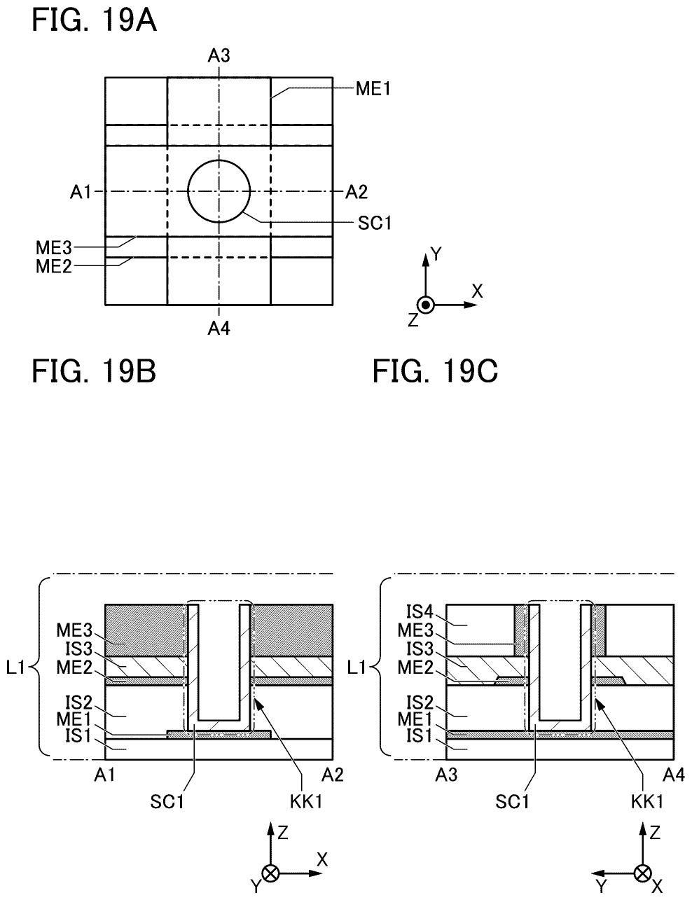

Next, a sacrificial layer (not illustrated) is formed over the semiconductor film SC1A to fill the opening KK1. After that, planarization treatment such as a CMP method is performed to polish the sacrificial layer and the semiconductor film SC1A until the conductor ME3 and the insulator IS4 are exposed. After that, the sacrificial layer embedded in the opening KK1 is removed (see FIG. 19A to FIG. 19C). Thus, the semiconductor SC1 is provided in contact with the inner side surface of the opening KK1.

For the semiconductor film SC1A, a material containing silicon, for example, can be used. Examples of the silicon include amorphous silicon (referred to as hydrogenated amorphous silicon in some cases), microcrystalline silicon, polycrystalline silicon, and single crystal silicon. In the process of forming the semiconductor film SC1A in the opening KK1, semiconductor regions in which the semiconductor film SC1A is formed and which are at interfaces in contact with the conductor ME1, the conductor ME2, and the conductor ME3 and in the vicinities thereof are preferably changed into low-resistance regions. In that case, the semiconductor SC1 includes a low-resistance region and a semiconductor region, so that the transistor MW can be a Si transistor.

In the description of this embodiment, the semiconductor film SC1A includes the metal oxide functioning as an oxide semiconductor.

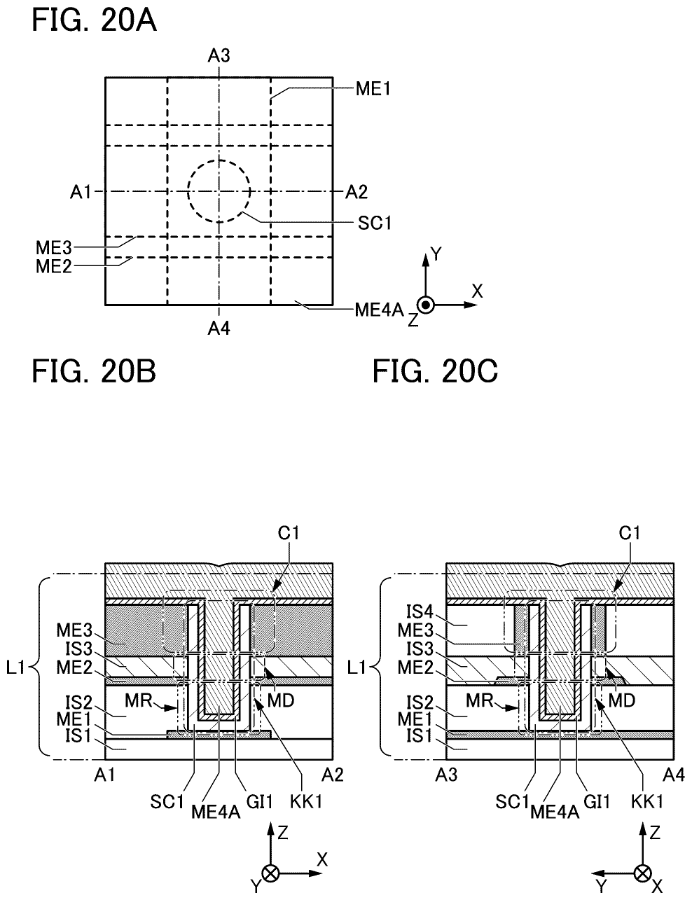

Next, the insulator GI1 and the conductive film ME4A are formed in this order over the conductor ME3, the insulator IS4, and the semiconductor SC1. In particular, the conductive film ME4A is formed to fill the opening KK1 (see FIG. 20A to FIG. 20C). Specifically, the insulator GI1 is formed on the top surface of the semiconductor SC1, the top surface of the conductor ME3, and the top surface of the insulator IS4, and then the conductive film ME4A is formed on the top surface of the insulator GI1 to fill the opening KK1.

Thus, the transistor MR is formed in a region including the conductor ME1, the conductor ME2, the semiconductor SC1, the insulator GI1, and the conductive film ME4A. The capacitor C1 is formed in a region including the conductor ME3, the semiconductor SC1, the insulator GI1, and the conductive film ME4A. In some cases, the transistor MD is formed in a region including the conductor ME2, the conductor ME3, the insulator IS3, the semiconductor SC1, the insulator GI1, and the conductive film ME4A.

The insulator GI1 functions as a gate insulating film of the transistor MR. The insulator GI1 functions as a dielectric sandwiched between the pair of electrodes of the capacitor C1.

Thus, for the insulator GI1, a single layer or a stacked layer using an insulator containing what is called a high-k material, such as aluminum oxide, hafnium oxide, tantalum oxide, zirconium oxide, lead zirconate titanate (PZT), strontium titanate (SrTiO₃), or (Ba,Sr) TiO₃ (BST) is preferably used. Alternatively, for the insulator GI1, as an insulator having a high relative permittivity, an oxide containing aluminum and hafnium, an oxynitride containing aluminum and hafnium, an oxide containing silicon and hafnium, an oxynitride containing silicon and hafnium, or a nitride containing silicon and hafnium may be used.

With further miniaturization and higher integration of a transistor, a problem such as generation of a leakage current may arise because of a thinned gate insulator. When a high-k material is used for the insulator functioning as a gate insulator, a gate potential at the time of the operation of the transistor can be reduced while the physical thickness is maintained.

As the insulator GI1, an insulating layer in which the above-described high-k material and silicon oxide or silicon oxynitride are stacked may be used. Thus, an insulating layer having thermal stability in addition to a high relative permittivity can be used as the gate insulating film of the transistor MR.

In the case where the semiconductor SC1 includes the metal oxide functioning as an oxide semiconductor, microwave treatment is preferably performed in an oxygen-containing atmosphere immediately after the formation of the insulator GI1 (before the formation of the conductive film ME4A). Here, the microwave treatment refers to, for example, treatment using an apparatus including a power source that generates high-density plasma with use of a microwave. In this specification and the like, a microwave refers to an electromagnetic wave having a frequency greater than or equal to 300 MHz and less than or equal to 300 GHz. Note that in the case where the insulating film GI1 has a stacked-layer structure, the microwave treatment may be performed at the time when the insulating film GI1 is partially formed. For example, in the case where the insulating film GI1 includes a silicon oxide film or a silicon oxynitride film, the microwave treatment may be performed at the time when the silicon oxide film or the silicon oxynitride film is formed.

For the microwave treatment, a high-frequency wave such as a microwave or RF, oxygen plasma, oxygen radicals, or the like can be used. In the case where the microwave treatment is performed, for example, a microwave treatment apparatus including a power source generating high-density plasma using microwaves is preferably used. Here, the frequency of the microwave treatment apparatus is set to higher than or equal to 300 MHz and lower than or equal to 300 GHz, preferably higher than or equal to 2.4 GHz and lower than or equal to 2.5 GHZ, for example, 2.45 GHz. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Application of RF to the substrate side allows oxygen ions generated by the high-density plasma to be introduced into the semiconductor SC1 which is a metal oxide efficiently. The effect of plasma, microwaves, and the like enables VoH included in a region of the semiconductor SC1 to be cut off and hydrogen to be removed from the region. That is, VoH contained in the region can be reduced. As a result, oxygen vacancies and VoH in the region can be reduced to lower the carrier concentration. In addition, oxygen radicals generated by the oxygen plasma can be supplied to oxygen vacancies formed in the region, thereby further reducing oxygen vacancies in the region and lowering the carrier concentration.

The conductive film ME4A is a film to be the conductor ME4 (the node FN or part of the node FN) in a later step. The conductor ME4 functions as a gate electrode of the transistor MR and the other of the pair of electrodes of the capacitor C1. Thus, a material having high conductivity is preferably used for the conductive film ME4.

A material that is usable for the conductor ME1 can be used for the conductive film ME4A, for example.

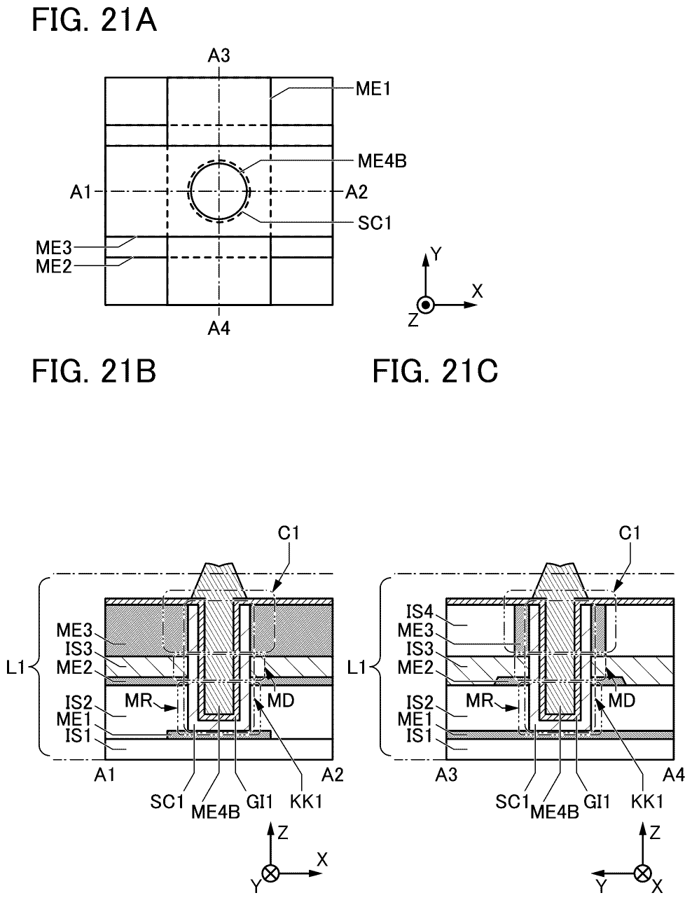

Next, the conductive film ME4A is processed by a lithography method so that the insulator GI1 is partly exposed and a conductive film ME4B is formed. Specifically, the processing is performed such that the side surface of the conductive film ME4B overlaps with the inner part of a region of the opening KK1 (see FIG. 21A to FIG. 21C). The lithography method described with reference to FIG. 10A to FIG. 10C can be referred to for the lithography method.

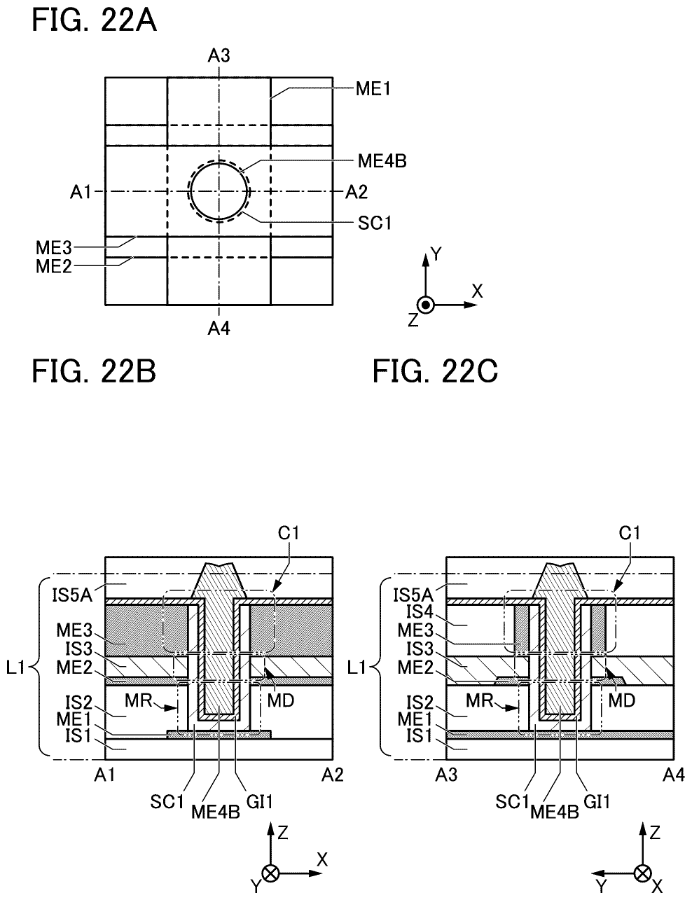

Next, an insulating film ISSA is formed over the insulator GI1 and the conductive film ME4B (see FIG. 22A to FIG. 22C). The insulating film ISSA can be formed by a film-formation method such as a sputtering method, a CVD method, an MBE method, a PLD method, or an ALD method, for example.

The insulating film ISSA is a film to be the insulator IS5 in a later step. The insulator IS5 functions as an interlayer film, for example. Thus, an insulating material with a low dielectric constant is preferably used for the insulator IS5. The use of an insulating material with a low dielectric constant for the interlayer film can reduce the parasitic capacitance between wirings.

Any of the materials that can be used for the insulator IS1 can be used for the insulating film IS5A, for example.

The conductor ME5 is formed over the insulator IS5 in a later manufacturing step. For this reason, in order to prevent oxidation of the conductor ME5, for example, silicon nitride is preferably used for the insulator IS5 as a barrier insulating film that inhibits diffusion of oxygen.

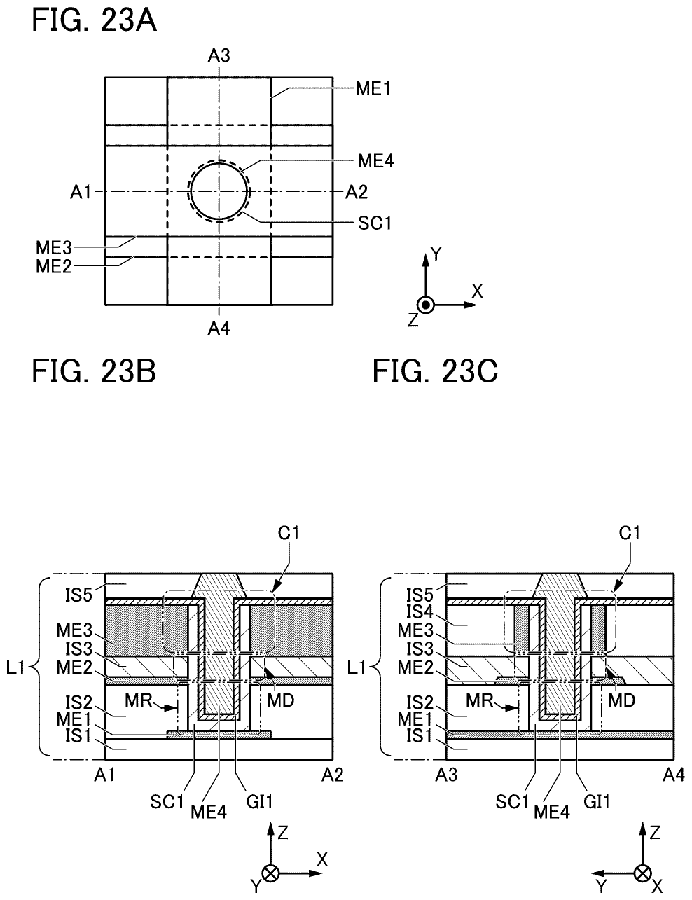

Next, planarization treatment such as a CMP method is performed to polish the insulating film IS5A and the conductive film ME4B, so that the insulator IS5 and the conductor ME4 are formed (see FIG. 23A to FIG. 23C). Thus, a wiring electrically connected to the memory cell MC and a circuit element such as the transistor MW can be easily formed above the insulator IS5 and the conductor ME4.

By the above manufacturing method, the transistor MR and the capacitor C1 can be provided in the layer L1. In some cases, the transistor MD is provided above the transistor MR and below the capacitor C1.

Next, an example of a method for manufacturing the layer L2 of the memory cell MC will be described.

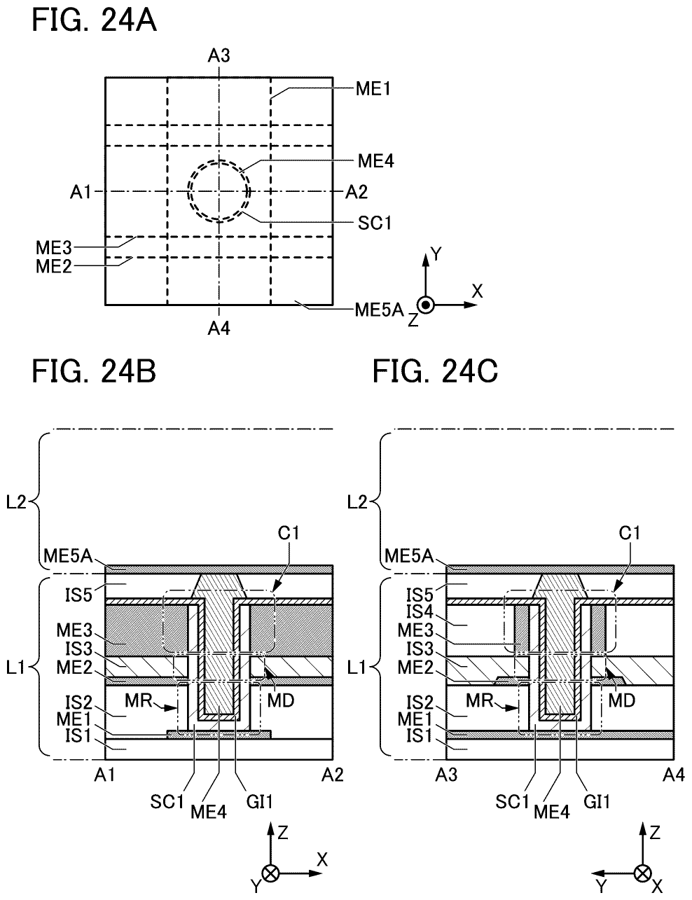

A conductive film MESA is formed over the insulator IS5 and the conductive film ME4 (see FIG. 24A to FIG. 24C). The conductive film MESA can be formed by a film-formation method such as a sputtering method, a CVD method, an MBE method, a PLD method, or an ALD method, for example.

The conductive film MESA is a film to be the conductor ME5 (the node FN or part of the node FN) in a later step. The conductor ME5 also functions as one of a source electrode and a drain electrode of the transistor MW. Thus, a material having high conductivity is preferably used for the conductive film ME5.

A material that is usable for the conductor ME1 can be used for the conductive film MESA, for example.

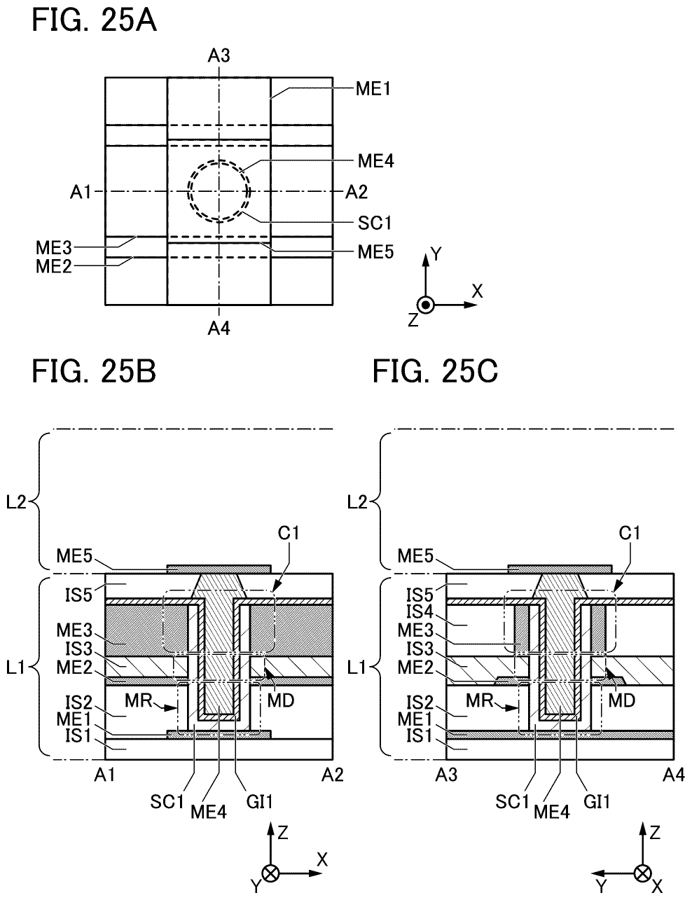

Next, the conductive film MESA is processed by a lithography method so that the insulator IS5 is partly exposed and the conductor ME5 is formed. In particular, the conductor ME5 is processed to overlap with the conductor ME4 (see FIG. 25A to FIG. 25C). The lithography method described with reference to FIG. 10A to FIG. 10C can be referred to for the lithography method.

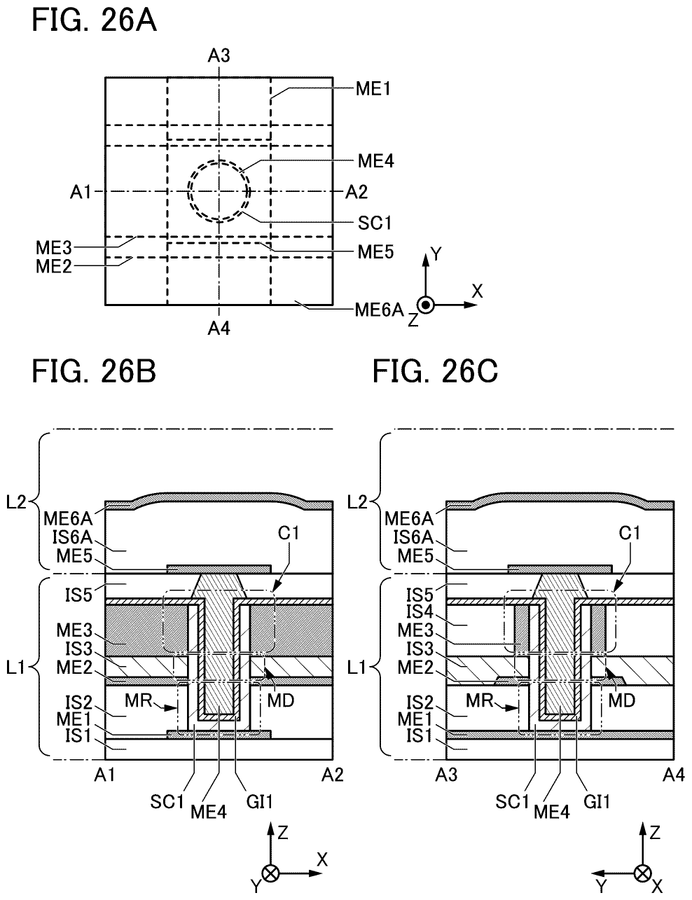

Next, an insulating film IS6A and a conductive film ME6A are formed in this order over the insulator IS5 and the conductive film ME5 (see FIG. 26A to FIG. 26C). The insulating film IS6A and the conductive film ME6A can be formed by a film-formation method such as a sputtering method, a CVD method, an MBE method, a PLD method, or an ALD method, for example.

The insulating film IS6A is a film to be the insulator IS6 in a later step. The insulator IS6 functions as an interlayer film, for example. The insulator IS6 preferably includes an insulating material with a low dielectric constant. The use of an insulating material with a low dielectric constant for the interlayer film can reduce the parasitic capacitance between wirings.

Any of the materials that can be used for the insulator IS1 can be used as the insulating film IS6A, for example. In particular, in the case where the semiconductor SC2 formed in a later step is a metal oxide functioning as an oxide semiconductor, for example, silicon oxide, silicon oxynitride, and porous silicon oxide are preferably used for the insulating film IS6A. These materials are capable of easily forming a region containing oxygen that is released by heating, so that the released oxygen can be supplied to the metal oxide. This reduces the carrier concentration of the metal oxide at the interface of the semiconductor SC2 in contact with the insulator IS6 and in the vicinity of the interface, whereby the interface of the semiconductor SC2 and the vicinity of the interface are i-type or substantially i-type. Accordingly, the interface of the semiconductor SC2 and the vicinity of the interface function as the channel formation region of the transistor MW.

The conductive film ME6A is a film to be the conductor ME6 (wiring WBL) in a later step. Part of the conductor ME6 also functions as the other of the source electrode and the drain electrode of the transistor MW. Thus, a material having high conductivity is preferably used for the conductive film ME6.

A material that is usable for the conductor ME1 can be used for the conductive film ME6A, for example.

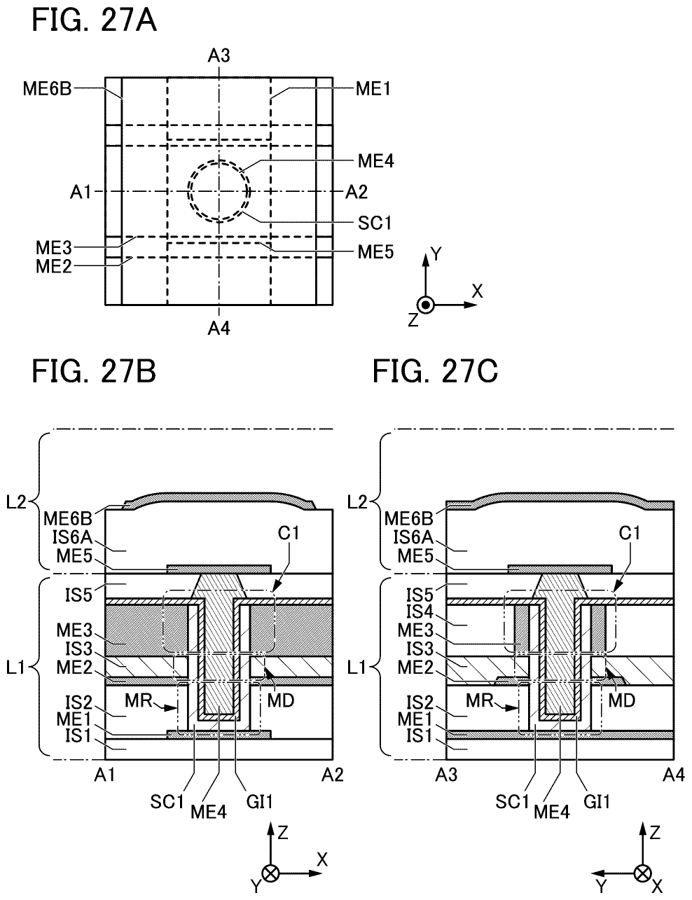

Next, the conductive film ME6A is processed into a belt-like shape to form the conductive film ME6B by a lithography method (see FIG. 27A to FIG. 27C). Specifically, here, the conductive film ME6B is formed to extend in the direction parallel to the dashed-dotted line A3-A4 (Y direction) and overlap with the conductor ME5. The lithography method described with reference to FIG. 10A to FIG. 10C can be referred to for the lithography method.

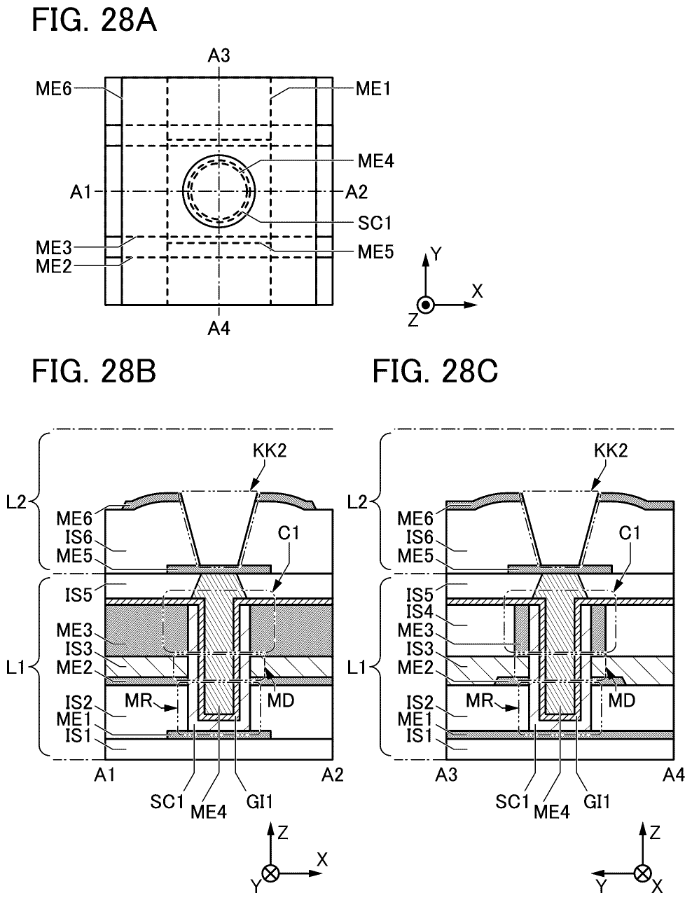

Next, the insulating film IS6A and the conductive film ME6B are processed by a lithography method to form the insulator IS6 and the conductor ME5 that include the opening KK2 (see FIG. 28A to FIG. 28C). The opening KK2 is formed in a region overlapping with the conductor ME5, in particular. That is, the opening KK2 is an opening in which the conductor ME5 is the bottom surface. A dry etching method or a wet etching method can be employed for the above processing, and processing by a dry etching method is suitable for microfabrication. The insulator IS6 and the conductive film ME6B may be processed under different conditions. In FIG. 28A to FIG. 28C, the side surface of the opening KK2 may have a tapered shape with a taper angle. Specifically, for example, the side surfaces of the insulator IS6 and the conductor ME6 may each have a tapered shape with a taper angle greater than or equal to 45° and less than or equal to 90°.

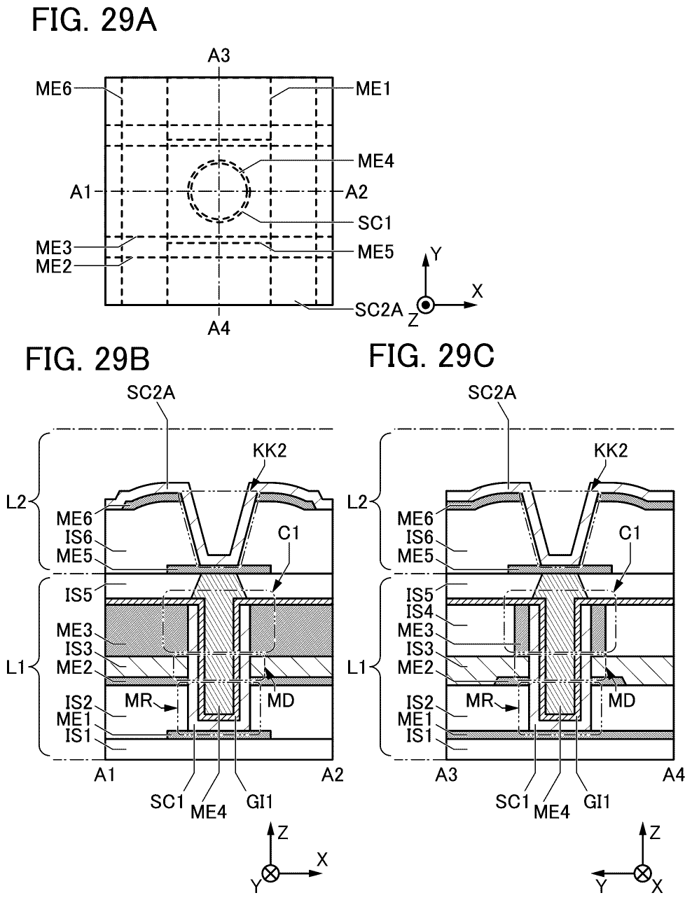

Next, a semiconductor film SC2A is formed over the conductor ME5, the insulator IS6, and the conductor ME6 (see FIG. 29A to FIG. 29C). Specifically, in the opening KK2, the semiconductor film SC2A is formed on the top surface of the conductor ME5, the side surface of the insulator IS6, and the side surface of the conductor ME6. In the outer part of the opening KK2, the semiconductor film SC2A is formed on the top surface of the conductor ME6 and the top surface of the insulator IS6. That is, the semiconductor film SC2A is formed on the bottom surface and the inner side surface of the opening KK2, the top surface and the side surface of the conductor ME6, and the side surface of the insulator IS6. The semiconductor film SC2A can be formed by a film-formation method such as a sputtering method, a CVD method, an MBE method, a PLD method, or an ALD method. The semiconductor film SC2A is preferably formed by an ALD method. In particular, in the case where a material of a semiconductor film SC2B is the same as a material of the semiconductor film SC2A, the description of the ALD method for the formation of the semiconductor film SC1A can be referred to for the ALD method for the formation of the semiconductor film SC2B.

The semiconductor film SC2A is a film to be the semiconductor SC2 in a later step. Part of the semiconductor SC2 functions as the channel formation region of the transistor MW formed in a later step.

A material that is usable for the semiconductor SC1 can be used for semiconductor film SC2A, for example. Thus, the transistor MW can be an OS transistor or a Si transistor.

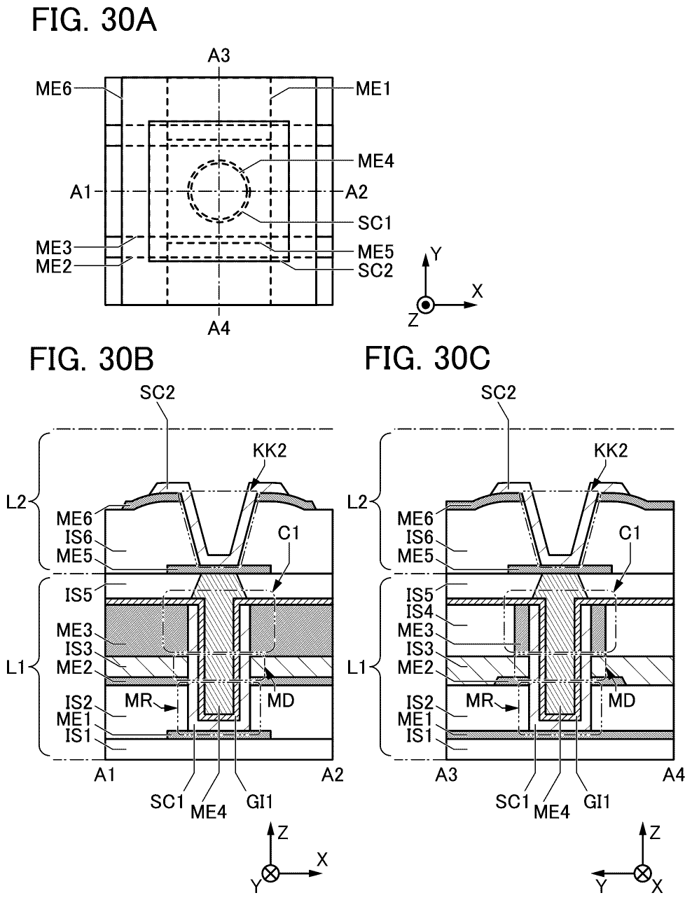

Next, the semiconductor SC2 is formed by processing the semiconductor film SC2A by a lithography method so that part of the insulator IS6 and part of the conductor ME6 are exposed. Specifically, the semiconductor SC2 is processed to overlap with the conductor ME5 (see FIG. 30A to FIG. 30C). The lithography method described with reference to FIG. 10A to FIG. 10C can be referred to for the lithography method.

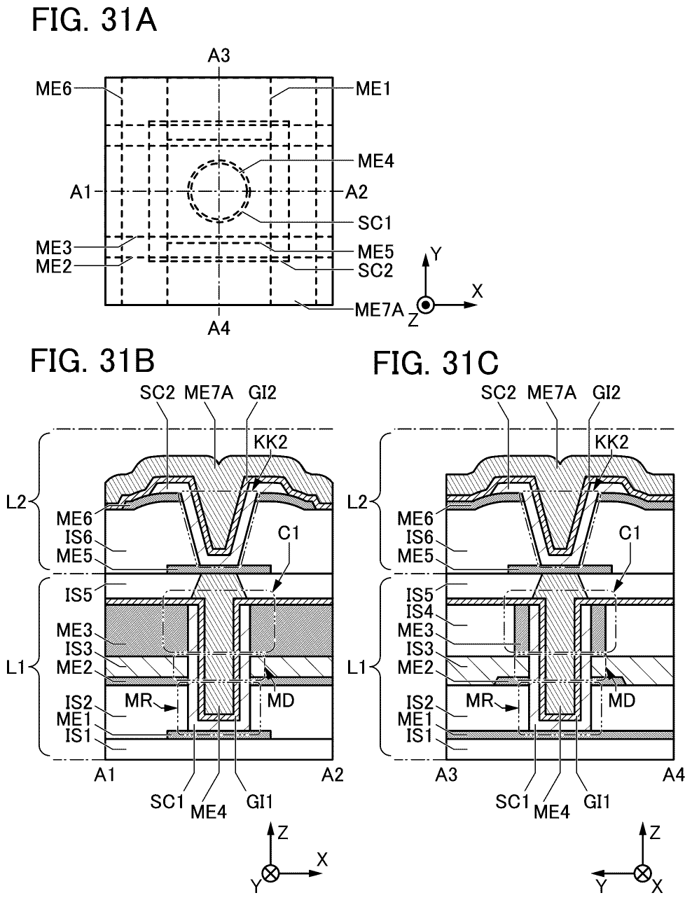

Next, a film of the insulator GI2 and a conductive film ME7A are formed in this order over the insulator IS6, the conductive film ME6, and the semiconductor SC2 (see FIG. 31A to FIG. 31C). Specifically, the conductive film ME7A is formed to fill the opening KK2. The insulator GI2 and the conductive film ME7A can be formed by a film-formation method such as a sputtering method, a CVD method, an MBE method, a PLD method, or an ALD method, for example.

The insulator GI2 functions as a gate insulating film of the transistor MW.

Any of the materials that can be used for the insulator GI1 can be used as the insulator GI2, for example.

In the case where the semiconductor SC2 includes the metal oxide functioning as an oxide semiconductor, the semiconductor SC2A covered with the insulator GI2 may be subjected to microwave treatment, like the semiconductor SC1. Particularly in this case, the layer L1 may be unaffected by the microwave treatment because the effect of a high-frequency wave such as a microwave or RF, oxygen plasma, or the like on the layer L1 is blocked by the conductor ME5 and the conductor ME6.

The conductive film ME7A is a film to be the conductor ME7 (wiring WWL) in a later step. Part of the conductor ME7 also functions as the gate electrode of the transistor MW. Thus, a material having high conductivity is preferably used for the conductive film ME7.

A material that is usable for the conductor ME1 can be used for the conductive film ME7A, for example.

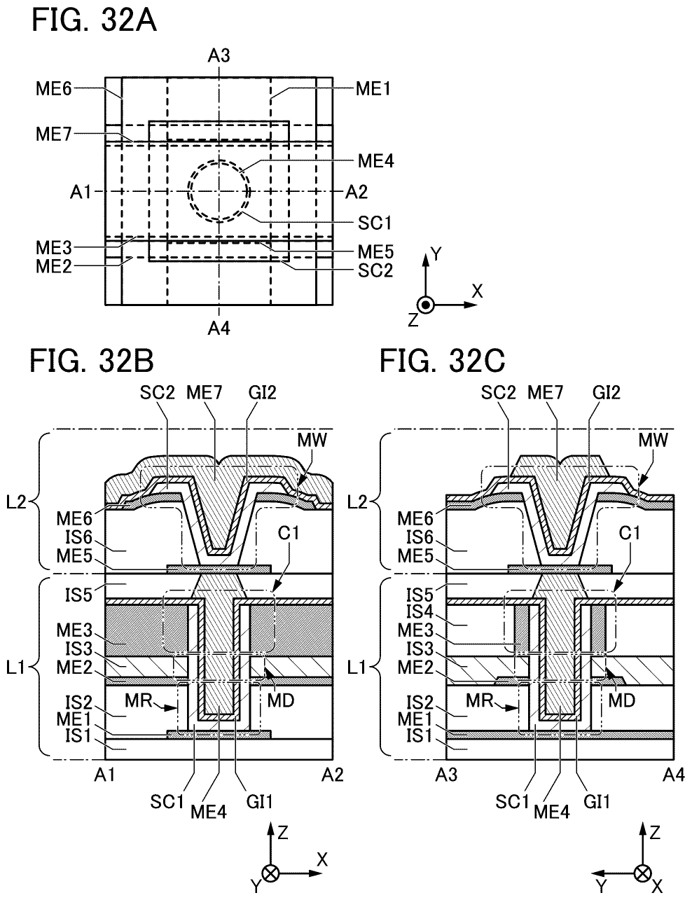

Next, the conductive film ME7A is processed into a belt-like shape to form the conductive film ME7 by a lithography method (see FIG. 32A to FIG. 32C). Specifically, here, the conductive film ME7 is formed to extend in the direction parallel to the dashed-dotted line A1-A2 (X direction) and overlap with the conductor ME5. The lithography method described with reference to FIG. 10A to FIG. 10C can be referred to for the lithography method.

Next, the insulator IS7 is formed over the insulator GI2 and the conductor ME7 (see FIG. 2A to FIG. 2C).

The insulator IS7 is a film functioning as an interlayer film, for example. Thus, the insulator IS7 preferably contains an insulating material with a low dielectric constant. The use of an insulating material with a low dielectric constant for the interlayer film can reduce the parasitic capacitance between wirings.

Any of the materials that can be used as the insulator IS1 can be used for the insulator IS7, for example.

The conductor ME7 is formed below the insulator IS7. Thus, for the insulator IS7, silicon nitride is preferably used as a barrier insulating film that inhibits diffusion of oxygen, for example, in order to prevent oxidation of the conductor ME7.

By the above manufacturing method, the transistor MW can be provided in the layer L2. Through the formation of the layer L1 and the layer L2, the memory cell MC illustrated in FIG. 2A to FIG. 2C can be formed.

### MODIFICATION EXAMPLE

The method for manufacturing a semiconductor device of one embodiment of the present invention is not limited to the above. The manufacturing method may be modified as appropriate in the manufacture of the semiconductor device of one embodiment of the present invention. Even in the case where the structure of the semiconductor device is changed by modification of the manufacturing method, the semiconductor device can be regarded as one embodiment of the present invention.

### Modification Example 1

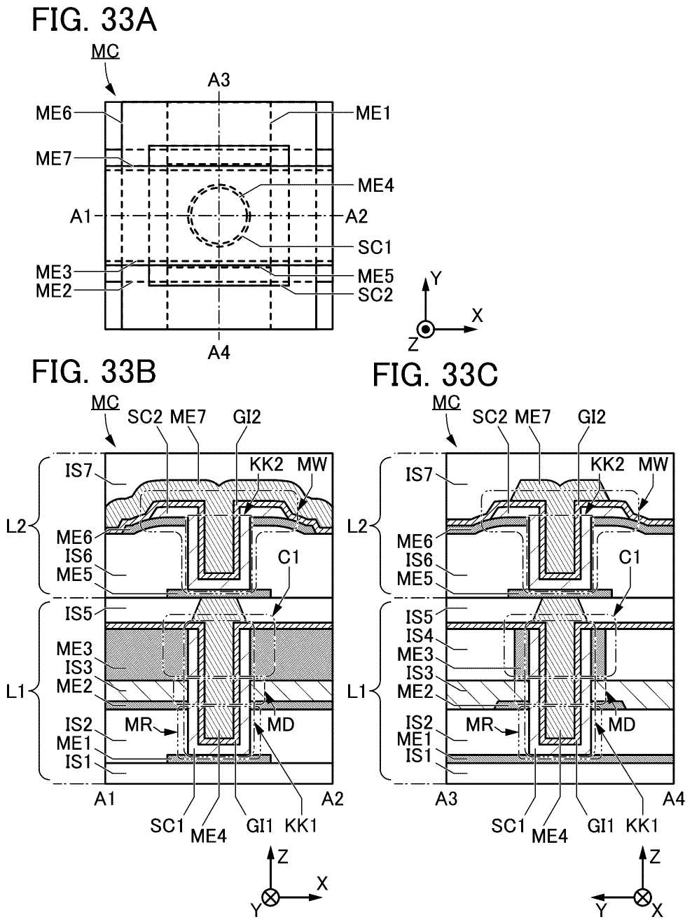

The memory cell MC illustrated in FIG. 33A to FIG. 33C is a modification example of the memory cell MC in FIG. 2A to FIG. 2C, and has a structure in which the taper angle of the opening KK2 in the memory cell MC in FIG. 2A to FIG. 2C is 90°.

The taper angle of the opening KK2 is set to 90° with respect to the substrate (not illustrated) in the manufacturing step of the memory cell MC illustrated in FIG. 28A to FIG. 28C, for example, so that the memory cell MC illustrated in FIG. 33A to FIG. 33C can be manufactured.

When the taper angle of the opening KK2 is 90°, the area for forming the opening KK2 can be reduced and the area of the memory cell MC can be reduced.

### Modification Example 2

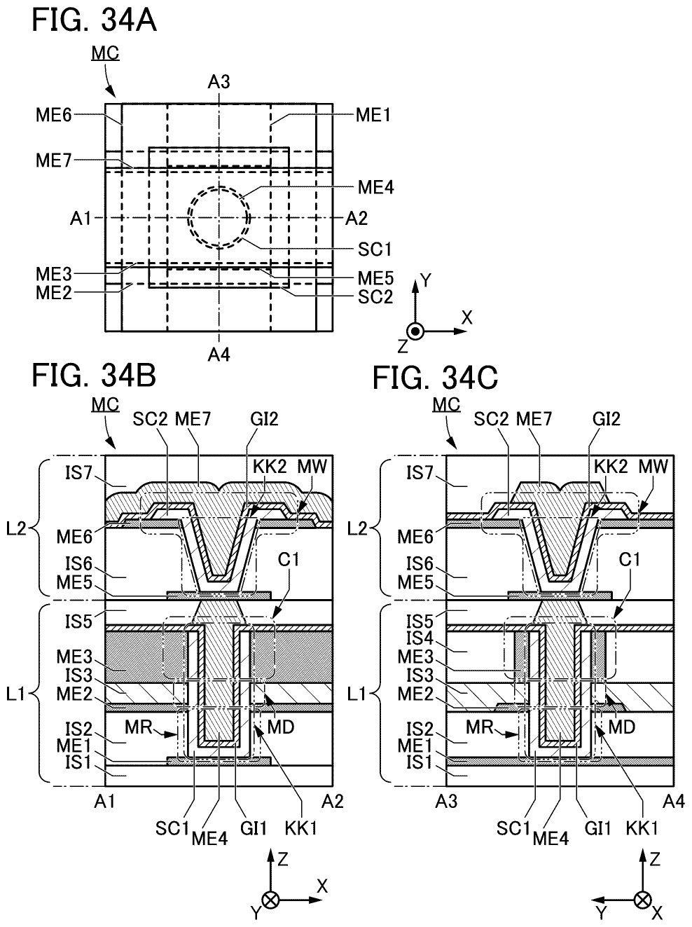

The memory cell MC illustrated in FIG. 34A to FIG. 34C is a modification example of the memory cell MC in FIG. 2A to FIG. 2C, and has a structure in which the insulator IS6 is planarized in a region outside the opening KK2.

The insulating film IS6A is polished by planarization treatment such as a CMP method after formed in the manufacturing step of the memory cell MC illustrated in FIG. 26A to FIG. 26C, for example, whereby the memory cell MC illustrated in FIG. 34A to FIG. 34C can be obtained.

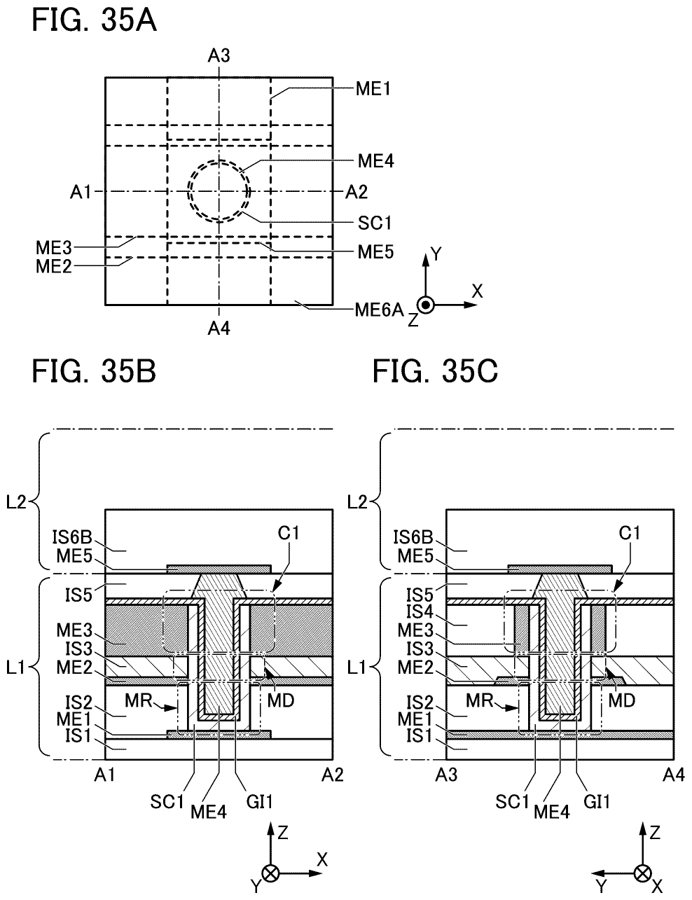

Specifically, for example, in the manufacturing step of the memory cell MC in FIG. 26A to FIG. 26C, the insulating film IS6A is formed and then processed into an insulating film IS6B by planarization treatment such as a CMP method (see FIG. 35A to FIG. 35B). After that, formation of the conductive film ME6A in the manufacturing step of the memory cell MC in FIG. 26A to FIG. 26C, the manufacturing step in FIG. 27A to FIG. 27C, and the subsequent steps are successively performed, whereby the memory cell MC illustrated in FIG. 33A to FIG. 33C can be manufactured.

Planarizing the insulator IS6 can prevent a step on the insulator IS6 from causing a failure in the formation of the conductor ME6 and the insulator GI2 over the insulator IS6A, for example. That is, the yield of the memory cell MC can be increased.

### Modification Example 3

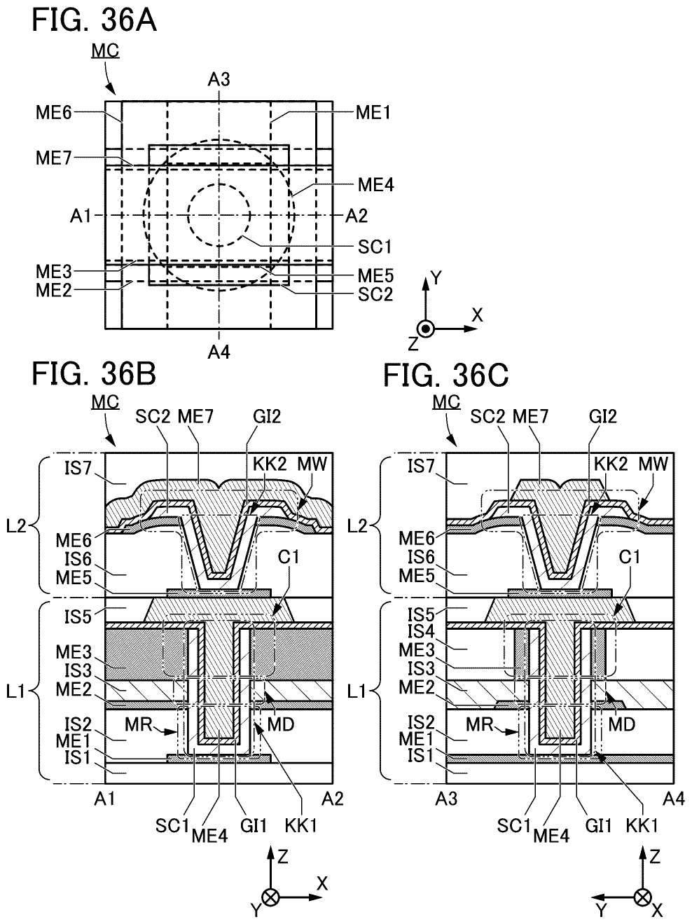

The memory cell MC illustrated in FIG. 36A to FIG. 36C is a modification example of the memory cell MC in FIG. 2A to FIG. 2C, and has a structure in which the area of the conductor ME4 formed over the insulator GI1 in the memory cell MC in FIG. 2A to FIG. 2C is increased in the plan view.

For example, processing is performed such that the conductor ME4 is formed above the conductor ME3 and the insulator IS4 in the manufacturing step of the memory cell MC in FIG. 21A to FIG. 21C, whereby the memory cell MC illustrated in FIG. 36A to FIG. 36C can be manufactured.

When the region where the conductor ME3 and the conductor ME4 overlap with each other is enlarged as in the memory cell MC illustrated in FIG. 36A to FIG. 36C, the electrostatic capacitance value of the capacitor C1 can be increased. Increasing the electrostatic capacitance value of the capacitor C1 can extend the data retention time of the memory cell MC, for example.

### Modification Example 4

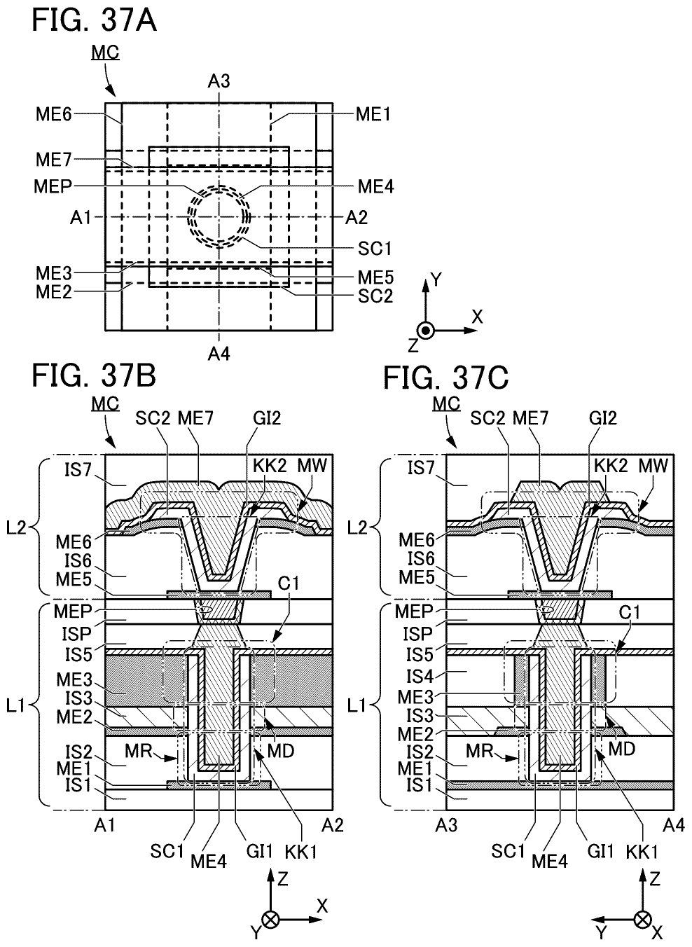

The memory cell MC illustrated in FIG. 37A to FIG. 37C is a modification example of the memory cell MC in FIG. 2A to FIG. 2C, and has a structure in which a conductor MEP functioning as a contact plug is provided between the conductor ME4 and the conductor ME5.

For example, a step of providing the conductor MEP is performed after the step of manufacturing the memory cell MC in FIG. 23A to FIG. 23C, so that the memory cell MC illustrated in FIG. 37A to FIG. 37C can be obtained.

Specifically, for example, an insulator ISP functioning as an interlayer film is formed after the manufacturing step of the memory cell MC in FIG. 23A to FIG. 23C. Next, an opening is formed in a region of the insulator ISP which overlaps with the conductor ME4 by a lithography method. Then, the conductor MEP is formed to fill the opening and planarization treatment such as a CMP method is performed, so that polishing is performed until the insulator ISP is exposed. After that, the layer L2 is formed over the conductor MEP so that the conductor ME5 is provided, whereby the memory cell MC illustrated in FIG. 37A to FIG. 37C can be manufactured.

In particular, enlarging the area of the conductor MEP functioning as a contact plug can increase a margin for a region where the transistor MW is manufactured. Accordingly, for example, even if a region to be processed by a lithography method is misaligned, as long as the region is within the region where the transistor MW is manufactured, the transistor MW electrically connected to the capacitor C1 can be manufactured. That is, the yield of the memory cell MC can be increased.

As a film formation method of the conductor MEP, a sputtering method, a CVD method, an MBE method, a PLD method, or an ALD method is used, for example. For the conductor MEP, any of the materials that can be used for the conductor ME1 can be used, for example. Although the conductor MEP has a stacked-layer structure of two layers in FIG. 37B and FIG. 37C, the present invention is not limited thereto. The conductor MEP may have a single-layer structure or a stacked-layer structure of three or more layers.

The insulator ISP functions as an interlayer film, for example. The insulator ISP preferably includes an insulating material with a low dielectric constant. The use of an insulating material with a low dielectric constant for the interlayer film can reduce the parasitic capacitance between wirings.

As a film formation method of the insulator ISP, a sputtering method, a CVD method, an MBE method, a PLD method, or an ALD method is used, for example. Any of the materials that can be used for the insulator IS1 can be used as the insulator ISP, for example.

### Modification Example 5

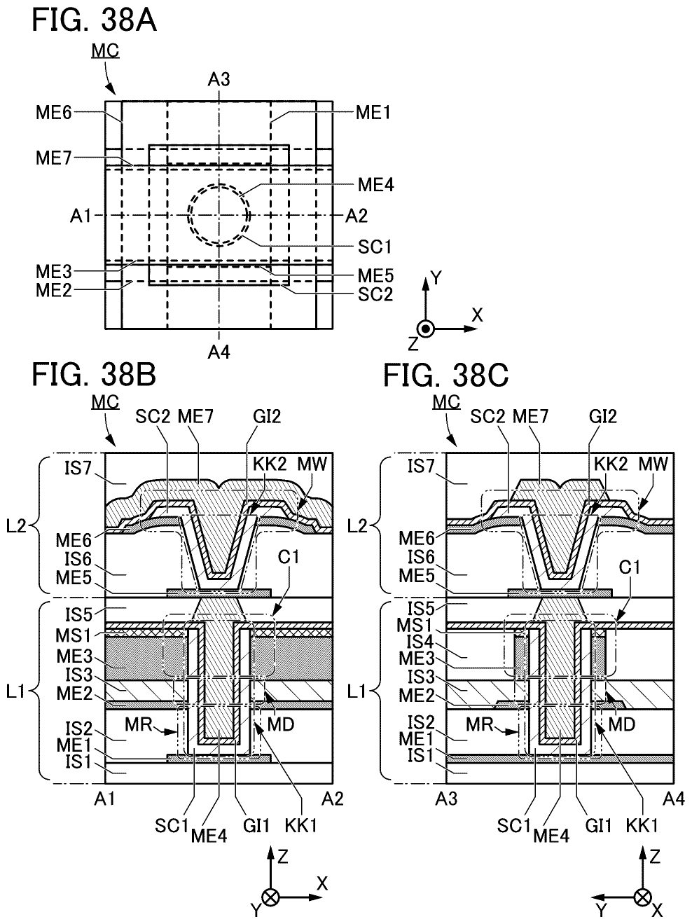

The memory cell MC illustrated in FIG. 38A to FIG. 38C is a modification example of the memory cell MC in FIG. 2A to FIG. 2C and has a structure in which the conductor MS1 functioning as a hard mask is provided on the top surface of the conductor ME3.

For example, a step of providing the conductor MS1 as a hard mask is performed after the step of manufacturing the memory cell MC in FIG. 13A to FIG. 13C, so that the memory cell MC illustrated in FIG. 38A to FIG. 38C can be obtained.

Specifically, after the manufacturing step of the memory cell MC in FIG. 13A to FIG. 13C, the conductor MS1 is formed as a hard mask material used later in a lithography method, for example. Next, the opening KK1 is formed by the lithography method, as in FIG. 14A to FIG. 14C. After that, steps similar to those in the method for manufacturing the memory cell MC in FIG. 2A to FIG. 2C are performed, whereby the memory cell MC illustrated in FIG. 38A to FIG. 38C can be manufactured.

When the conductor MS1 is provided as a hard mask material on the top surface of the conductor ME3, the conductor ME3 can be protected from a chemical solution or the like used for the etching treatment in the lithography method in FIG. 14A to FIG. 14C.

The conductor MS1 can be used as an auxiliary electrode in the conductor ME3 in some cases. In that case, a material having lower resistivity than the conductor ME3 is preferably used for the conductor MS1. Accordingly, the resistance value of the conductor ME3 (wiring CL) can be small, so that the power consumption of the memory cell MC can be reduced.

As illustrated in FIG. 38C, the side surface of the conductor MS1 is substantially aligned with the side surface of the conductor ME3. In other words, the conductor MS1 and the conductor ME3 may be regarded as forming a conductor having a stacked-layer structure.

As a film formation method of the conductor MS1, a sputtering method, a CVD method, an MBE method, a PLD method, or an ALD method is used, for example. The conductor MS1 is preferably formed in the same deposition apparatus as the conductor ME3.

Note that the conductor MS1 may be removed by planarization treatment such as the CMP method in FIG. 19A to FIG. 19C after the step in FIG. 14A to FIG. 14C.

### Modification Example 6

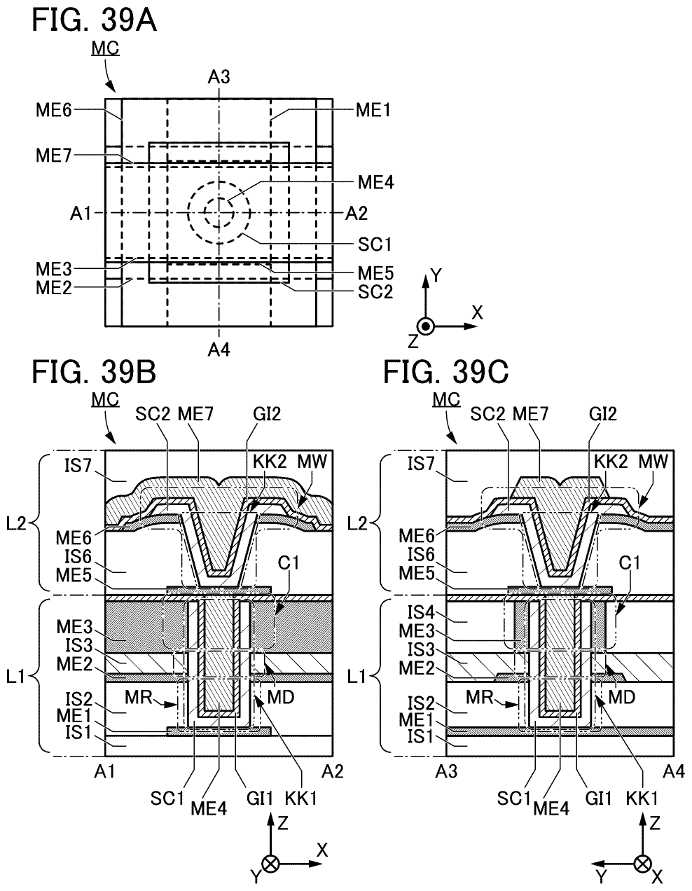

The memory cell MC illustrated in FIG. 39A to FIG. 39C is a modification example of the memory cell MC in FIG. 2A to FIG. 2C, and has a structure in which the conductor ME5 is formed not only over the conductor ME4 but also over the insulator GI1.

The conductive film ME4A is polished until the insulator GI1 is exposed by planarization treatment such as a CMP method, instead of the lithography method performed in the manufacturing step of the memory cell MC in FIG. 21A to FIG. 21C, for example, whereby the memory cell MC illustrated in FIG. 39A to FIG. 39C can be manufactured.

The memory cell MC illustrated in FIG. 39A to FIG. 39C does not need formation of the insulator IS5 and accordingly can be manufactured more simply than the memory cell MC in FIG. 2A to FIG. 2C.

### Modification Example 7

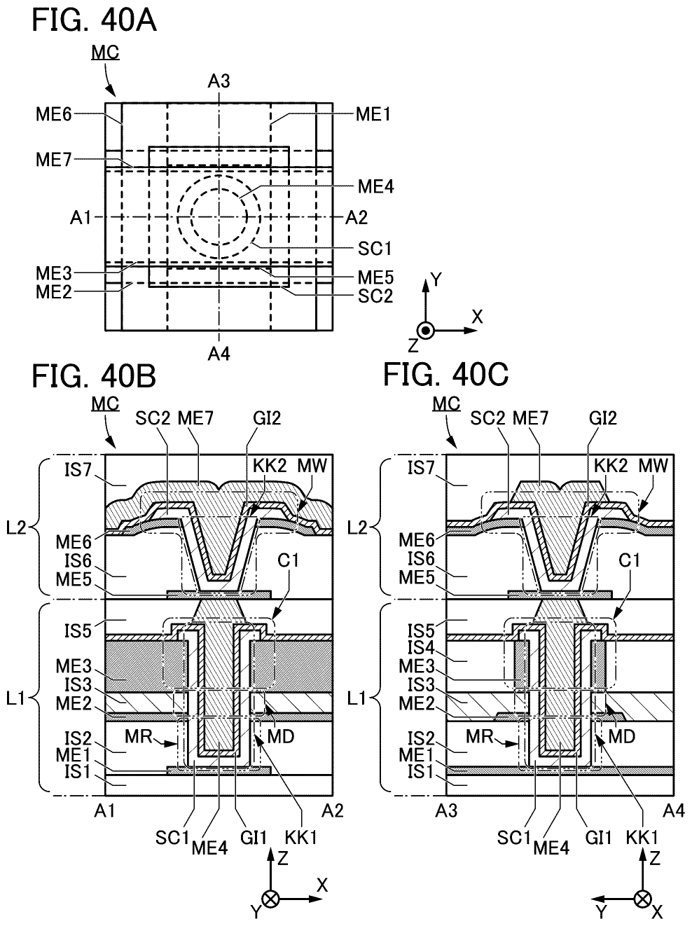

The memory cell MC illustrated in FIG. 40A to FIG. 40C is a modification example of the memory cell MC in FIG. 2A to FIG. 2C and has a structure in which an end portion of the semiconductor SC1 is formed to be positioned on the top surface of the conductor ME3.

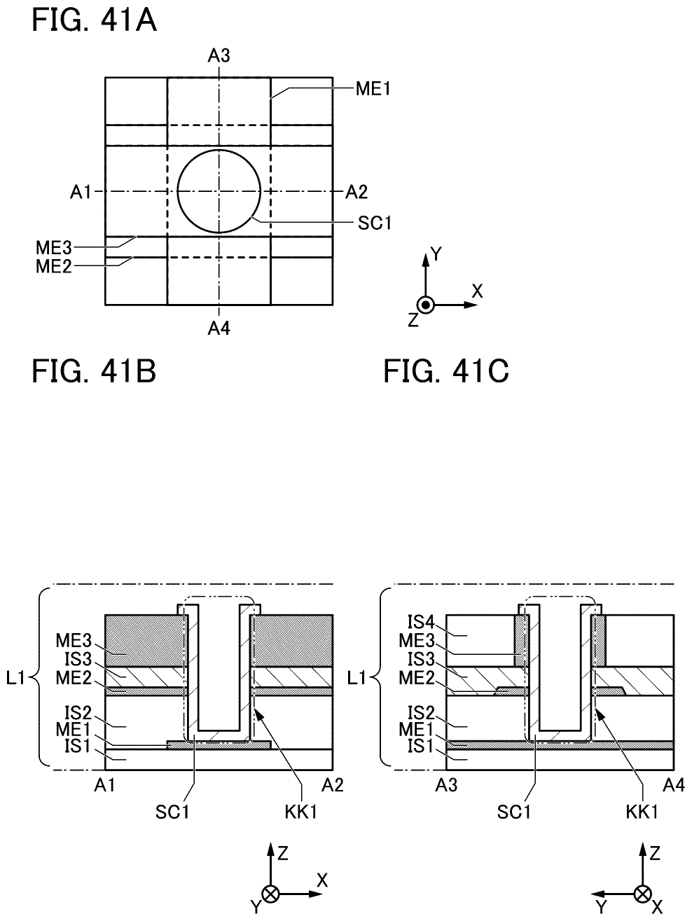

For example, the semiconductor film SC1A is processed by a lithography method after the manufacturing step of the memory cell MC in FIG. 18A to FIG. 18C, so that the memory cell MC illustrated in FIG. 40A to FIG. 40C can be manufactured (see FIG. 41A to FIG. 41C). After the manufacturing step in FIG. 41A to FIG. 41C, the manufacturing step of the memory cell MC in FIG. 20A to FIG. 20C and the subsequent steps are successively performed.

Before the processing by the lithography method, a sacrificial layer may be formed over the semiconductor film SC1A to fill the opening KK1, and the sacrificial layer may be removed after the lithography method, whereby the semiconductor SC1 illustrated in FIG. 41A to FIG. 41C may be formed.

For the memory cell MC in FIG. 2A to FIG. 2C, planarization treatment is employed to process the semiconductor film SC1A into the semiconductor SC1. Meanwhile, for the memory cell MC in FIG. 40A to FIG. 40C, a lithography method is employed to process the semiconductor film SC1A into the semiconductor SC1 so that the semiconductor SC1 is formed on the bottom surface and the inner side surface of the opening KK1 and over part of the conductor ME3. The method for processing the semiconductor film SC1A into the semiconductor SC1 is not limited to that in the method for manufacturing the memory cell MC in FIG. 2A to FIG. 2C, for example, and may be changed as appropriate.

### Modification Example 8

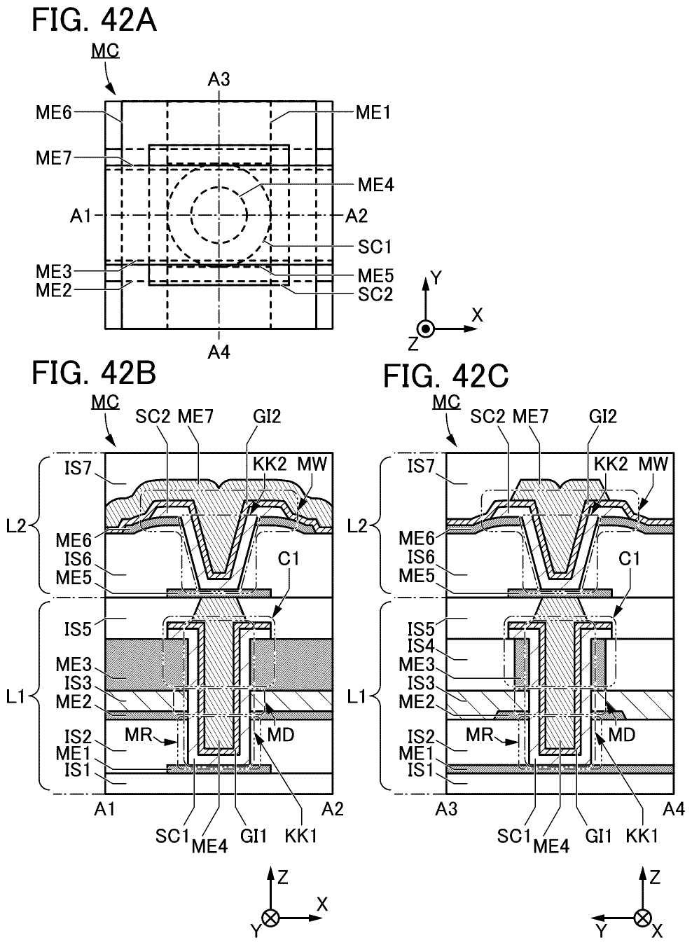

The memory cell MC illustrated in FIG. 42A to FIG. 42C is a modification example of the memory cell MC in FIG. 40A to FIG. 40C and has a structure in which an end portion of the insulator GI1 is positioned on the top surface of the semiconductor SC1.

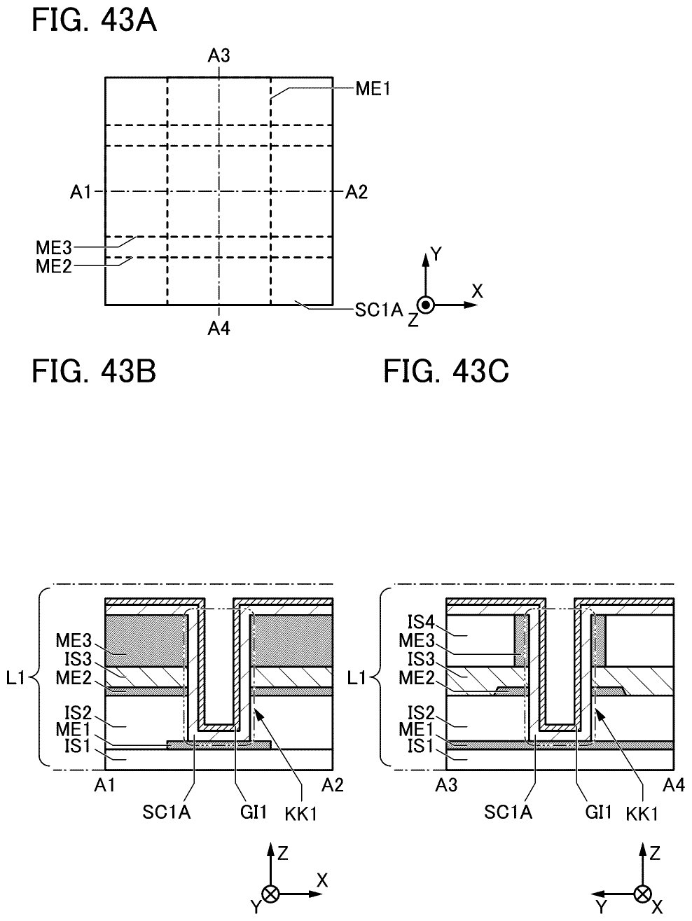

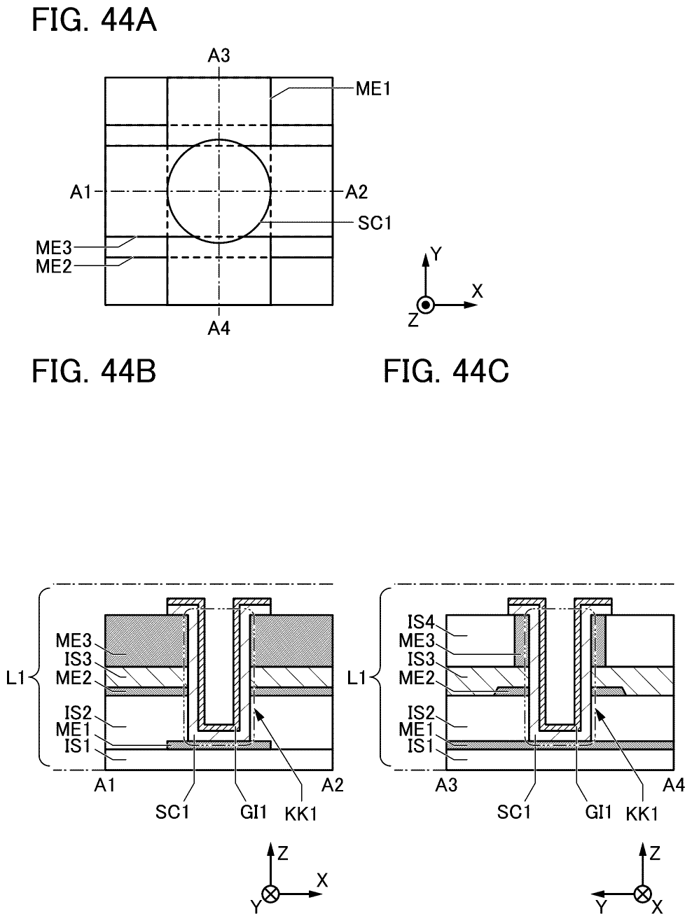

An example of the method for manufacturing the memory cell MC illustrated in FIG. 42A to FIG. 42C is as follows. After the manufacturing step of the memory cell MC in FIG. 18A to FIG. 18C, a film of the insulator GI1 is formed over the semiconductor film SC1A (see FIG. 43A to FIG. 43C). Next, the semiconductor film SC1A and the insulator GI1 are processed by a lithography method such that an end portion of the semiconductor SC1 is positioned over the conductor ME3 or the insulator IS4 (see FIG. 44A to FIG. 44C). After that, the step of manufacturing the memory cell MC in FIG. 20A to FIG. 20C and the subsequent steps are successively performed, whereby the memory cell MC in FIG. 42A to FIG. 42C can be manufactured.

Before the processing by the lithography method, a sacrificial layer may be formed over the insulator GI1 to fill the opening KK1, and the sacrificial layer may be removed after the lithography method, whereby the semiconductor SC1 and the insulator GI1 illustrated in FIG. 42A to FIG. 42C may be formed.

### Modification Example 9

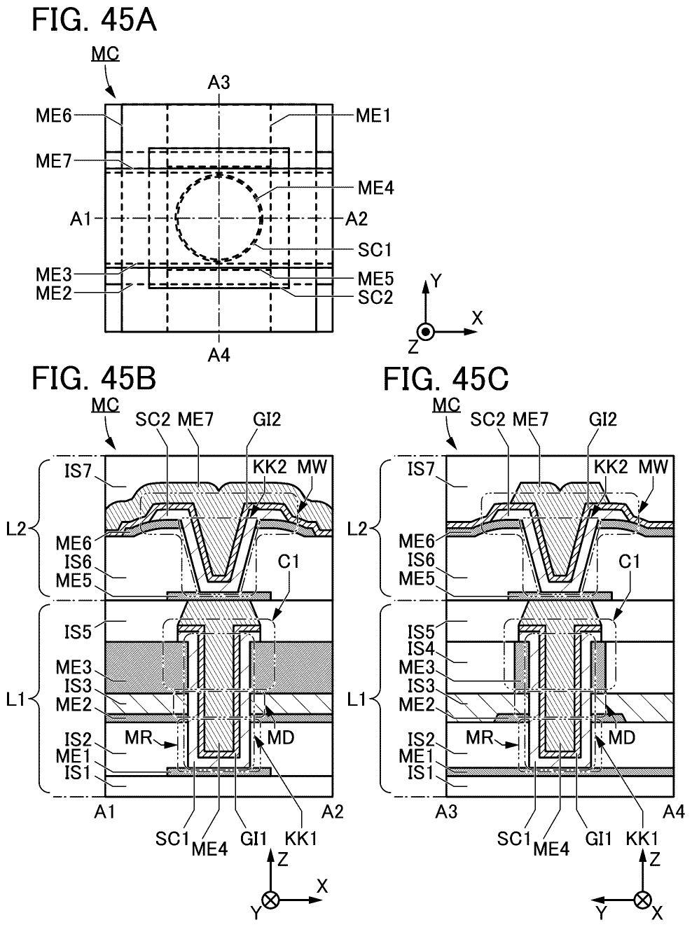

The memory cell MC illustrated in FIG. 45A to FIG. 45C is an example of further modification of the memory cell MC in FIG. 42A to FIG. 42C and has a structure in which the conductor ME4 positioned over the opening KK1, the insulator GI1, and the semiconductor SC1 are collectively processed by a lithography method.

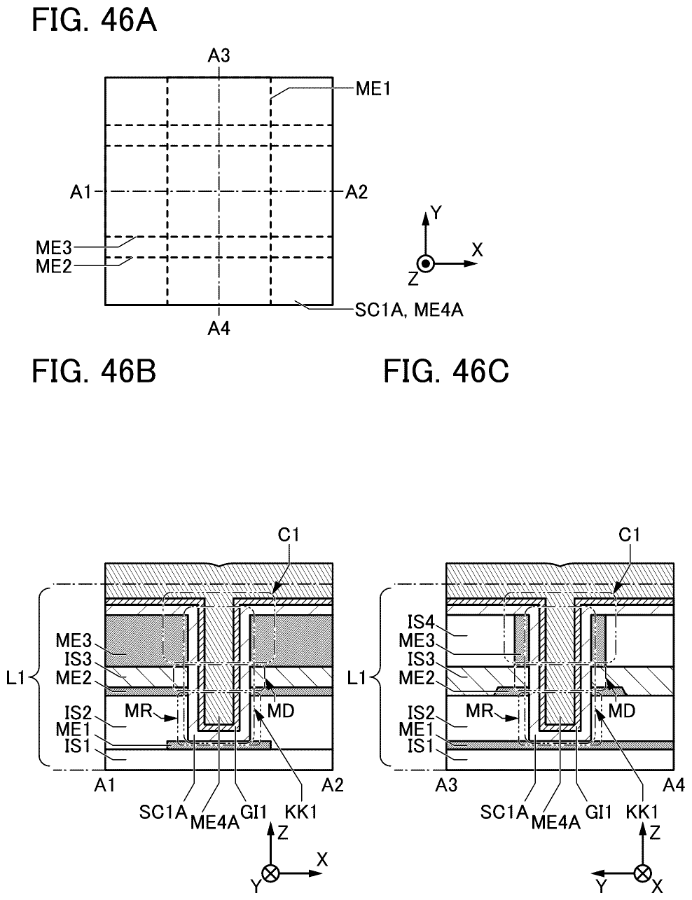

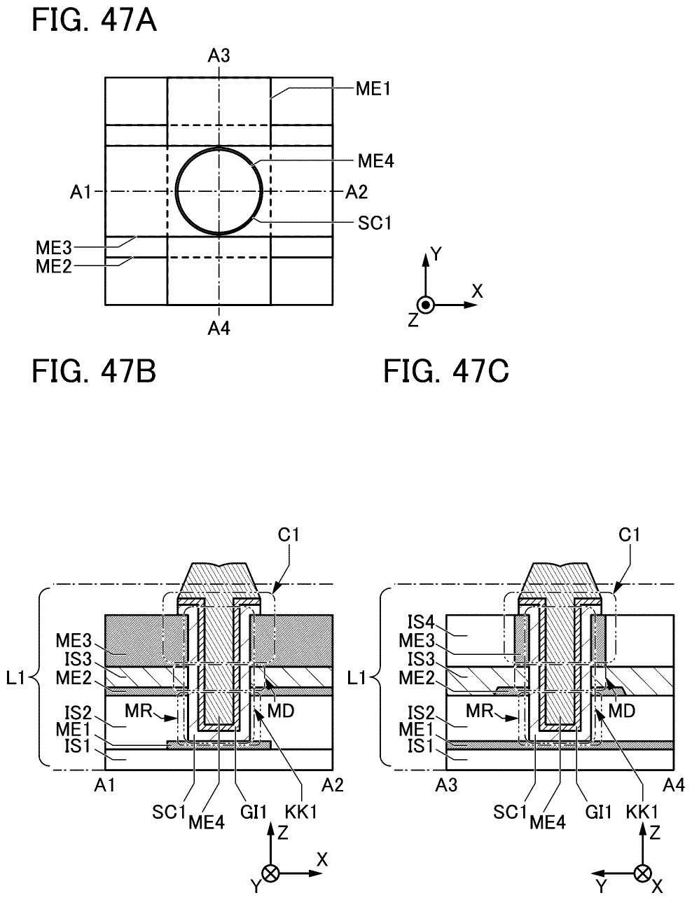

An example of the method for manufacturing the memory cell MC illustrated in FIG. 45A to FIG. 45C is as follows. After the manufacturing step of the memory cell MC in FIG. 18A to FIG. 18C, the film of the insulator GI1 and the conductive film ME4A are formed in this order over the semiconductor film SC1A (see FIG. 46A to FIG. 46C). Next, the semiconductor film SC1A, the insulator GI1, and the conductive film ME4A are processed by a lithography method such that an end portion of the semiconductor SC1 is positioned over the conductor ME3 or the insulator IS4 (see FIG. 47A to FIG. 47C). After that, the step of manufacturing the memory cell MC in FIG. 22A to FIG. 22C and the subsequent steps are successively performed, whereby the memory cell MC in FIG. 45A to FIG. 45C can be manufactured.

### Modification Example 10

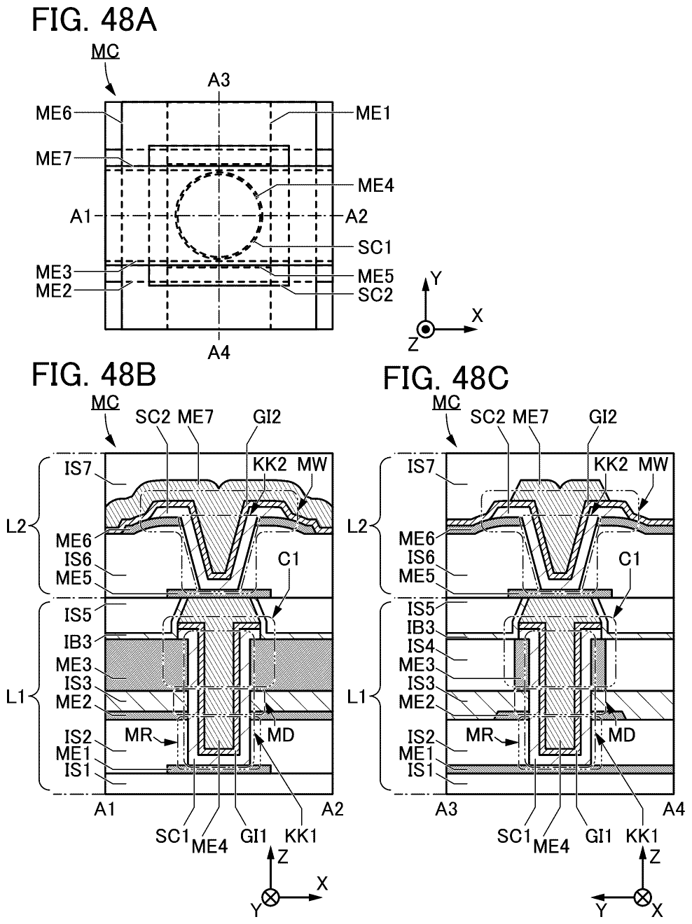

The memory cell MC illustrated in FIG. 48A to FIG. 48C is an example of further modification of the memory cell MC in FIG. 45A to FIG. 45C and has a structure in which an insulator IB3 is provided on the top surface of the conductor ME3, the top surface of the insulator IS4, a side surface of the semiconductor SC1, a side surface of the insulator GI1, and a side surface of the conductor ME4.

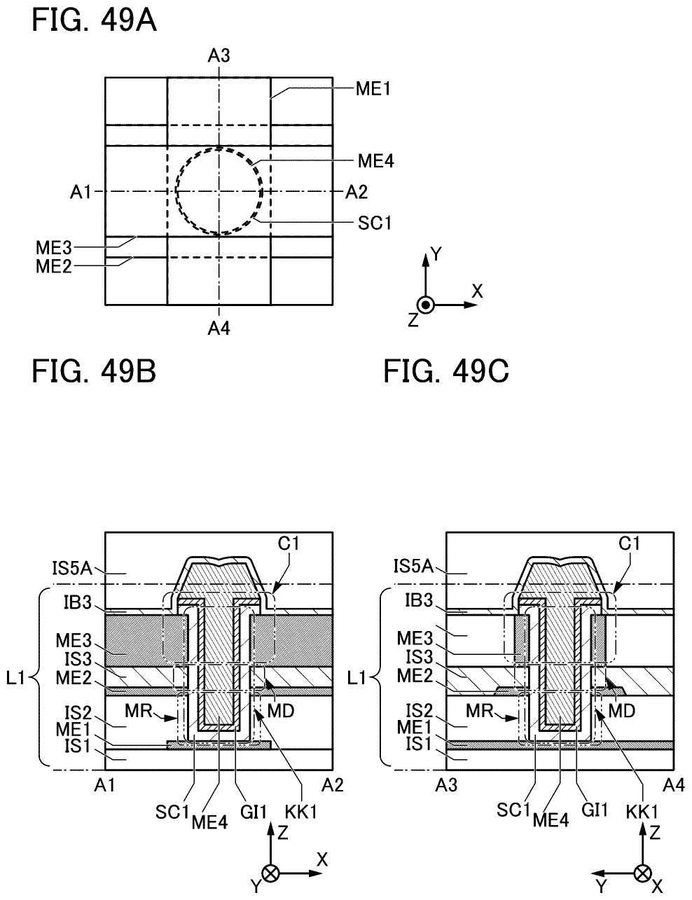

An example of the method for manufacturing the memory cell MC illustrated in FIG. 48A to FIG. 48C is as follows. After the manufacturing step of the memory cell MC in FIG. 47A to FIG. 47C, a film of the insulator IB3 is formed over the top surface of the conductor ME3, the top surface of the insulator IS4, the side surface of the semiconductor SC1, the side surface of the insulator GI1, and the side surface and a top surface of the conductor ME4, and a film of an insulator IS5A is formed over the insulator IB3 (see FIG. 49A to FIG. 49C). After that, the step of manufacturing the memory cell MC in FIG. 23A to FIG. 23C and the subsequent steps are successively performed, whereby the memory cell MC in FIG. 48A to FIG. 48C can be manufactured.

The insulator IB3 preferably functions as a barrier insulating film that inhibits entry of impurities such as water, hydrogen, nitrogen, and oxygen contained in the insulator IS5 into the conductor ME3, the conductor ME4, and the semiconductor SC1, for example. Thus, it is preferable to use, for the insulator IB3, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulator IB3. In that case, impurities such as water and hydrogen can be inhibited from diffusing into the capacitor C1 and the transistor MR side from the insulator IB3.

As a film formation method of the insulator IB3, a sputtering method, a CVD method, an MBE method, a PLD method, or an ALD method is used, for example.

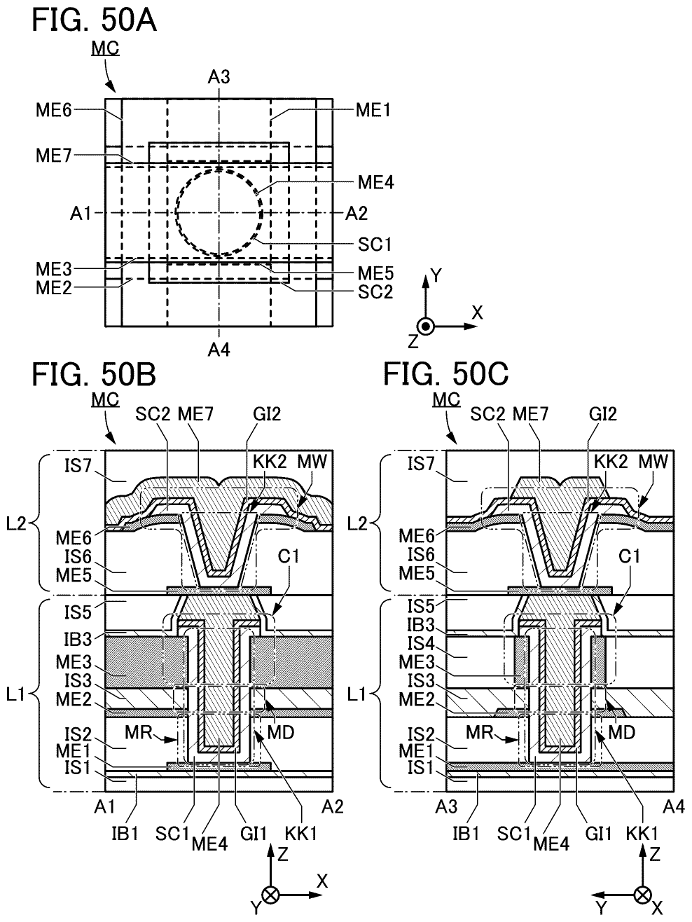

A barrier insulating film similar to the insulator IB3 may be provided in another portion. As illustrated in FIG. 50A to FIG. 50C, an insulator IB1 as the barrier insulating film similar to the insulator IB3 may be provided over the insulator IS1, for example. Thus, impurities such as water, hydrogen, nitrogen, and oxygen contained in the insulator IS1 can be inhibited from entering the conductor ME1, the semiconductor SC1, the conductor ME2, and the like positioned above the insulator IS1.

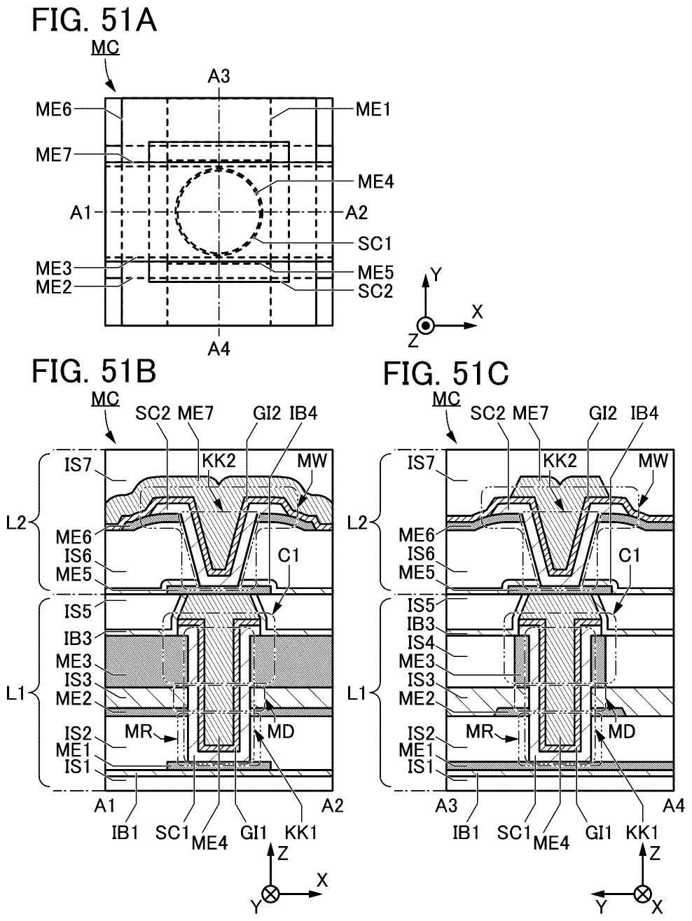

As illustrated in FIG. 51A to FIG. 51C, for example, the insulator IB4 as a barrier insulating film similar to the insulator IB3 may be provided over the insulator IS5 and the conductor ME5. The insulator IB4 includes a region of the opening KK2. Thus, impurities such as water, hydrogen, nitrogen, and oxygen contained in the insulator IS5 can be inhibited from entering the conductor ME5, the semiconductor SC2, the conductor ME6, and the like positioned above the insulator IS5.

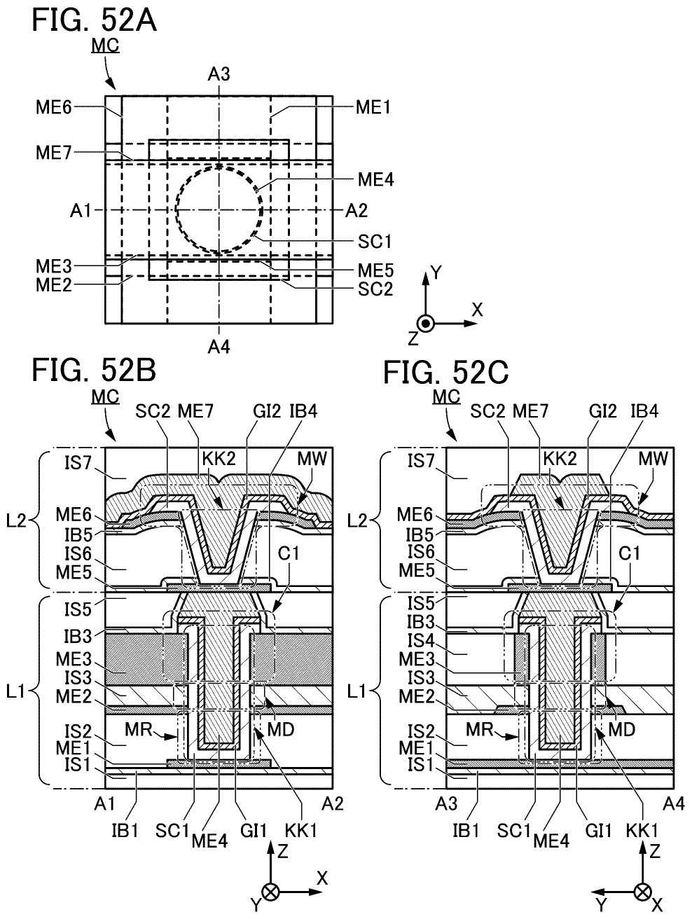

As illustrated in FIG. 52A to FIG. 52C, an insulator IB5 as the barrier insulating film similar to the insulator IB3 may be provided over the insulator IS6, for example. The insulator IB5 includes a region of the opening KK2. Thus, entry of impurities such as water, hydrogen, nitrogen, and oxygen from below the conductor ME6 can be inhibited.

Diffusion of impurities into the conductor and the semiconductor can be inhibited by a barrier insulating film provided as in the memory cell MC illustrated in FIG. 48A to FIG. 48C, the memory cell MC illustrated in FIG. 50A to FIG. 50C, the memory cell MC illustrated in FIG. 51A to FIG. 51C, and the memory cell MC illustrated in FIG. 52A to FIG. 52C.

### Modification Example 11

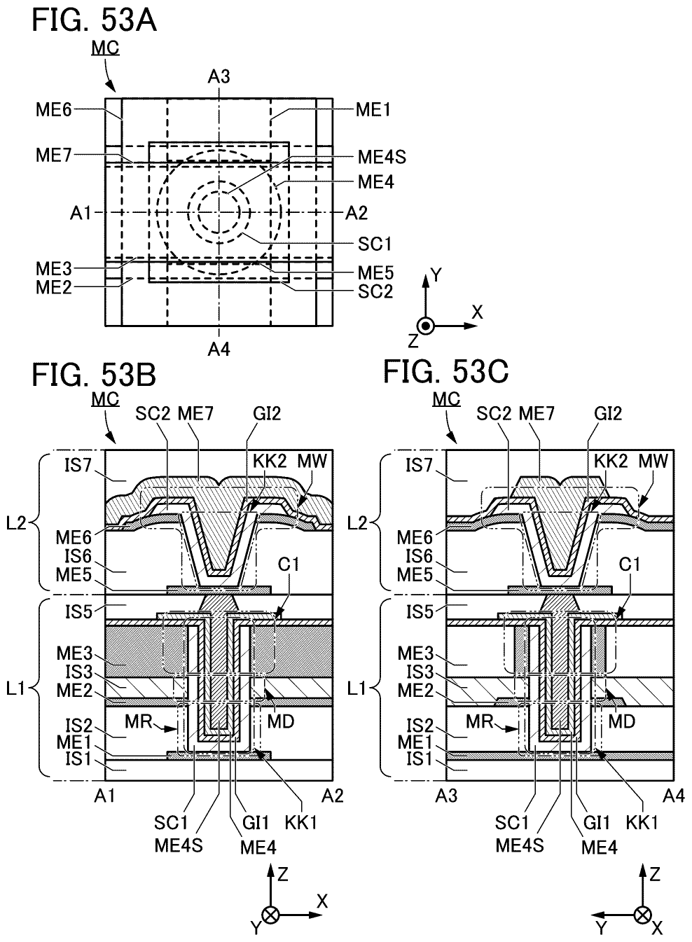

The memory cell MC illustrated in FIG. 53A to FIG. 53C is a modification example of the memory cell MC in FIG. 2A to FIG. 2C, and a stacked-layer structure of the conductor ME4 and a conductor ME4S is used as the conductor functioning as the gate electrode of the transistor MR and the other of the pair of electrodes of the capacitor C1.

Specifically, for example, the conductor ME4 with high coverage is formed on the bottom surface and the inner side surface of the opening KK1 and the conductor ME4S with high conductivity is formed over the conductor ME4 in the memory cell MC illustrated in FIG. 53A to FIG. 53C. Thus, the conductor ME4S functions as an auxiliary electrode of the conductor ME4.

An ALD method, which enables high coverage, is preferably used as a film formation method of the conductor ME4 in the memory cell MC in FIG. 53A to FIG. 53C.

As the film formation method of the conductor ME4S, a sputtering method, a CVD method, an MBE method, a PLD method, or an ALD method is used, for example. For the conductor ME4S, a material having lower resistivity than the conductor ME4 among the materials that can be used for the conductor ME1 is preferably used, for example.

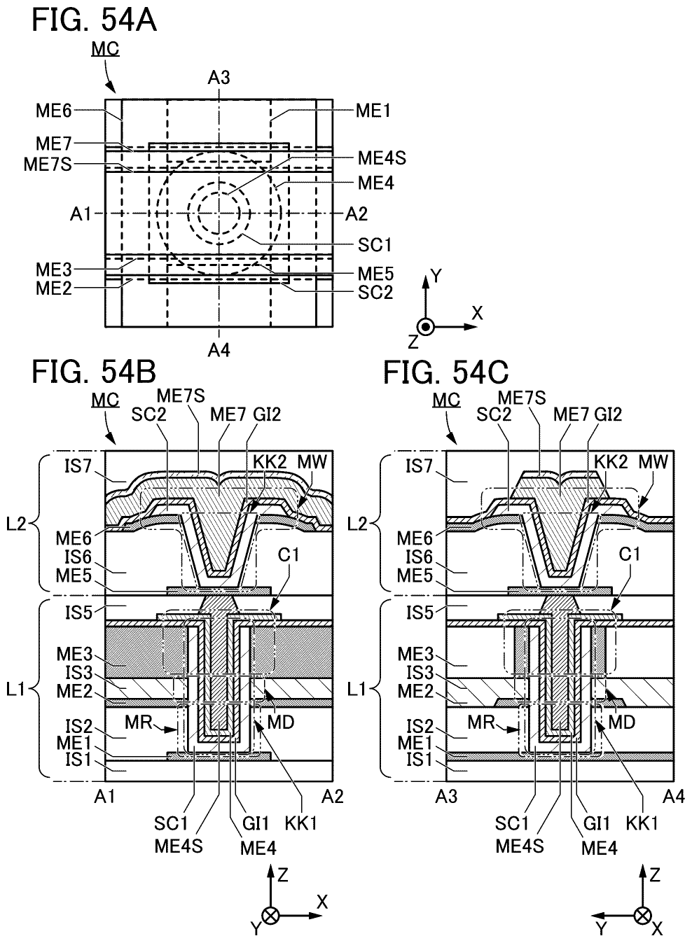

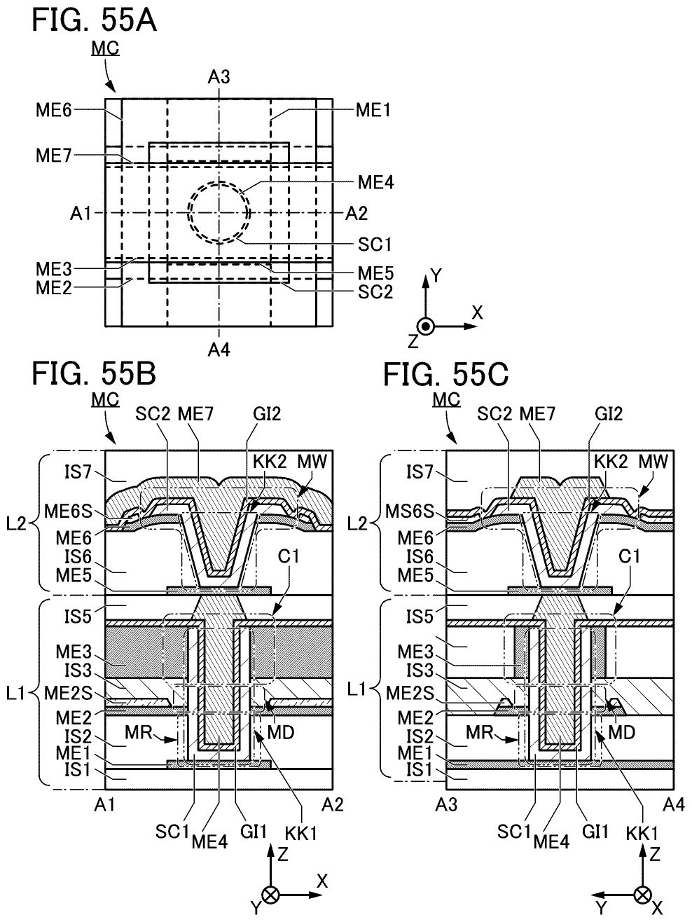

An auxiliary electrode similar to the conductor ME4S may be provided in another portion. As illustrated in FIG. 54A to FIG. 54C, for example, a conductor ME7S may be provided over the conductor ME7 as an auxiliary electrode like the conductor ME4S. As illustrated in FIG. 55A to FIG. 55C, for example, a conductor ME2S and a conductor ME6S may be provided over the conductor ME2 and the conductor ME6, respectively, as auxiliary electrodes similar to the conductor ME4S.

As the film formation method of the conductor ME2S, the conductor ME6S, and the conductor ME7S, a sputtering method, a CVD method, an MBE method, a PLD method, or an ALD method is used, for example. For the conductor ME2S, a material having lower resistivity than the conductor ME2 among the materials that can be used for the conductor ME1 is preferably used, for example. For the conductor ME6S, a material having lower resistivity than the conductor ME6 among the materials that can be used for the conductor ME1 is preferably used, for example. For the conductor ME7S, a material having lower resistivity than the conductor ME7 among the materials that can be used for the conductor ME1 is preferably used, for example.

When the auxiliary electrode is provided over the conductor as in the memory cell MC illustrated in FIG. 53A to FIG. 53C, the memory cell MC illustrated in FIG. 54A to FIG. 54C, and the memory cell MC illustrated in FIG. 55A to FIG. 55C, the electrical resistance of a wiring including the conductor and the auxiliary electrode can be reduced, resulting in reduced power consumption of the memory cell MC.

### Modification Example 12

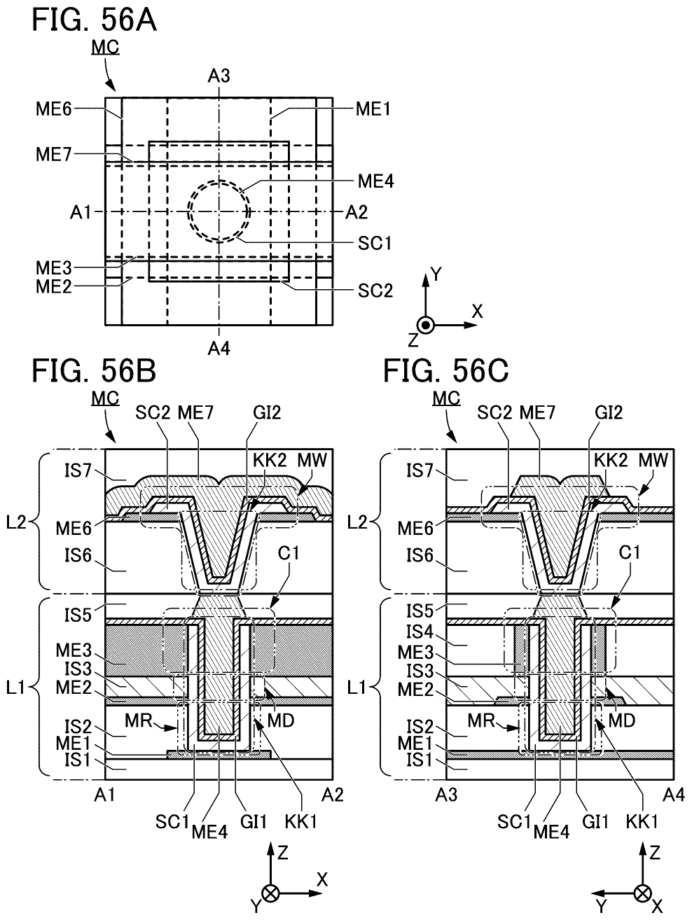

The memory cell MC illustrated in FIG. 56A to FIG. 56C is a modification example of the memory cell MC in FIG. 2A to FIG. 2C, and is different from the memory cell MC in FIG. 2A to FIG. 2C in that the conductor ME5 is not provided.

The memory cell MC in FIG. 56A to FIG. 56C has a structure in which, for example, the insulating film IS6A and the conductive film ME6A are formed in this order over the insulator IS5 and the conductor ME4 and the opening KK2 is provided in a region of the insulating film IS6A and the conductive film ME6A, which overlaps with the conductor ME4.

As described above, the memory cell MC in FIG. 56A to FIG. 56C has a structure in which the conductor ME5 is not provided, which is different from the structure of the memory cell MC in FIG. 2A to FIG. 2C. Accordingly, the memory cell MC in FIG. 56A to FIG. 56C can be manufactured more simply than the memory cell MC in FIG. 2A to FIG. 2C.

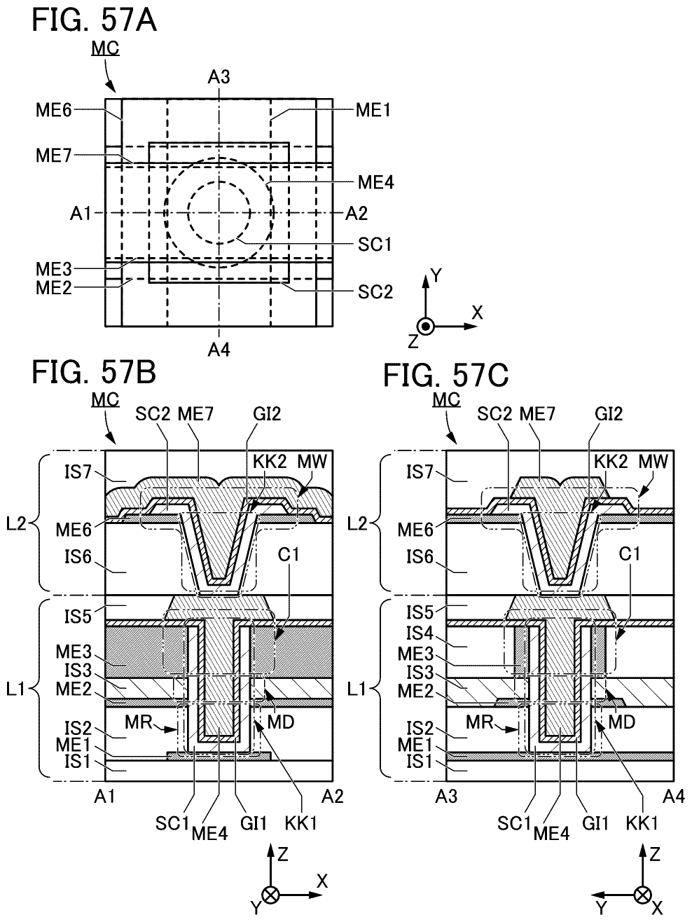

The structure in which the conductor ME5 is not provided can also be employed for the memory cell MC in any of the other modification examples described above. For example, the step of forming the conductor ME5 is eliminated from the method for manufacturing the memory cell MC in FIG. 36A to FIG. 36C, whereby the memory cell MC illustrated in FIG. 57A to FIG. 57C can be manufactured.

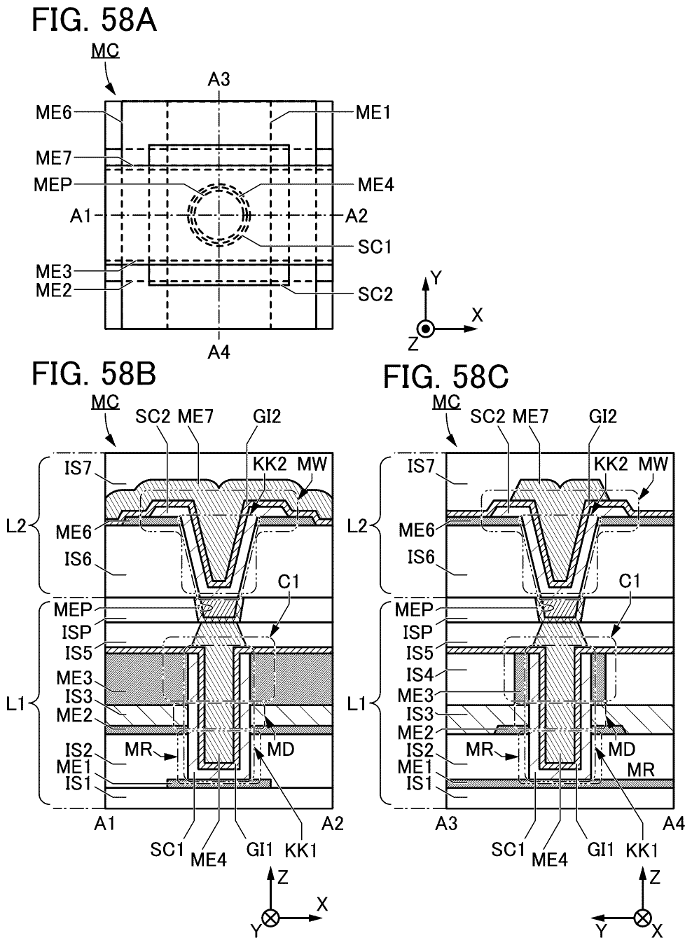

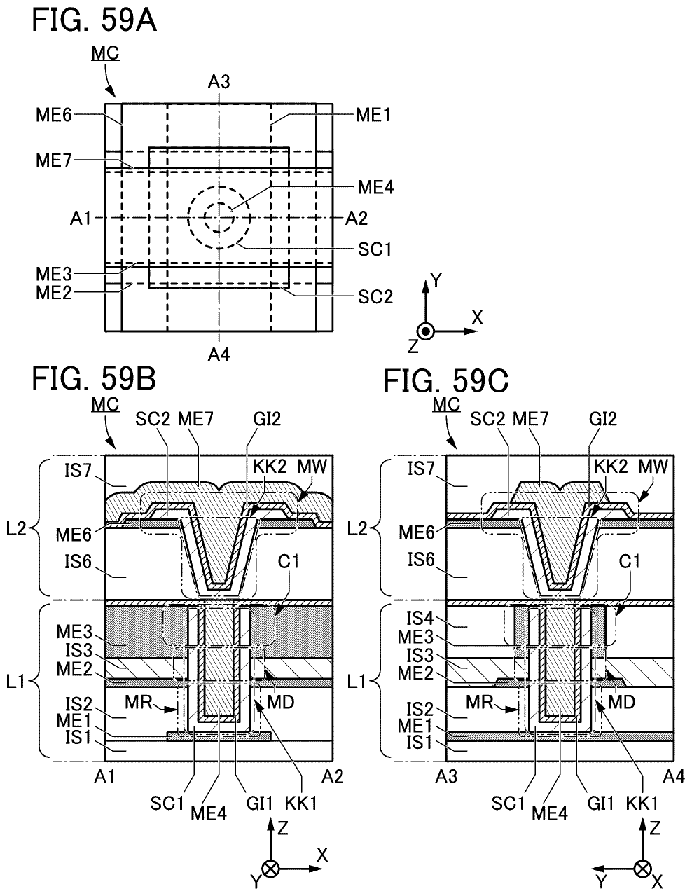

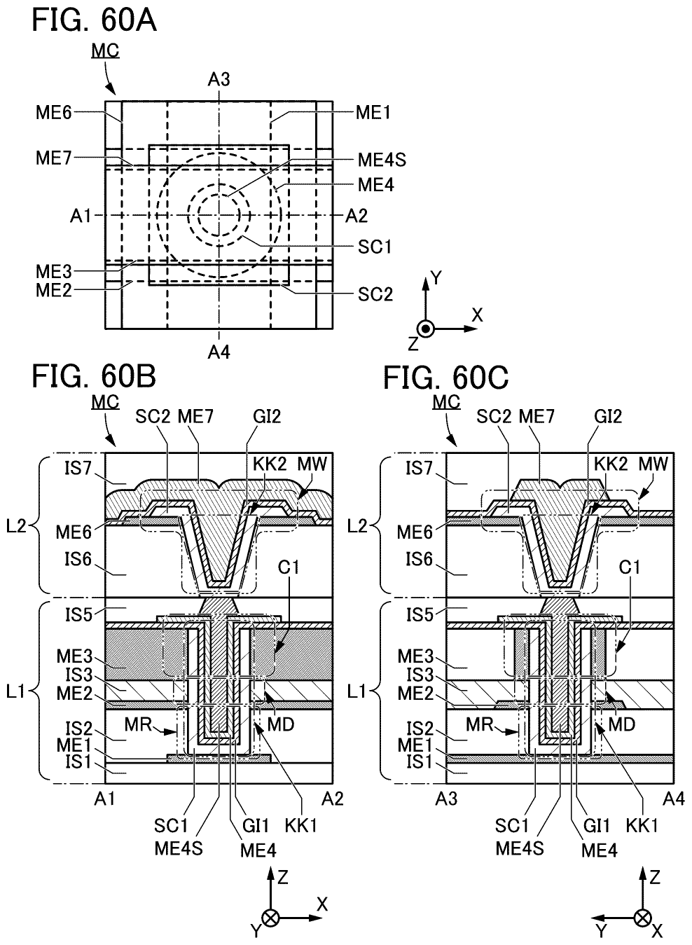

Furthermore, for example, the step of forming the conductor ME5 is eliminated from the method for manufacturing the memory cell MC in FIG. 37A to FIG. 37C, whereby the memory cell MC illustrated in FIG. 58A to FIG. 58C can be manufactured. For example, the step of forming the conductor ME5 is eliminated from the method for manufacturing the memory cell MC in FIG. 39A to FIG. 39C, whereby the memory cell MC illustrated in FIG. 59A to FIG. 59C can be manufactured. For example, the step of forming the conductor ME5 is eliminated from the method for manufacturing the memory cell MC in FIG. 53A to FIG. 53C, whereby the memory cell MC illustrated in FIG. 60A to FIG. 60C can be manufactured.

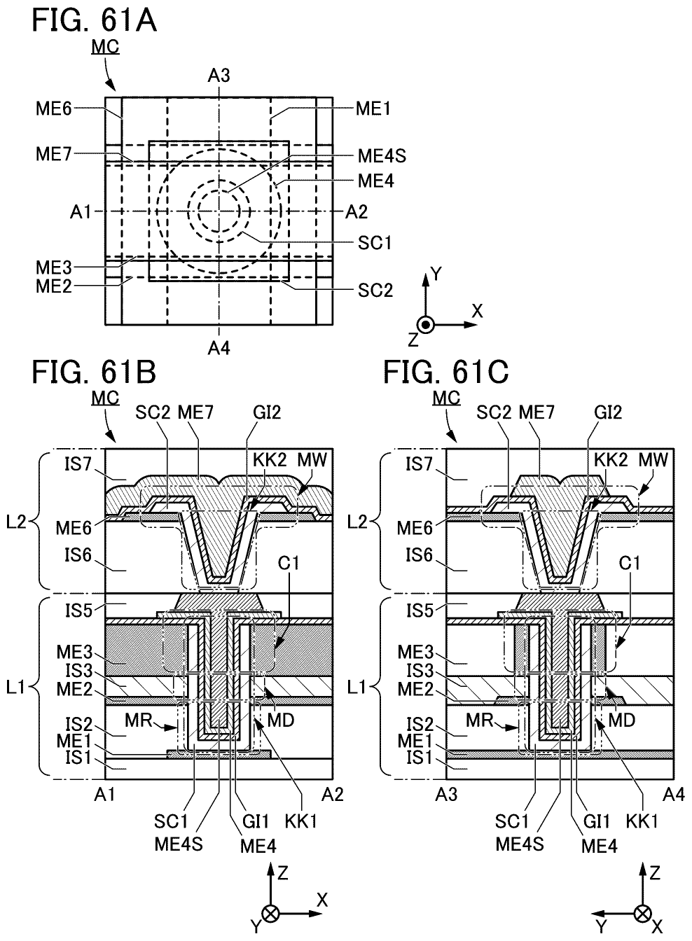

In the case where the step of forming the conductor ME5 is eliminated from the method for manufacturing the memory cell MC, the semiconductor SC2 included in the transistor MW is in direct contact with the conductor ME4. In this case, the conductor ME4 preferably has a large area in order to facilitate the formation of the semiconductor SC2 over the conductor ME4 (facilitate the formation of the opening KK2 in a region of the insulator IS6 overlapping with the conductor ME4, to be exact). For example, the conductor ME4S is formed to have a large area as in the memory cell MC illustrated in FIG. 61A to FIG. 61C, whereby poor connection between the conductor ME4 and the semiconductor SC2 can be prevented in the case of the memory cell MC in FIG. 60A to FIG. 60C.

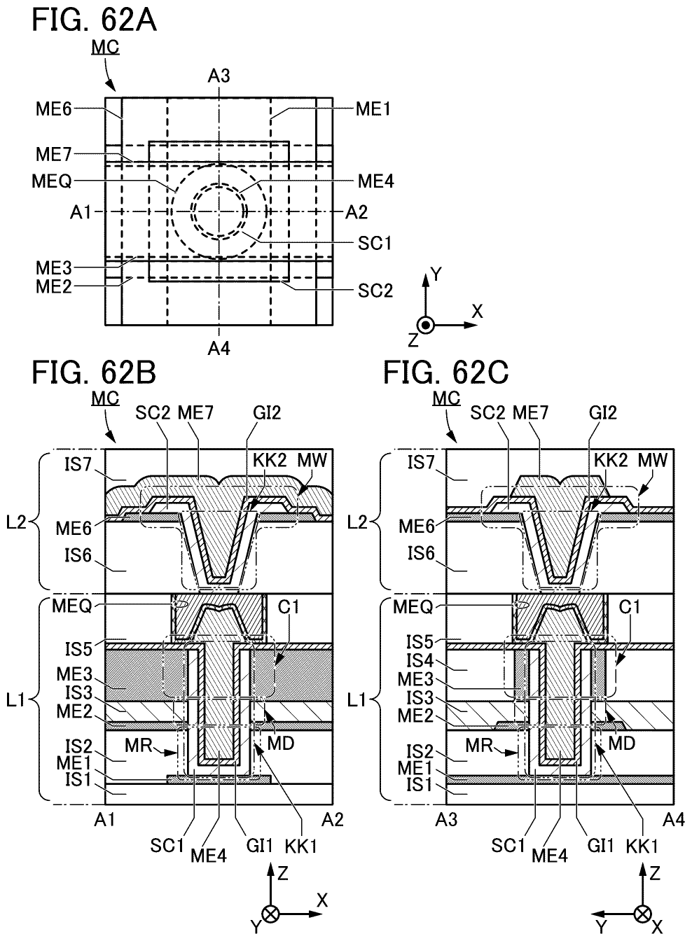

FIG. 62A to FIG. 62C illustrate a structure example of the memory cell MC in which the conductor ME4 and the semiconductor SC2 are easily in contact with each other without providing the conductor ME5. The memory cell MC illustrated in FIG. 62A to FIG. 62C is a modification example of the memory cell MC in FIG. 2A to FIG. 2C, and has a structure in which a conductor MEQ is provided over the conductor ME4 and the insulator GI1 and a transistor MW is formed over the conductor MEQ.

An example of the method for manufacturing the memory cell MC illustrated in FIG. 62A to FIG. 62C is as follows. After the manufacturing step of the memory cell MC in FIG. 22A to FIG. 22C, an opening is formed in a region of the insulator ISSA which includes the conductor ME4. Note that in the plan view, the area of the opening is preferably larger than that of the conductor ME4 (not illustrated). Next, a film of the conductor MEQ is formed to fill the opening, and then the conductor MEQ is polished by planarization treatment until the insulator IS5 is exposed. After that, the step of manufacturing the memory cell MC in FIG. 26A to FIG. 26C and the subsequent steps are successively performed, whereby the memory cell MC in FIG. 62A to FIG. 62C can be manufactured.

The area of the conductor MEQ is increased in the plan view in the memory cell MC in FIG. 62A to FIG. 62C, as in FIG. 61A to FIG. 61C, whereby the semiconductor SC2 is easily formed over the conductor MEQ (to be exact, the opening KK2 is easily formed in a region of the insulator IS6 overlapping with the conductor MEQ). This can prevent poor connection between the conductor MEQ and the semiconductor SC2.

As a film formation method of the conductor MEQ, a sputtering method, a CVD method, an MBE method, a PLD method, or an ALD method is used, for example. For the conductor MEQ, any of the materials that can be used for the conductor ME1 can be used, for example. Although the conductor MEQ has a stacked-layer structure of two layers in FIG. 60B and FIG. 60C, the present invention is not limited thereto. The conductor MEQ may have a single-layer structure or a stacked-layer structure of three or more layers.

### Modification Example 13

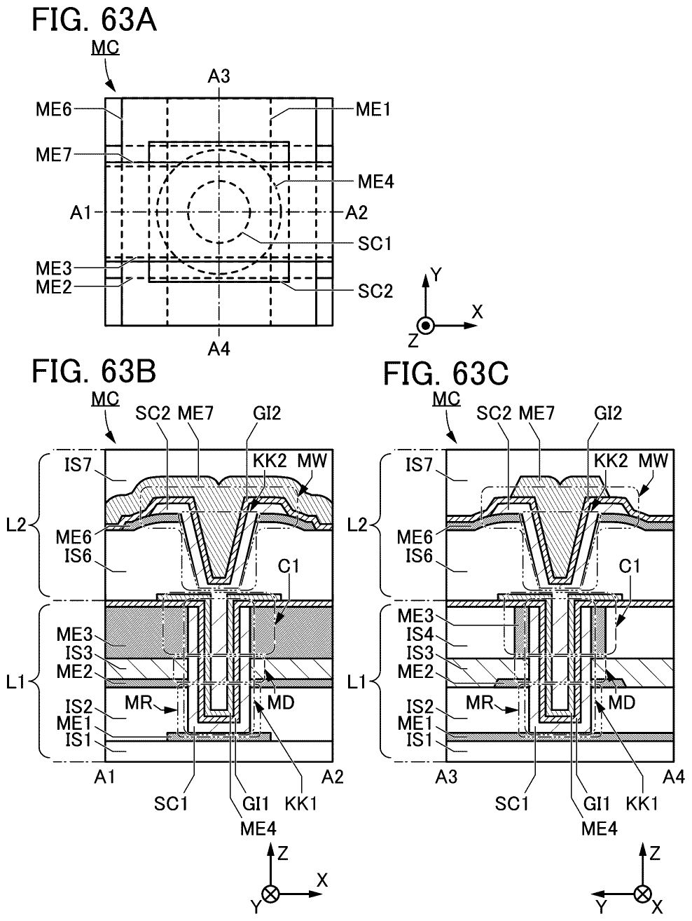

The memory cell MC illustrated in FIG. 63A to FIG. 63C is an example of further modification of the memory cell MC in FIG. 60A to FIG. 60C (FIG. 61A to FIG. 61C), and is different from the memory cell MC in FIG. 60A to FIG. 60C (FIG. 61A to FIG. 61C) in that the semiconductor SC2 of the transistor MW fills the inner part of the opening KK1, instead of the conductor ME4S.

An example of the method for manufacturing the memory cell MC illustrated in FIG. 63A to FIG. 63C is as follows. After the manufacturing step of the memory cell MC in FIG. 19A to FIG. 19C, a film of the insulator GI1 and a conductive film to be the conductor ME4 are formed in this order from the bottom. Next, a lithography method is used to form the conductor ME4 so that the conductive film is left in the opening KK1, over part of the conductor ME3, and over part of the conductor IS4. Then, an insulating film to be the insulator IS6 is formed over the conductor ME4 and the insulator GI1, and the conductive film to be the conductor ME6 is formed over the insulating film to be the insulator IS6. Next, the conductive film to be the conductor ME6 is processed by a lithography method, thereby forming a wiring extending in the Y direction. Then, by a lithography method, an opening is provided in a region of the conductive film to be the conductor ME6 and the insulating film to be the insulator IS6, which overlaps with the opening KK1. The opening corresponds to the bottom surface and the side surface of the conductor ME4 in the layer L1. Moreover, the insulator IS6 and the conductor ME6 are formed by the processing. Next, a film of the semiconductor SC1 is formed to fill the opening in the layer L1 and to be positioned on the side surface of the insulator IS6 and the side surface and the top surface of the conductor ME6. After that, the step of manufacturing the memory cell MC in FIG. 30A to FIG. 30C and the subsequent steps are successively performed, whereby the memory cell MC in FIG. 63A to FIG. 63C can be manufactured.

The memory cell MC illustrated in FIG. 63A to FIG. 63C does not need formation of the conductor ME4S and the insulator IS5 and accordingly can be manufactured more simply than the memory cell MC in FIG. 60A to FIG. 60C (FIG. 61A to FIG. 61C).

### Modification Example 14

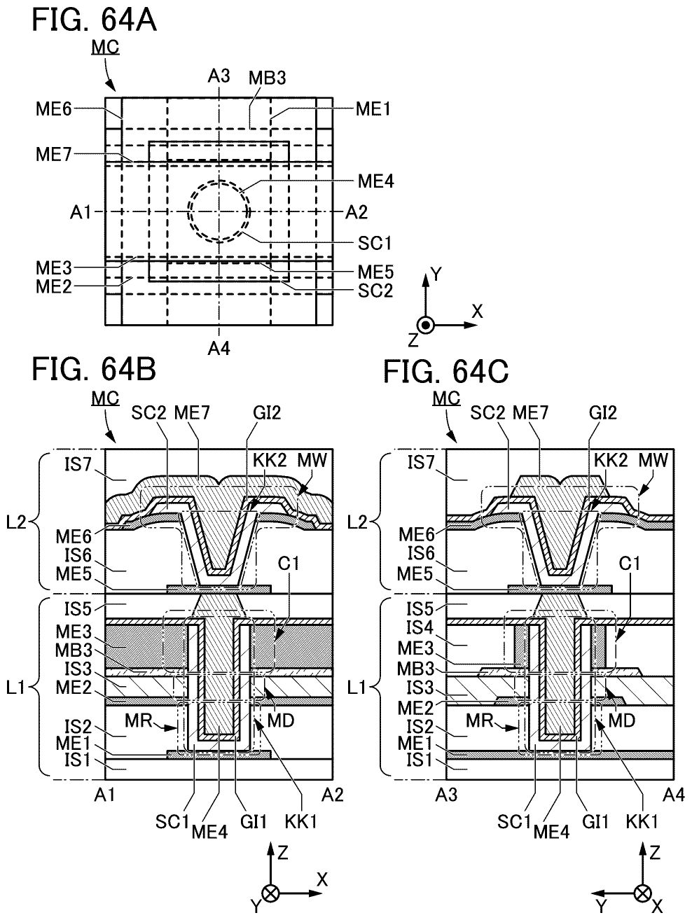

The memory cell MC illustrated in FIG. 64A to FIG. 64C is a modification example of the memory cell MC in FIG. 2A to FIG. 2C, and has a structure in which a conductor MB3 functioning as an auxiliary electrode is formed below the conductor ME3.

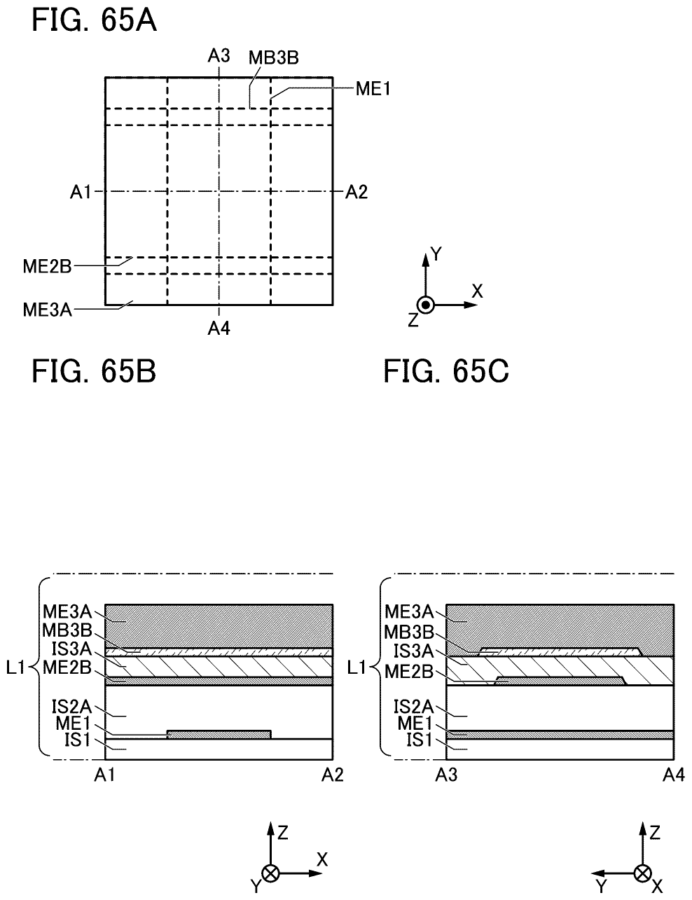

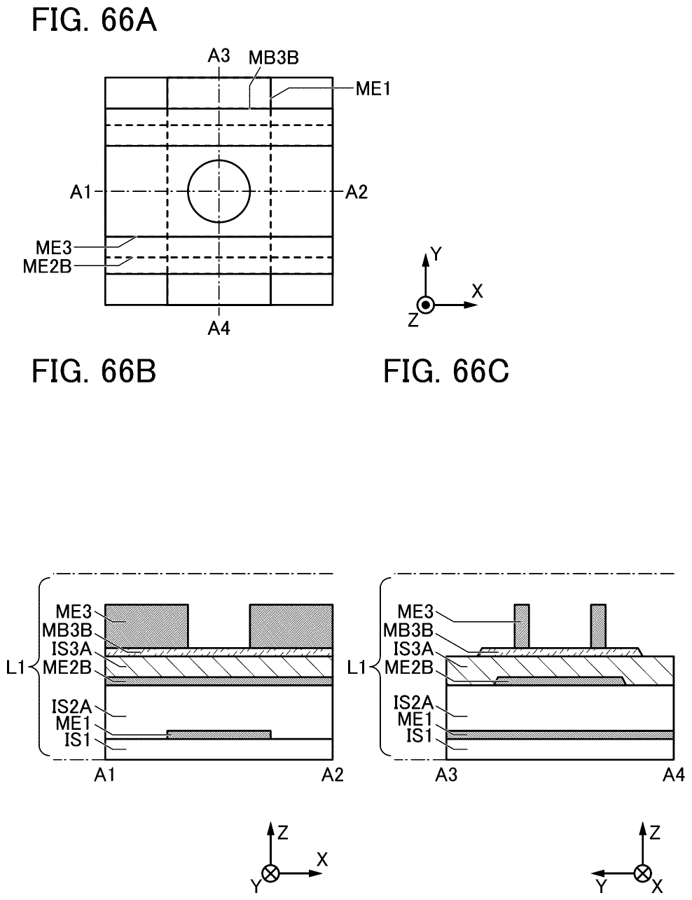

An example of the method for manufacturing the memory cell MC illustrated in FIG. 64A to FIG. 64C is as follows. In the manufacturing step of the memory cell MC in FIG. 13A to FIG. 13C, a conductive film MB3B to be the conductor MB3 is formed between the insulating film IS3A and the conductive film ME3A (see FIG. 65A to FIG. 65C). To obtain the conductive film MB3B, the conductive film to be the conductive film MB3B is formed over the insulator IS3A and is processed by a lithography method. Next, as in FIG. 14A to FIG. 14C, the conductive film ME3A is processed into a belt-like shape including an opening, so that the conductor ME3 is formed. Specifically, the opening is formed in a region where the conductor ME1 and the conductive film ME2B overlap with each other (see FIG. 66A to FIG. 66C).

Next, as in FIG. 15A to FIG. 15C, the insulating film IS4A is formed (not illustrated) over the insulating film IS3A and the conductor ME3. After the formation of the insulating film IS4A, the insulating film IS4A is polished (not illustrated) by planarization treatment by a CMP method or the like until the conductor ME3 is exposed, as in FIG. 16A to FIG. 16C.

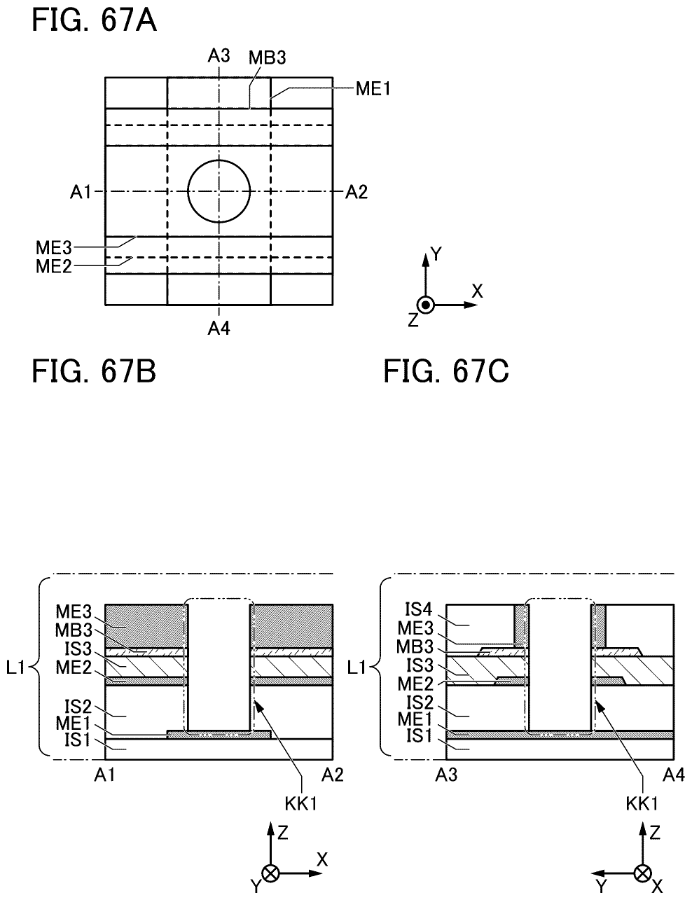

Next, as in FIG. 17A to FIG. 17C, the insulating film IS2A, the conductive film ME2B, a conductor MB3B, the insulating film IS3A, and the insulating film IS4B are processed by a lithography method to form the insulator IS2, the conductor ME2, the conductor MB3, the insulator IS3, and the insulator IS4, which include the opening KK1 (see FIG. 67A to FIG. 67C).

After that, the step of manufacturing the memory cell MC in FIG. 18A to FIG. 18C and the subsequent steps are successively performed, whereby the memory cell MC in FIG. 64A to FIG. 64C can be manufactured.

Although the memory cell MC in FIG. 64A to FIG. 64C has a structure in which the conductor MB3 functioning as an auxiliary electrode is formed below the conductor ME3, the semiconductor device of one embodiment of the present invention may have a structure in which the auxiliary electrode is formed above the conductor ME3.

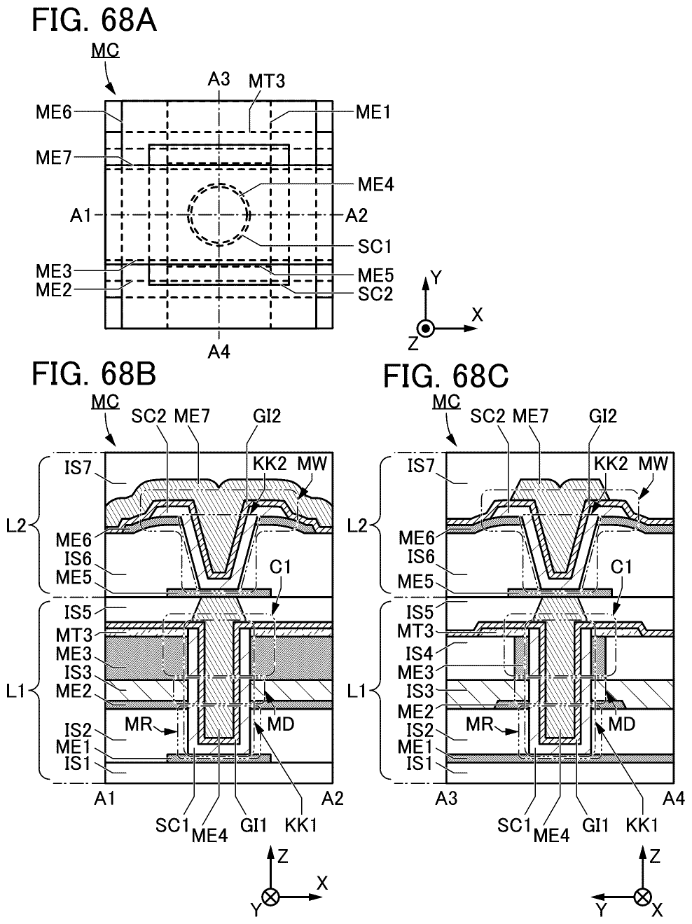

The memory cell MC illustrated in FIG. 68A to FIG. 68C is a modification example of the memory cell MC in FIG. 2A to FIG. 2C, and has a structure in which a conductor MT3 functioning as an auxiliary electrode is formed above the conductor ME3.

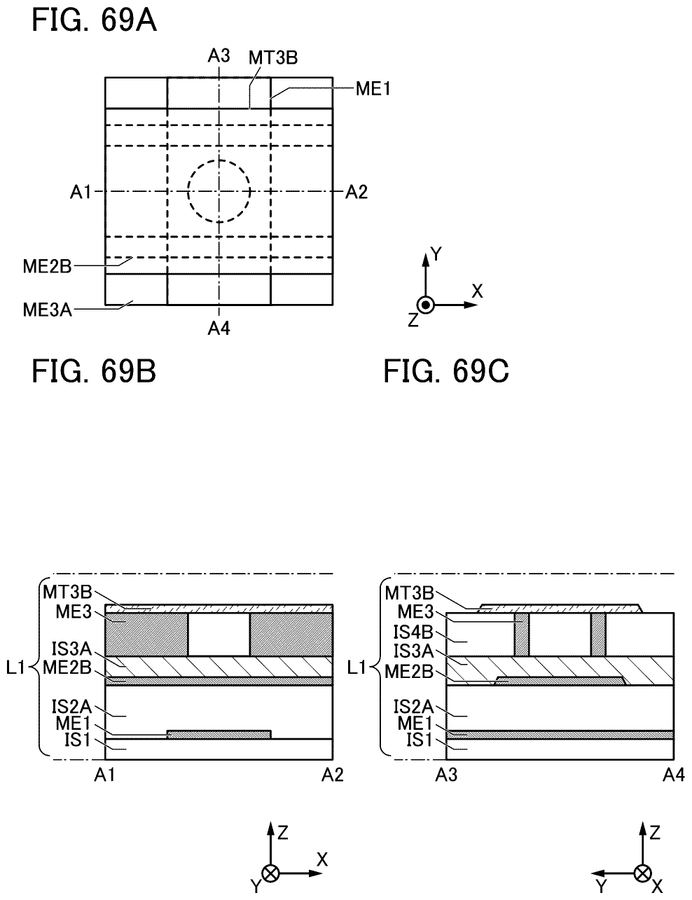

An example of the method for manufacturing the memory cell MC illustrated in FIG. 68A to FIG. 68C is as follows. In the manufacturing step of the memory cell MC in FIG. 16A to FIG. 16C, a conductive film MT3B to be the conductor MT3 is formed over the insulating film IS4B and the conductor ME3 (see FIG. 69A to FIG. 69C). To obtain the conductive film MT3B, a conductive film to be the conductive film MT3B is formed over the insulating film IS4B and the conductive film ME3A and the conductive film is processed by a lithography method.

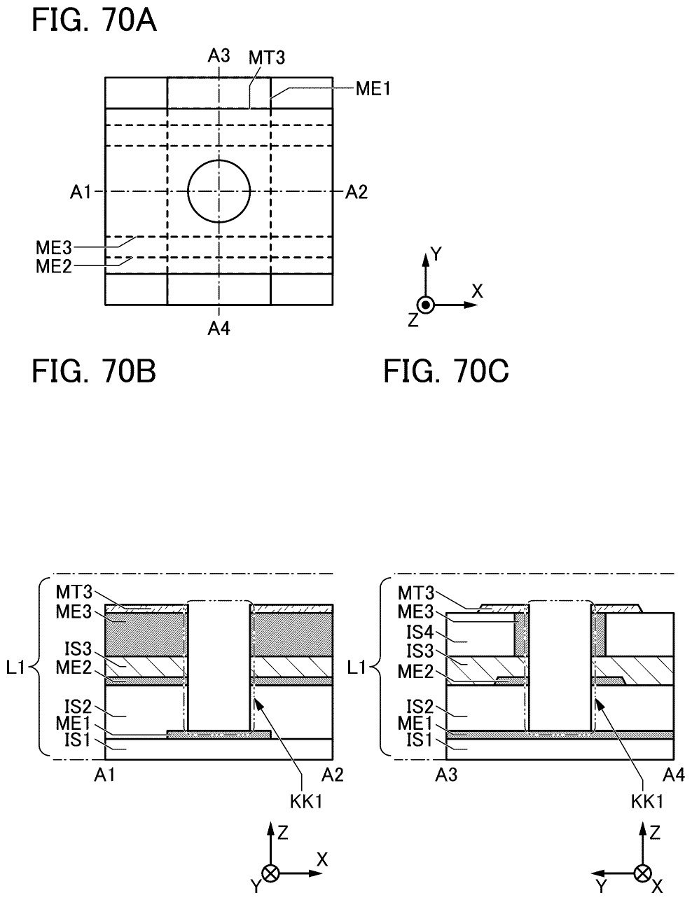

Next, as in FIG. 17A to FIG. 17C, the insulating film IS2A, the conductive film ME2B, the insulating film IS3A, the insulating film IS4B, and the conductor MT3B are processed by a lithography method to form the insulator IS2, the conductor ME2, the insulator IS3, the conductor MT3, and the insulator IS4, which include the opening KK1 (see FIG. 70A to FIG. 70C). After that, the step of manufacturing the memory cell MC in FIG. 18A to FIG. 18C and the subsequent steps are successively performed, whereby the memory cell MC in FIG. 68A to FIG. 68C can be manufactured

When an auxiliary electrode is provided under a conductor or over a conductor as in the memory cell MC illustrated in FIG. 64A to FIG. 64C and the memory cell MC illustrated in FIG. 68A to FIG. 68C, the electrical resistance of a wiring including the conductor and the auxiliary electrode can be reduced and the power consumption of the memory cell MC can be reduced.

### Modification Example 15

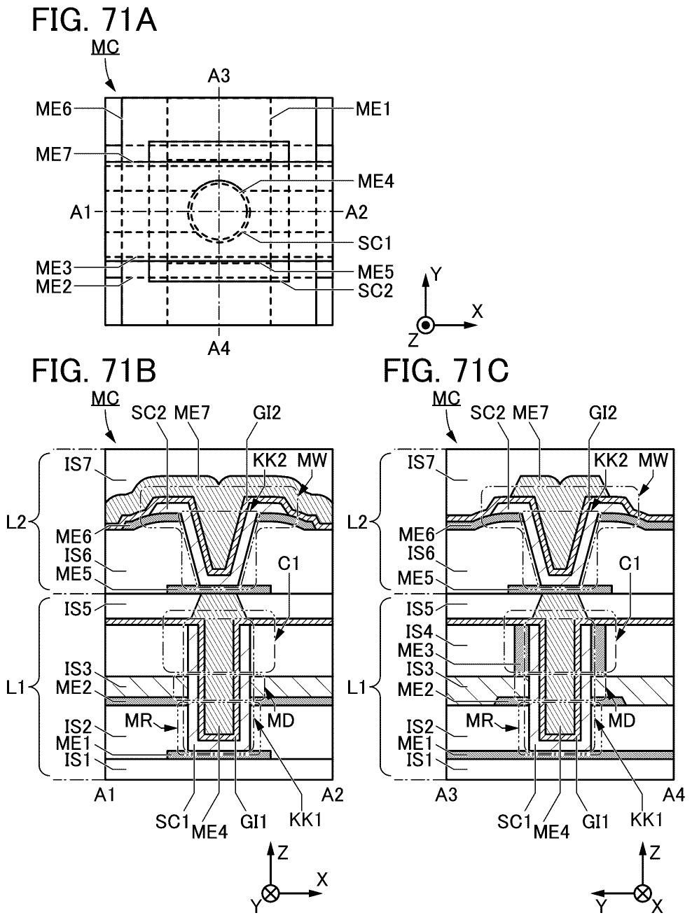

The memory cell MC illustrated in FIG. 71A to FIG. 71C is a modification example of the memory cell MC in FIG. 2A to FIG. 2C and has a structure in which the opening KK1 is interposed between conductors ME3 in the Y direction.

The memory cell MC in FIG. 71A to FIG. 71C can be manufactured by, for example, modifying the shape resulting from the processing from the conductive film ME3A into the conductor ME3 in the manufacturing step of the memory cell MC illustrated in FIG. 14A to FIG. 14C. Specifically, the conductive film ME3A is processed by a lithography method so that the opening KK1 is interposed between two conductors ME3 in the X direction.

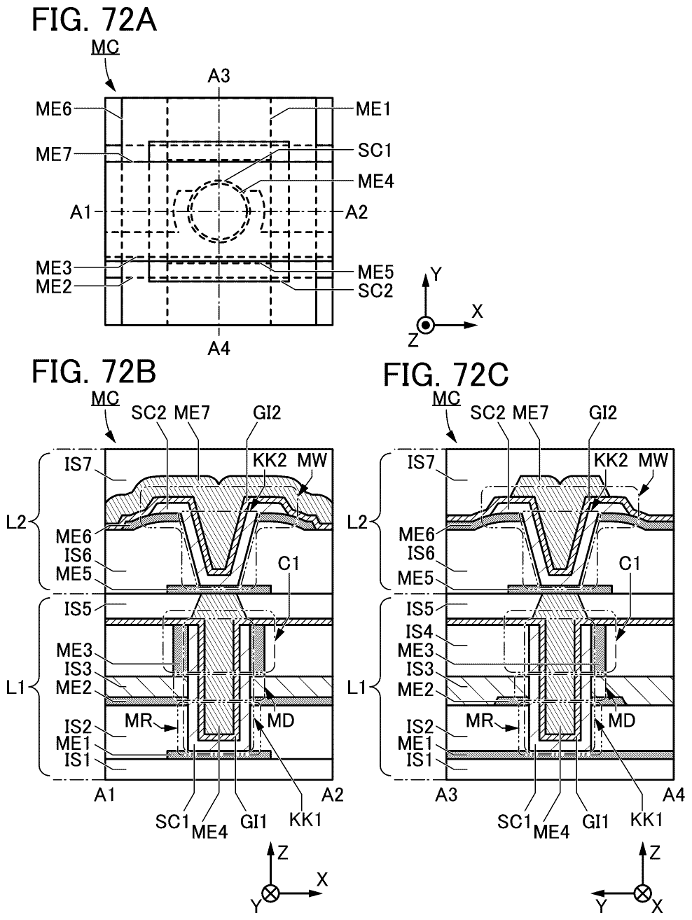

The shape of the conductors ME3 positioned around the opening KK1 may be that in the structure of the memory cell MC illustrated in FIG. 72A to FIG. 72C, instead of that in the structure of the memory cell MC illustrated in FIG. 71A to FIG. 71C. The memory cell MC illustrated in FIG. 72A to FIG. 72C has a structure in which the conductor ME3 having a U shape is formed around the opening KK1 in the plan view.

When the shape of the conductor ME3 around the opening KK1 is changed as in the memory cell MC illustrated in FIG. 71A to FIG. 71C or the memory cell MC illustrated in FIG. 72A to FIG. 72C, the electrostatic capacitance value of the capacitor C1 included in the memory cell MC can be increased or decreased. In the case where the electrostatic capacitance value of the capacitor C1 is increased, the data retention time for the memory cell MC is increased and the operation speed of the memory cell MC may be slowed down accordingly. The electrostatic capacitance value of the capacitor C1 is decreased for higher operation speed of the memory cell MC or alternatively is increased for longer data retention time of the memory cell MC in the manufacturing stage of the memory cell MC.

### Modification Example 16

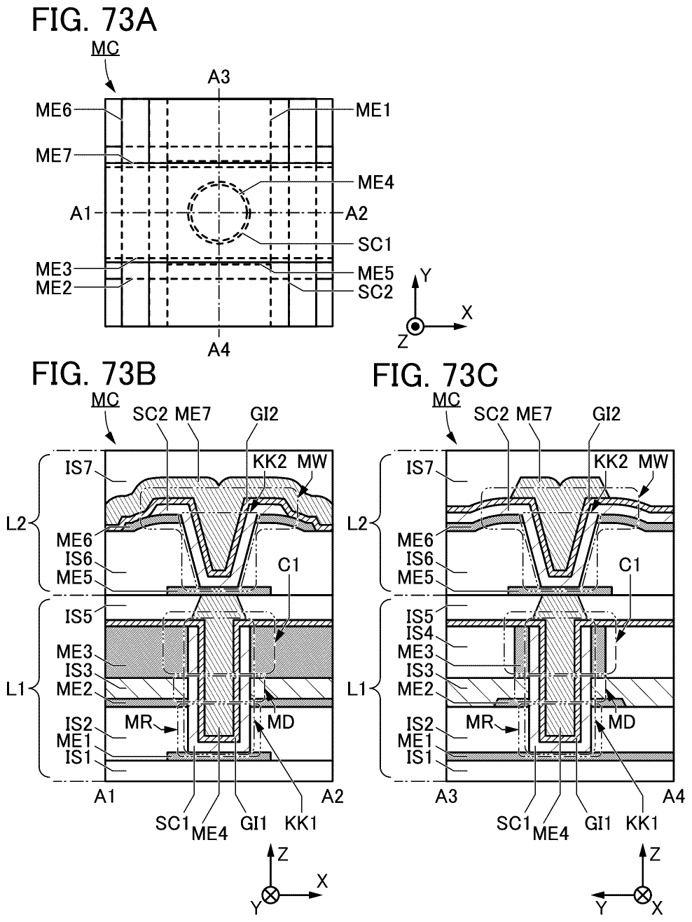

The memory cell MC illustrated in FIG. 73A to FIG. 73C is a modification example of the memory cell MC in FIG. 2A to FIG. 2C and has a structure in which the semiconductor SC2 extends in the Y direction.

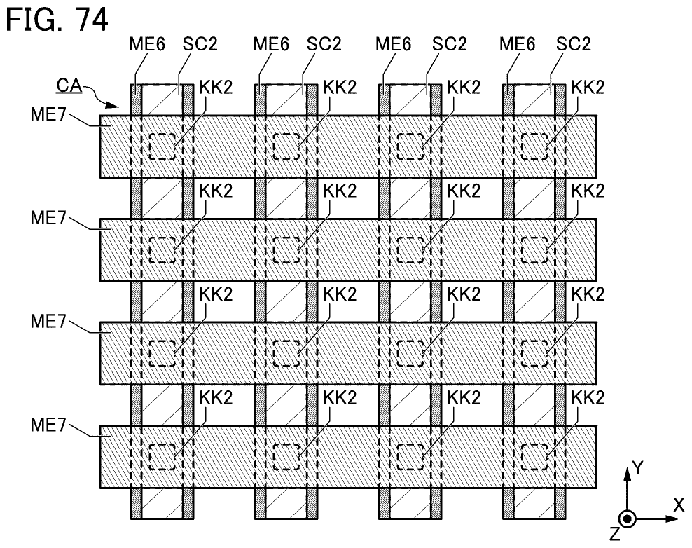

Specifically, the semiconductor SC2 of the memory cell MC in FIG. 73A to FIG. 73C is positioned over the side surface and the bottom surface of the opening KK2 and formed over part of the conductor ME6 so as to, like the conductor ME6, extend along the Y direction in the cell array CA, as illustrated in FIG. 74.

The memory cell MC illustrated in FIG. 73A to FIG. 73C can be manufactured as follows: in the manufacturing step of the memory cell MC in FIG. 30A to FIG. 30C, for example, the semiconductor film SC2A is processed by a lithography method to form the semiconductor SC2 so that part of the insulator IS6 and part of the conductor ME6 are exposed and extend in the Y direction.

In the memory cell MC illustrated in FIG. 73A to FIG. 73C, the semiconductor SC2 is formed over the conductor ME6 extending in the Y direction. In this case, the conductor ME6 may contain an impurity against the semiconductor SC2 in order to reduce the resistance of the interface of the semiconductor SC2 in contact with the conductor ME6 and the vicinity of the interface. Specifically, for example, in the case where the semiconductor SC2 is a metal oxide (e.g., an In-M-Zn oxide), the conductor ME6 may contain an impurity such as water, hydrogen, nitrogen, or a nitride in order to reduce the resistance of the metal oxide. By the reduction in the resistance of the region of the semiconductor SC2 positioned over the conductor ME6, the region of the semiconductor SC2 functions as an auxiliary electrode in the conductor ME6. Accordingly, the resistance value of the wiring WBL including the conductor ME6 can be small, so that the power consumption of the memory cell MC can be reduced.

Although the conductor ME6 and the semiconductor SC2 in the memory cell MC illustrated in FIG. 73A to FIG. 73C are formed by a lithography method at different timings, the conductor ME6 and the semiconductor SC2 may be formed at the same time.

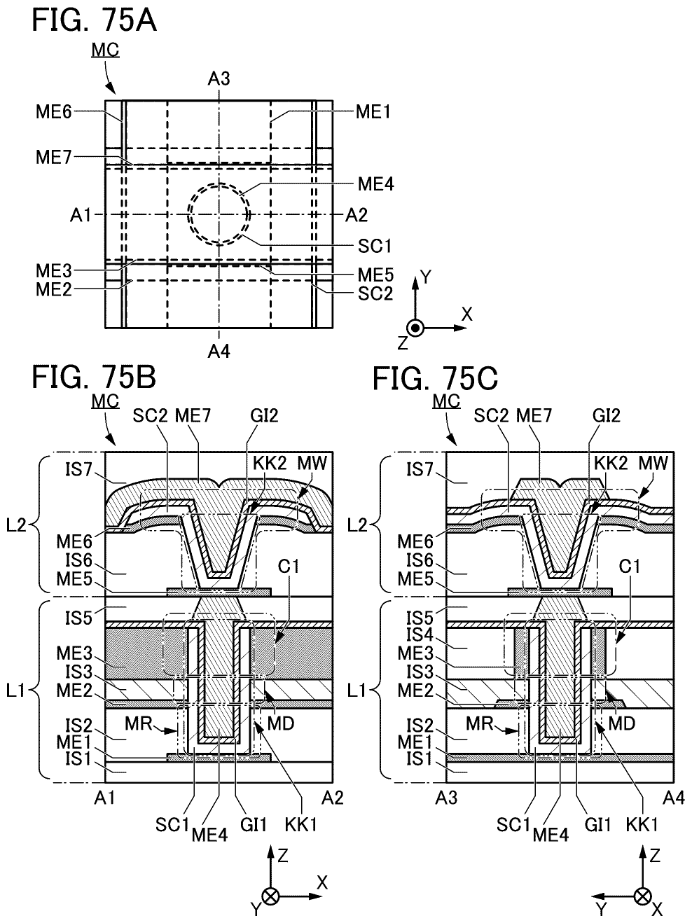

The memory cell MC illustrated in FIG. 75A to FIG. 75C is a modification example of the memory cell MC in FIG. 73A to FIG. 73C and has a structure in which the conductor ME6 and the semiconductor SC2 are formed at the same time.

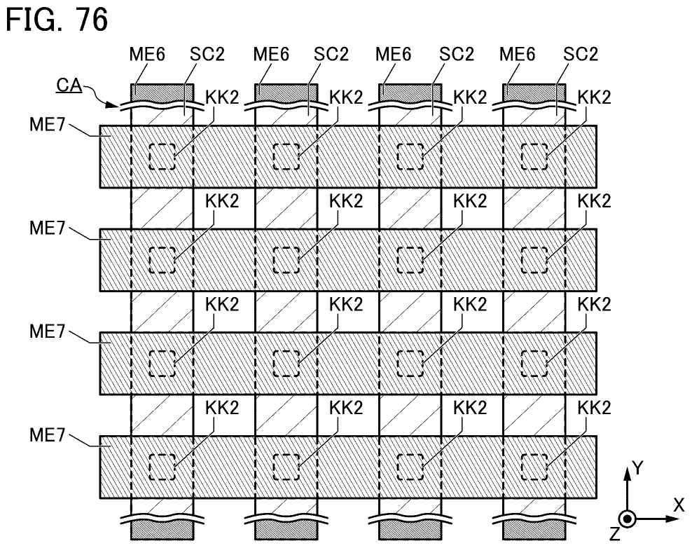

Thus, the semiconductor SC2 of the memory cell MC in FIG. 75A to FIG. 75C is formed to almost overlap with the conductor ME6 in the cell array CA, as illustrated in FIG. 76.

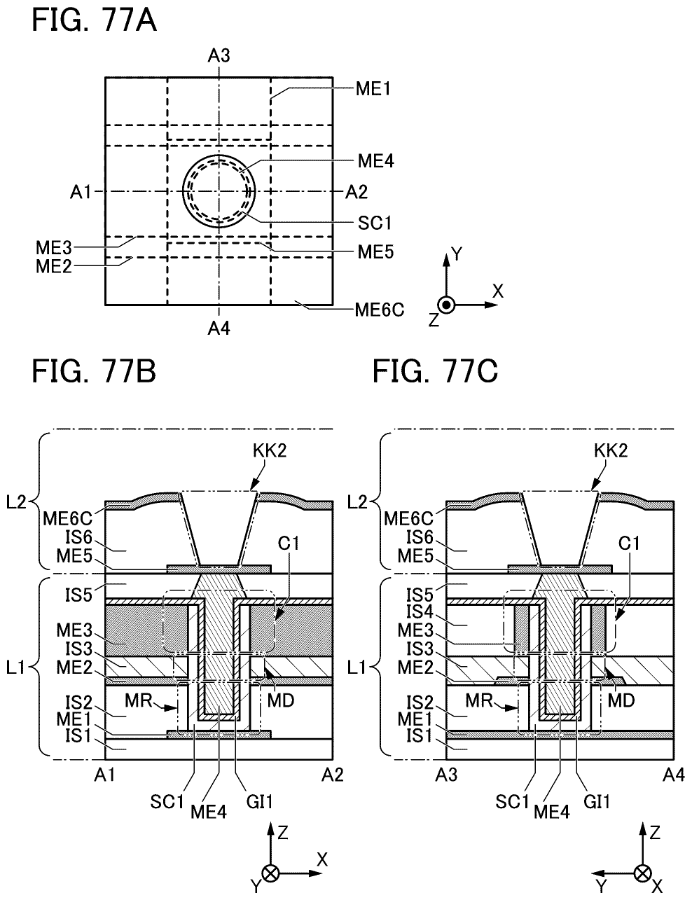

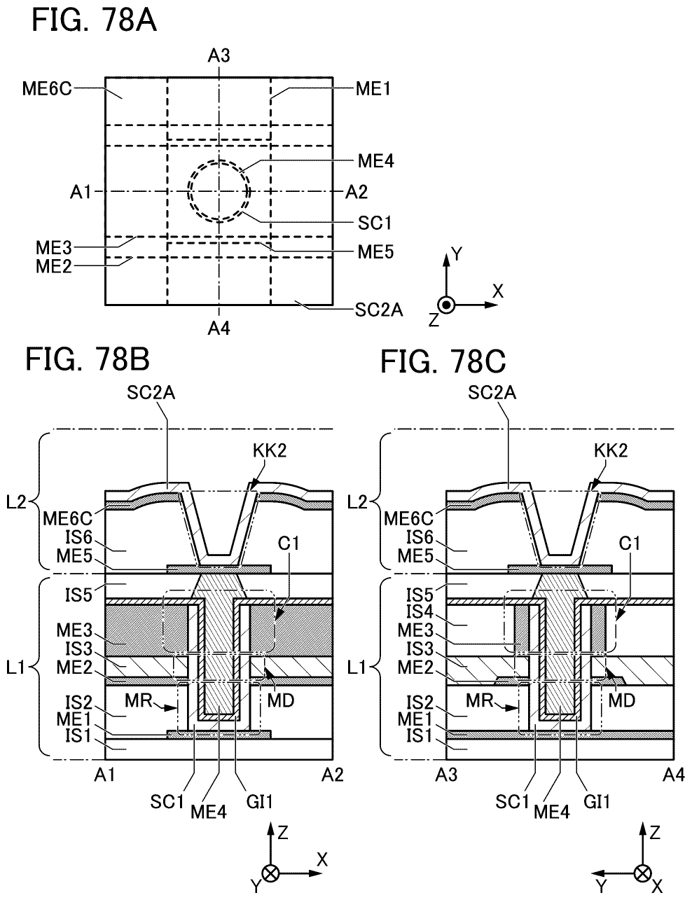

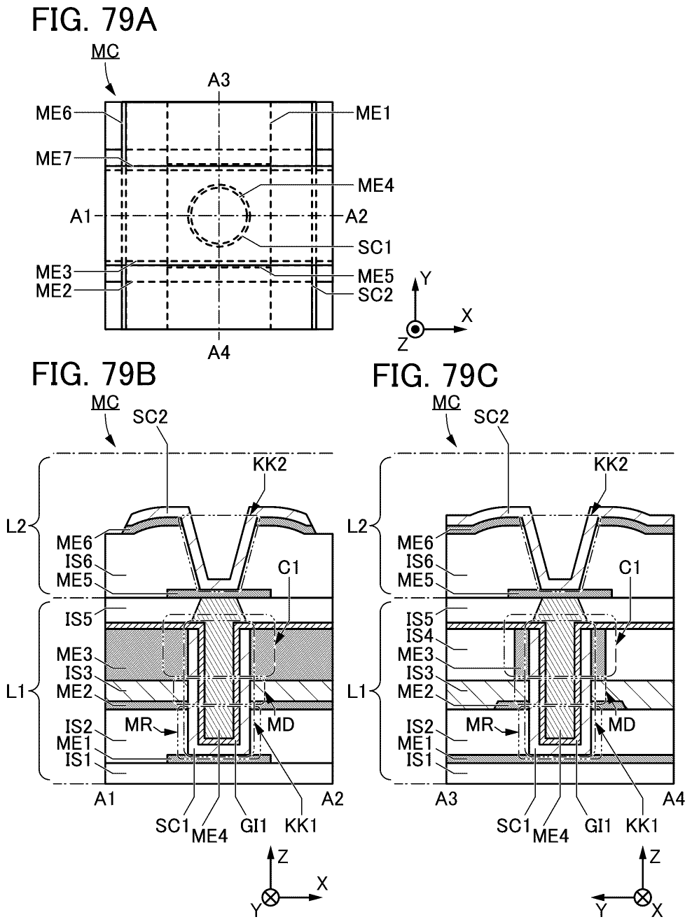

In the manufacturing step of the memory cell MC illustrated in FIG. 75A to FIG. 75C, for example, after the manufacturing step of the memory cell MC in FIG. 26A to FIG. 26C, the insulating film IS6A and the conductive film ME6A are processed by a lithography method to form the insulator IS6 and a conductive film ME6C, which include the opening KK2 (see FIG. 77A to FIG. 77C). Next, the semiconductor film SC2A is formed over a conductor ME6C and the side surface and the bottom surface of the opening KK2 (see FIG. 78A to FIG. 78C). After the formation of the semiconductor film SC2A, the conductor ME6C and the semiconductor SC2 are processed by a lithography method to extend in the Y direction, whereby the conductor ME6 and the semiconductor SC2 are formed (see FIG. 79A to FIG. 79C). After that, the step of manufacturing the memory cell MC in FIG. 31A to FIG. 31C and the subsequent steps are successively performed, whereby the memory cell MC in FIG. 75A to FIG. 75C can be manufactured.

Since the insulator IS6 and the conductor ME6C are formed at the same time in the manufacturing step of the memory cell MC illustrated in FIG. 75A to FIG. 75C, the memory cell MC illustrated in FIG. 75A to FIG. 75C can be manufactured more simply than the memory cell MC illustrated in FIG. 2A to FIG. 2C.

In the memory cell MC illustrated in FIG. 75A to FIG. 75C, the conductor ME6 may contain a material that promotes an increase in the resistance of the semiconductor SC2 in order to increase the resistance of the interface of the semiconductor SC2 in contact with the conductor ME6 and the vicinity of the interface. Specifically, for example, in the case where the semiconductor SC2 is a metal oxide (e.g., an In-M-Zn oxide), the conductor ME6 may contain oxygen to increase the resistance of the metal oxide. In that case, oxygen contained in the conductor ME6 is supplied to the semiconductor SC2, whereby the interface of the semiconductor SC2 in contact with the conductor ME6 and the vicinity of the interface can have higher resistance. The higher resistance of the interface of the semiconductor SC2 and the vicinity of the interface increases the effective insulator thickness of the semiconductor SC2 and the insulator GI2 positioned above the conductor ME6; accordingly, the parasitic capacitance between the conductor ME6 and the conductor ME7 overlapping with the conductor ME6 can be reduced. The reduced parasitic capacitance leads to the higher driving frequency of the transistor MW, thereby increasing the writing operation of the memory cell MC.

In that case, a material that has a low resistance value even when containing oxygen, such as indium oxide or indium tin oxide, is preferably used for the conductor ME6.

### Modification Example 17

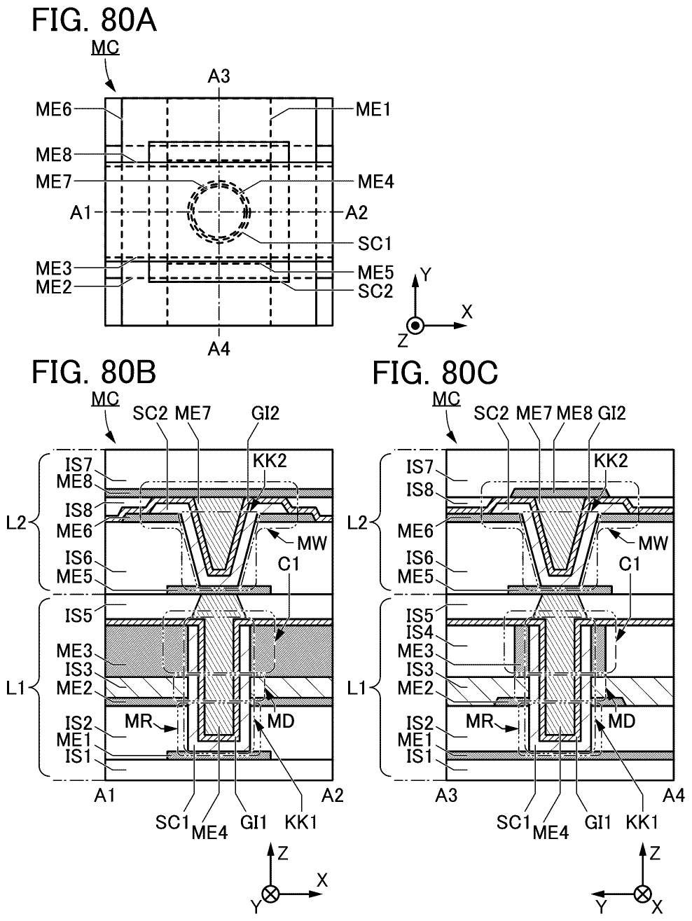

The memory cell MC illustrated in FIG. 80A to FIG. 80C is a modification example of the memory cell MC in FIG. 34A to FIG. 34C and has a structure in which the conductor ME7, the insulator GI2, and an insulator IS8 described later are substantially level with each other. Since the conductor ME7 is formed only in the inner part of the opening KK2, a conductor ME8, which is formed over the conductor ME7 and the insulator GI2, functions as the wiring WWL in the memory cell MC in FIG. 80A to FIG. 80C.

An example of the method for manufacturing the memory cell MC illustrated in FIG. 80A to FIG. 80C is as follows. After the manufacturing step in FIG. 35A to FIG. 35C, the manufacturing steps in FIG. 27A to FIG. 27C to FIG. 31A to FIG. 31C are performed, and the conductive film ME7A is embedded in the opening KK2. Next, the conductive film ME7A is polished by planarization treatment using a CMP method or the like until the insulator GI2 is exposed, whereby the conductor ME7 is formed. After that, an insulating film to be the insulator IS8 is formed over the insulator GI2 and the conductor ME7 to level the insulator GI2. Then, planarization treatment using a CMP method or the like is again performed to polish the insulating film to be the insulator IS8 until the insulator GI2 is exposed, whereby the insulator IS8 is formed. Consequently, the memory cell MC in which the conductor ME7, the insulator GI2, and the insulator IS8 are substantially level with each other can be obtained.

In the formation method in which the conductor ME7 is embedded in the opening KK2, the conductive film to be the conductor ME7 is selected in a self-aligned manner without using a mask to form the conductor ME7. Thus, the conductor ME7 can be formed without an alignment margin, resulting in a reduction in the area occupied by the transistor MW.

As a film formation method of the conductor ME8, a sputtering method, a CVD method, an MBE method, a PLD method, or an ALD method is used, for example. For the conductor ME8, any of the materials that can be used for the conductor ME1 can be used, for example.

As a film formation method of the insulator IS8, a sputtering method, a CVD method, an MBE method, a PLD method, or an ALD method is used, for example. Any of the materials that can be used for the insulator IS1 can be used as the insulator IS8, for example.

The conductor ME8 is formed over the insulator IS8 in a later manufacturing step. For this reason, in order to prevent oxidation of the conductor ME8, for example, silicon nitride is preferably used for the insulator IS8 as a barrier insulating film that inhibits diffusion of oxygen.

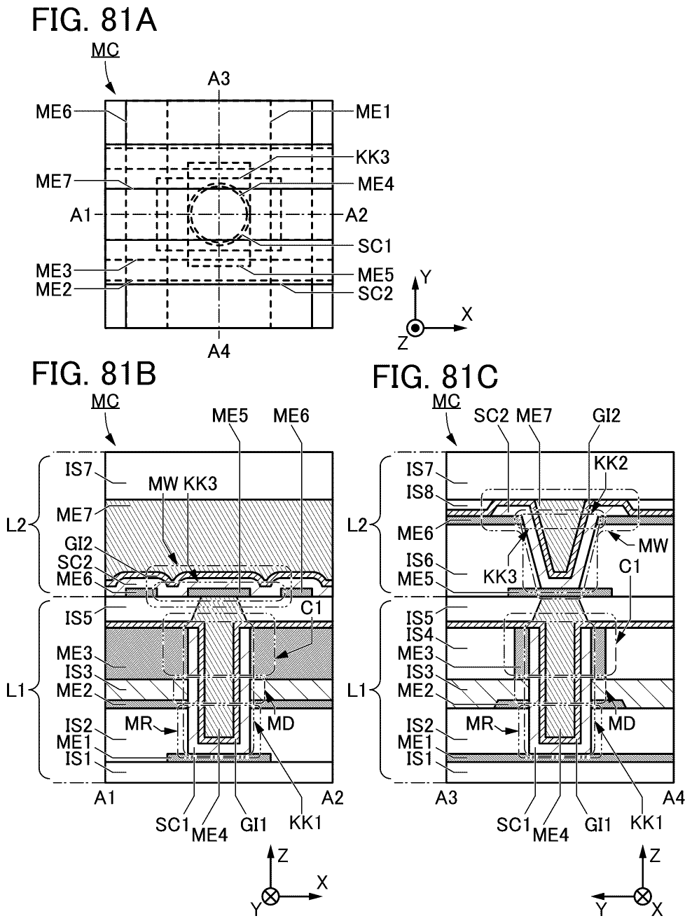

Like the memory cell MC in FIG. 80A to FIG. 80C, the memory cell MC illustrated in FIG. 81A to FIG. 81C has a structure in which the conductor ME7 and the insulator GI2 are substantially level with each other by planarization treatment using a CMP method or the like after the conductor ME7 is embedded in the opening KK2; however, instead of the conductor ME8, the conductor ME7 is used as the wiring WWL.

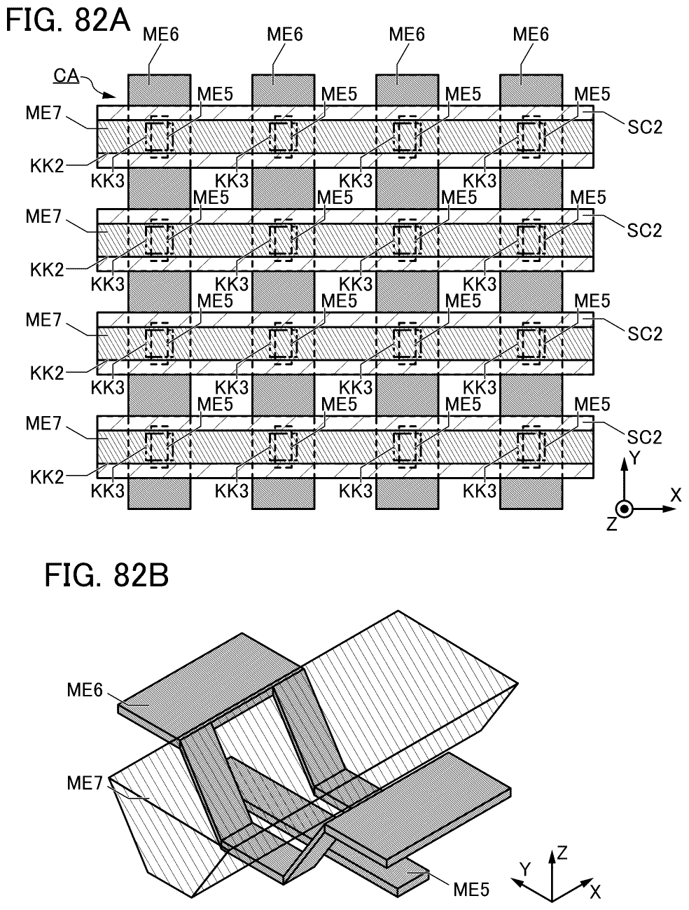

Specifically, the memory cell MC in FIG. 81A to FIG. 81C has a structure in which the opening KK2 is provided along the row direction (X direction) and the conductor ME7 is formed to fill the opening KK2 in the cell array CA, as illustrated in FIG. 82A. Thus, in FIG. 81B, the conductor ME6 provided along the column direction in the cell array CA has an opening KK3 so as not to be electrically connected to the conductor ME5.

FIG. 82B is a schematic perspective view selectively illustrating the conductor ME5, the conductor ME6, and the conductor ME7 around the transistor MW in the memory cell MC. In FIG. 82B, the conductor ME5 is formed and then the insulator IS6 including the opening KK2 (not illustrated) is formed. After that, the conductive film to be the conductor ME6 is formed on the side surface and the bottom surface of the opening KK2 and over the insulator IS6.

Next, by a lithography method, the opening KK3 is provided in the conductive film to expose the conductor ME5, and the conductor ME6 is formed to extend in the Y direction. In that case, the conductor ME5 and the conductor ME6 are preferably formed using different materials so that they can have etching selectivity. Specifically, indium tin oxide is preferably used for the conductor ME5, and a material other than indium tin oxide, such as tantalum, titanium, or tungsten, is preferably used for the conductor ME6, for example.

Next, the semiconductor SC2 (not illustrated) is formed in a region including the opening KK2. At this time, the semiconductor SC2 is formed along the X direction. After that, the insulator GI2 (not illustrated) is formed over the semiconductor SC2 and the conductor ME6.

Next, the conductive film to be the conductor ME7 is formed over the insulator GI2, and then the conductor ME7 can be embedded in the opening KK2 by planarization treatment such as a CMP method. In other words, by such a formation method, the conductive film to be the conductor ME7 can be selected in a self-aligned manner without using a mask to form the conductor ME7. Thus, the wiring WWL including the conductor ME7 can be formed without an alignment margin, so that positioning defects due to misalignment of a mask or the like are less likely to occur. Consequently, the yield of the memory cell MC can be increased.

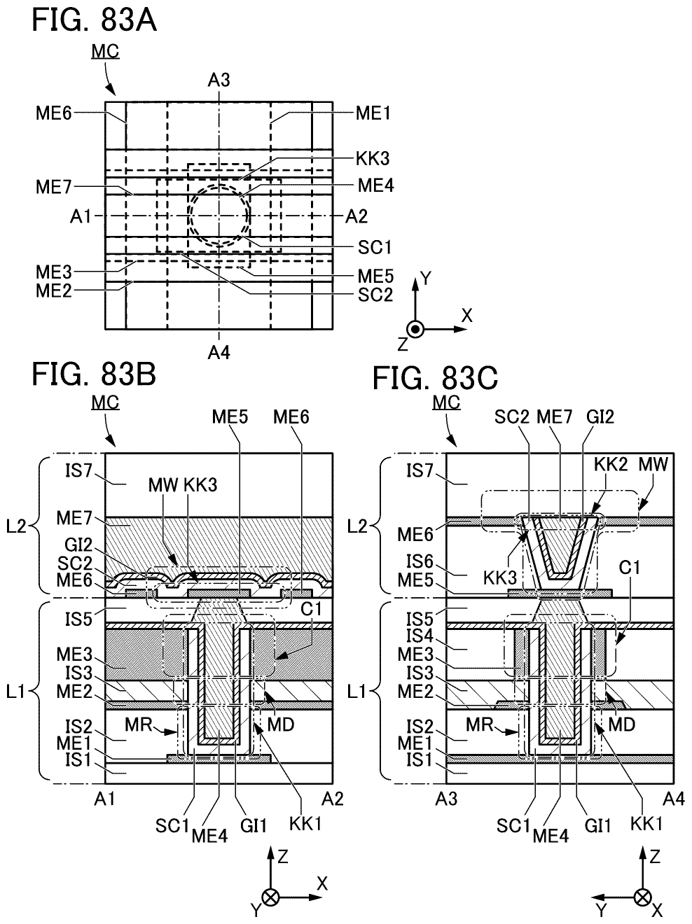

The memory cell MC in FIG. 81A to FIG. 81C may be modified as appropriate. For example, in the case where the conductor ME7 is formed by planarization treatment in the memory cell MC in FIG. 81A to FIG. 81C, polishing may be performed until the level of the conductor ME7 reaches not the level of the insulator GI2 but the level of the conductor ME6. In other words, the conductor ME7 may be polished by planarization treatment until the conductor ME6 is exposed. FIG. 83A to FIG. 83C illustrate a modification example of the memory cell MC in FIG. 81A to FIG. 81C and has a structure in which the conductor ME7 is polished by planarization treatment until the conductor ME6 is exposed.

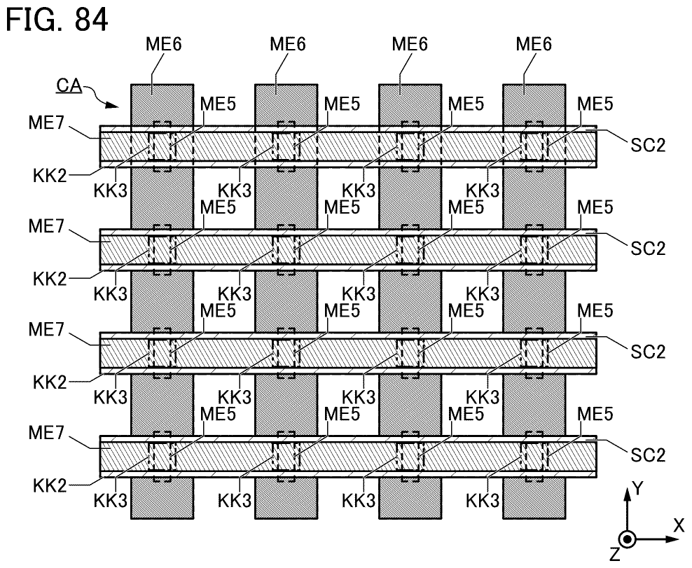

The opening KK2 in the memory cell MC in FIG. 83A to FIG. 83C is provided along the row direction in the cell array CA, as illustrated in FIG. 84. The semiconductors SC2 and the conductors ME7 are also provided along the row direction to fill the opening KK2. The cell array CA illustrated in FIG. 84 is different from the cell array CA illustrated in FIG. 82A in that the semiconductor SC2 is formed only in the inner part of the opening KK2.

### Modification Example 18

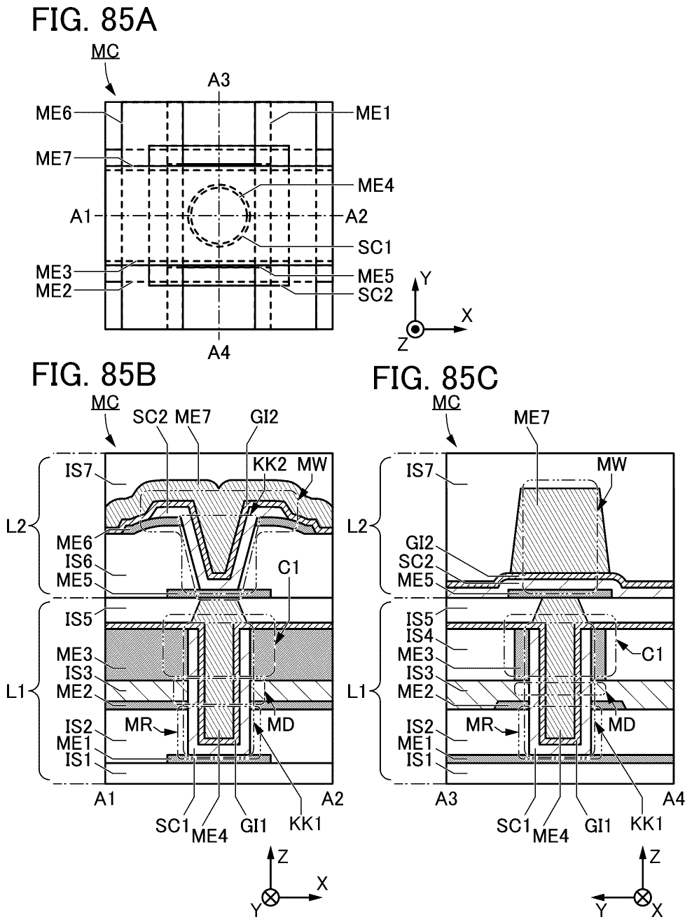

The memory cell MC illustrated in FIG. 85A to FIG. 85C is a modification example of the memory cell MC in FIG. 2A to FIG. 2C and is a structure example in which the opening KK2 is formed along the Y direction.

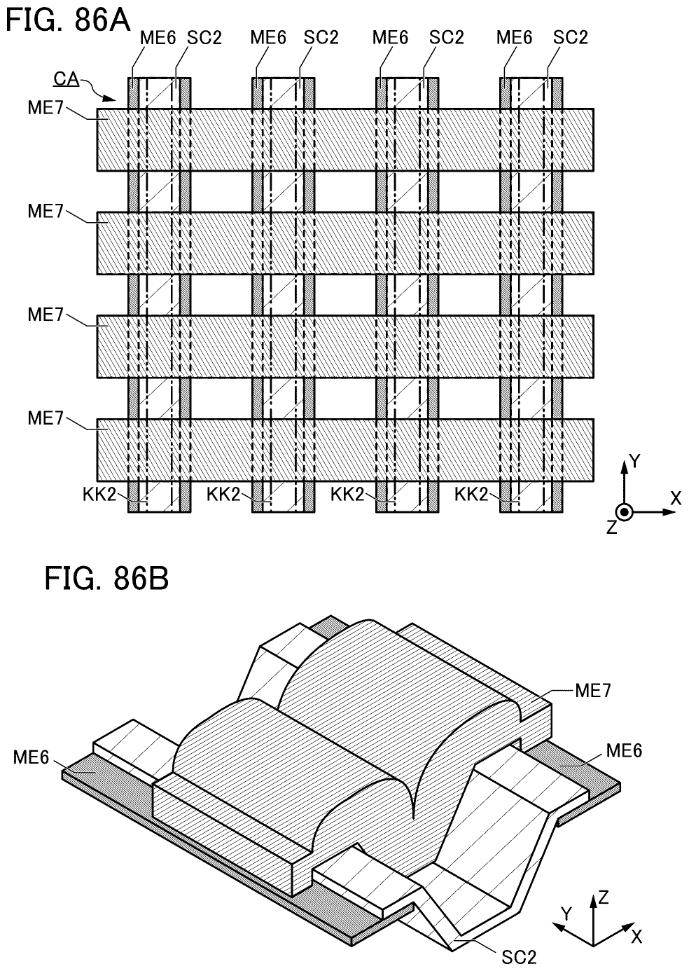

Specifically, the memory cell MC in FIG. 85A to FIG. 85C has a structure in which the opening KK2 is provided along the column direction (Y direction) and the semiconductor SC2 is formed along the opening KK2 in the cell array CA, as illustrated in FIG. 86A. Thus, in the cell array CA, the conductors ME6 along the column direction are provided as a set of two to form the wiring WBL extending in the column direction (Y direction), for example.

FIG. 86B is a schematic perspective view selectively illustrating the conductor ME6, the semiconductor SC2, and the conductor ME7 around the transistor MW in the memory cell MC. In FIG. 86B, the insulating film to be the insulator IS6 (not illustrated) and the conductive film to be the conductor ME6 are formed in this order. The conductive film extends in the column direction (Y direction). Next, the opening KK2 reaching the conductor ME5 (not illustrated) is formed in a region of the conductive film. Thus, the insulating film is formed into the insulator IS6, and the conductive film is formed into the conductor ME6. Next, the semiconductor SC2 is formed over the conductor ME6 and the conductor ME5. The semiconductor SC2 extends in the column direction (Y direction). The film of the insulator GI2 (not illustrated) is formed over the conductor ME6 and the semiconductor SC2. Next, the conductor ME7 is formed along the X direction. After that, the insulator IS7 (not illustrated) is formed to cover the conductor ME6, the semiconductor SC2, the insulator GI2, and the conductor ME7.

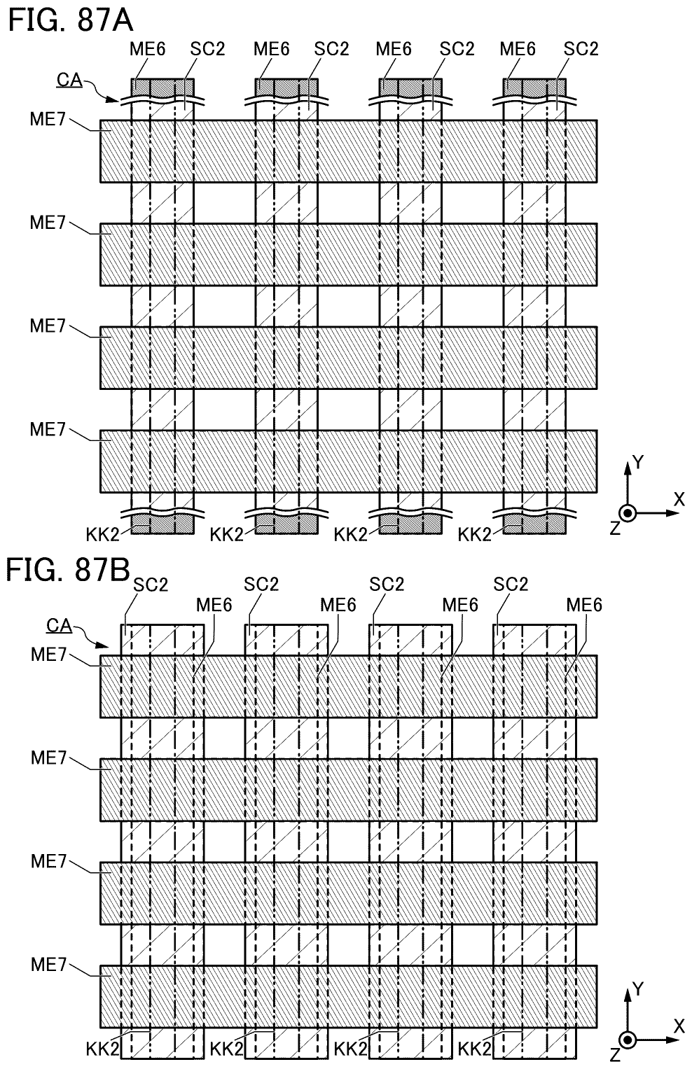

The memory cell MC in FIG. 85A to FIG. 85C may have a structure in which the conductive film to be the conductor ME6 and a semiconductor film to be the semiconductor SC2 are collectively processed over the insulator IS6 by a lithography method. In this case, end portions of the conductor ME6 and the semiconductor film SC2 may overlap with each other in the plan view. For example, the conductor ME6 and the semiconductor SC6 overlap with each other as in the cell array CA illustrated in FIG. 87A by collectively processing the conductive film to be the conductor ME6 and the semiconductor film to be the semiconductor SC2 over the insulator IS6 by a lithography method.

Alternatively, the memory cell MC in FIG. 85A to FIG. 85C may have a structure in which the semiconductor SC2 covers the conductor ME6. For example, as in the cell array CA illustrated in FIG. 87B, the shape of the semiconductor SC2 may be wider than the width of the conductor ME6 extending in the Y direction so as to cover the conductor ME6.

Note that the insulators, the conductors, and the semiconductors disclosed in this specification and the like can be formed by a PVD (Physical Vapor Deposition) method or a CVD method. Examples of a PVD method include a sputtering method, a resistance heating evaporation method, an electron beam evaporation method, an MBE (Molecular Beam Epitaxy) method, and a PLD method. Examples of the CVD method include a plasma CVD method and a thermal CVD method. In particular, examples of a thermal CVD method include an MOCVD method and an ALD method.

A thermal CVD method is a deposition method not using plasma, and thus has an advantage that no defect due to plasma damage is generated.

Deposition by a thermal CVD method may be performed in such a manner that a source gas and an oxidizer are supplied into a chamber at a time, the pressure in the chamber is set to an atmospheric pressure or a reduced pressure, and they are made to react with each other in the vicinity of the substrate or over the substrate to be deposited over the substrate.

Deposition by an ALD method may be performed in such a manner that pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves); in order to avoid mixing of the plurality of kinds of source gases, an inert gas (e.g., argon or nitrogen) or the like is introduced at the same time as or after introduction of a first source gas and then a second source gas is introduced. Note that in the case where the first source gas and the inert gas are introduced at a time, the inert gas serves as a carrier gas, and the inert gas may also be introduced at the same time as the introduction of the second source gas. Alternatively, the second source gas may be introduced after the first source gas is exhausted by vacuum evacuation instead of the introduction of the inert gas. The first source gas is adsorbed on the surface of the substrate to deposit a first thin layer; then the second source gas is introduced to react with the first thin layer; as a result, a second thin layer is stacked over the first thin layer, so that a thin film is formed. The sequence of the gas introduction is controlled and repeated a plurality of times until a desired thickness is obtained, so that a thin film with excellent step coverage can be formed. The thickness of the thin film can be adjusted by the number of repetition times of the sequence of the gas introduction; therefore, an ALD method makes it possible to accurately adjust the thickness and is thus suitable for manufacturing a minute FET.

A variety of films such as the metal film, the semiconductor film, and the inorganic insulating film disclosed in the above-described embodiments can be formed by a thermal CVD method such as an MOCVD method and an ALD method; for example, in the case of depositing an In—Ga—Zn—O film, trimethylindium (In(CH₃)₃), trimethylgallium (Ga(CH₃)₃), and dimethylzinc (Zn(CH₃)₂) are used. Without limitation to the above combination, triethylindium (In(C₂H₅)₃) can also be used instead of trimethylindium, triethylgallium (Ga(C₂H₅)₃) can also be used instead of trimethylgallium, and diethylzinc (Zn(C₂H₅)₂) can also be used instead of dimethylzinc.

For example, in the case where a hafnium oxide film is formed with a deposition apparatus using an ALD method, two kinds of gases, ozone (O₃) as an oxidizer and a source gas which is obtained by vaporizing liquid containing a solvent and a hafnium precursor compound (e.g., hafnium alkoxide and hafnium amide such as tetrakis(dimethylamide) hafnium (TDMAH, Hf[N(CH₃)₂]₄)), are used. Examples of another material include tetrakis(ethylmethylamide) hafnium.

For example, in the case where an aluminum oxide film is formed with a deposition apparatus using an ALD method, two kinds of gases, H₂O as an oxidizer and a source gas which is obtained by vaporizing liquid containing a solvent and an aluminum precursor compound (e.g., trimethylaluminum (TMA, Al(CH₃)₃)) are used. Examples of another material include tris(dimethylamide)aluminum, triisobutylaluminum, and aluminum tris(2,2,6,6-tetramethyl-3,5-heptanedionate).

For example, in the case where a silicon oxide film is formed by a deposition apparatus using an ALD method, hexachlorodisilane is adsorbed on a surface on which a film is to be formed, and radicals of an oxidizing gas (e.g., O₂ or dinitrogen monoxide) are supplied to react with the adsorbate.

For example, in the case where a tungsten film is deposited by a deposition apparatus using an ALD method, a WF₆ gas and a B₂H₆ gas are sequentially and repeatedly introduced to form an initial tungsten film, and then a WF₆ gas and an H₂ gas are sequentially and repeatedly introduced to form a tungsten film. Note that an SiH₄ gas may be used instead of a B₂H₆ gas.

In the case where an In—Ga—Zn—O film is deposited as an oxide semiconductor film with a deposition apparatus using an ALD method, a precursor (generally referred to as a metal precursor or the like in some cases) and an oxidizer (generally referred to as a reactant, a non-metal precursor, or the like in some cases) are sequentially and repetitively introduced. Specifically, for example, an In(CH₃)₃ gas as a precursor and an O₃ gas as an oxidizer are introduced to form an In—O layer; a Ga(CH₃)₃ gas as a precursor and an O₃ gas as an oxidizer are introduced to form a GaO layer; and then, a Zn(CH₃)₂ gas as a precursor and an O₃ gas as an oxidizer are introduced to form a ZnO layer. Note that the order of these layers is not limited to this example. A mixed oxide layer such as an In—Ga—O layer, an In—Zn—O layer, or a Ga—Zn—O layer may be formed with the use of these gases. Note that although an H₂O gas which is obtained by bubbling water with an inert gas (e.g., argon) may be used instead of an O₃ gas, it is preferable to use an O₃ gas which does not contain H. Furthermore, instead of an In(CH₃)₃ gas, an In(C₂H₅) 3 gas may be used. Furthermore, instead of a Ga(CH₃)₃ gas, a Ga(C₂H₅) 3 gas may be used. Furthermore, instead of a Zn(CH₃)₂ gas, a Zn(C₂H₅) 2 gas may be used.

The structure described in this embodiment can be combined as appropriate with any of the other structures described in this embodiment. For example, the configurations, structures, methods, and the like described in this embodiment can be used in an appropriate combination with any of the other configurations, structures, methods, and the like described in this embodiment.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 3

In this embodiment, modification examples of the memory cell MC which is the semiconductor device described in the above embodiment are described.

### Modification Example 1 of Memory Cell

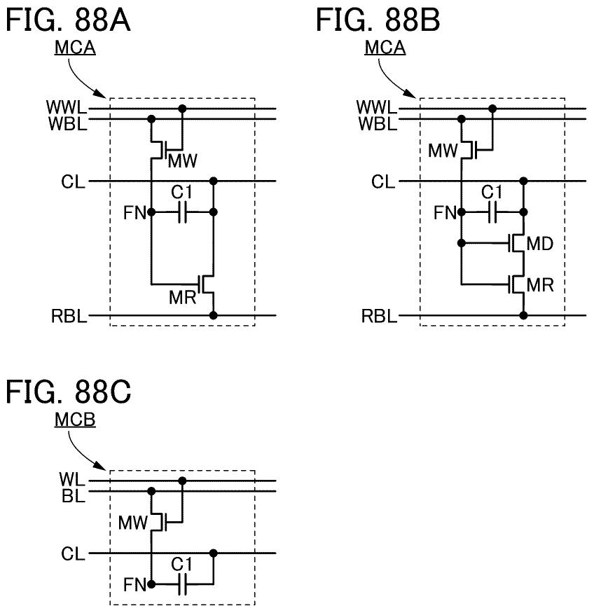

FIG. 88A illustrates a modification example of the memory cell MC in FIG. 1A, which is the semiconductor device of one embodiment of the present invention. A memory cell MCA illustrated in FIG. 88A is an example of a memory cell called a gain cell, like the memory cell MC in FIG. 1A, and includes the transistor MW, the transistor MR, and the capacitor C1. The memory cell MCA in FIG. 88A is different from the memory cell MC in FIG. 1A in not being electrically connected to the wiring SL.

In particular, in this specification and the like, the structure of the memory cell MCA in which OS transistors are used as the transistor MW and the transistor MR is referred to as a NOSRAM (registered trademark) in some cases, like the structure of the memory cell MC in FIG. 1A.

Next, plan-view and cross-sectional structure examples of the memory cell MCA in FIG. 88A are described.

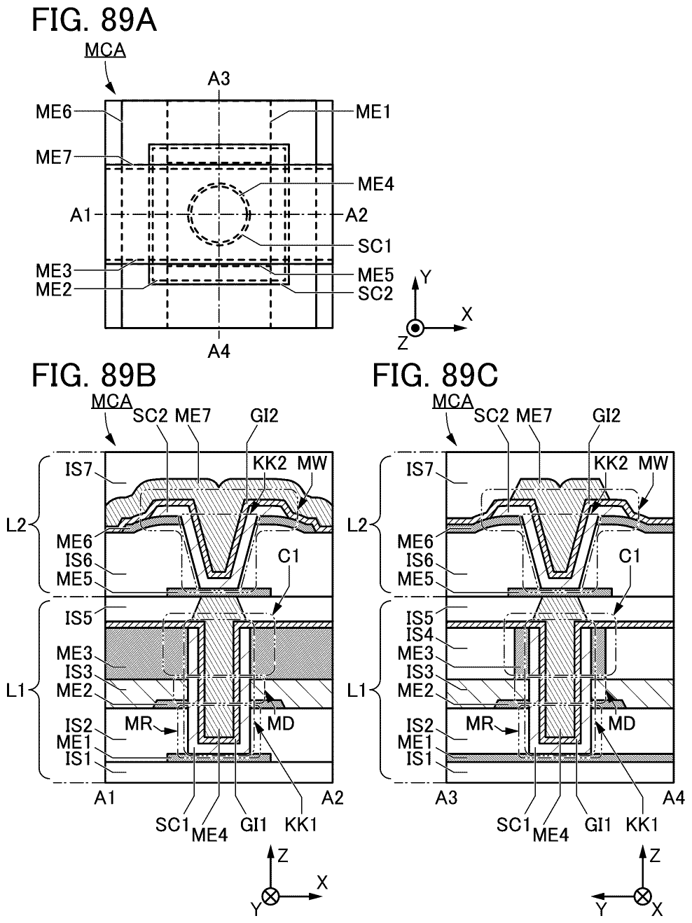

FIG. 89A shows a plan-view structure example of the memory cell MCA in FIG. 88A, and each of FIG. 89B and FIG. 89C shows a cross-sectional structure example of the memory cell MCA in FIG. 88A. FIG. 89B is a cross-sectional view of a portion indicated by the dashed-dotted line A1-A2 in the schematic plan view in FIG. 89A, and FIG. 89C is a cross-sectional view of a portion indicated by the dashed-dotted line A3-A4 in the schematic plan view in FIG. 89A. For clarity of the drawing, some components are omitted in the schematic plan view in FIG. 89A.

Since the memory cell MCA illustrated in FIG. 89A to FIG. 89C is a modification example of the memory cell MC illustrated in FIG. 2A to FIG. 2C, the description on the memory cell MC in FIG. 2A to FIG. 2C can be referred to for the structure of the memory cell MCA in FIG. 89A to FIG. 89C common to the memory cell MC in FIG. 2A to FIG. 2C. A structure in the memory cell MCA in FIG. 89A to FIG. 89C different from that of the memory cell MC in FIG. 2A to FIG. 2C will be described below.

The memory cell MCA illustrated in FIG. 89A to FIG. 89C is different from the memory cell MC illustrated in FIG. 2A to FIG. 2C in that the conductor ME2 does not extend in the Y direction and is formed only on the outer side surface of the opening KK1. Thus, unlike the memory cell MC illustrated in FIG. 2A to FIG. 2C, the memory cell MCA in FIG. 89A to FIG. 89C is not electrically connected to the wiring SL.

The conductor ME1 also functions as the wiring RBL, for example, and extends in the Y direction in FIG. 89A to FIG. 89C. The conductor ME3 also functions as the wiring CL, for example, and extends in the X direction in FIG. 89A to FIG. 89C.

The conductor ME6 also functions as the wiring WBL, for example, and extends in the Y direction in FIG. 89A to FIG. 89C. The conductor ME7 also functions as the wiring WWL, for example, and extends in the X direction in FIG. 89A to FIG. 89C.

In the structure of the memory cell MCA in FIG. 89A to FIG. 89C, the transistor MD may be formed above the transistor MR and below the capacitor C1, as in the structure of the memory cell MC in FIG. 2A to FIG. 2C. The transistor MD described in Embodiment 1 can be referred to for the transistor MD.

FIG. 88B shows an example of the case where the transistor MD is added to the circuit structure of the memory cell MC in FIG. 88A. In FIG. 88B, a first terminal of the transistor MD is electrically connected to the second terminal of the capacitor C1 and the wiring CL, a second terminal of the transistor MD is electrically connected to the first terminal of the transistor MR, and a gate of the transistor MD is electrically connected to the first terminal of the capacitor C1, the second terminal of the transistor MW, and the gate of the transistor MR.

The transistor MD is sometimes formed above the transistor MR and below the capacitor C1, as illustrated in FIG. 89A to FIG. 89C. As described in Embodiment 2, in the case where the semiconductor SC1 is the metal oxide functioning as an oxide semiconductor, supply of an impurity against the semiconductor SC1 from the insulator IS3 reduces the resistance of the interface of the semiconductor SC1 in contact with the insulator IS3 and the vicinity of the interface. For this reason, the transistor MD can be regarded as not a switching element but a wiring (or a normally-on transistor) when supplied with the impurity. That is, the circuit structure illustrated in FIG. 88B can be regarded as the circuit structure in FIG. 88A.

Next, a structure example of a memory device including the memory cell MCA in FIG. 88A or FIG. 88B is described.

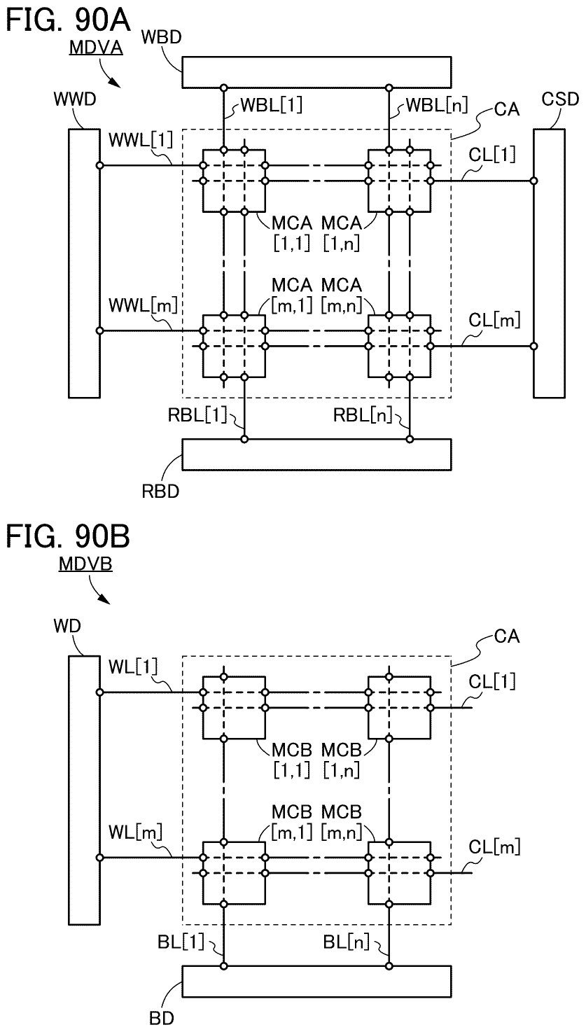

A memory device MDVA illustrated in FIG. 90A is a memory device of one embodiment of the present invention and includes the cell array CA, the circuit WBD, the circuit WWD, the circuit CSD, and the circuit RBD. The memory device MDVA is a modification example of the memory device MDV in FIG. 3A and is different from the memory device MDV in FIG. 3A in that the cell array CA includes not the memory cell MC[1,1] to the memory cell MC[m,n] but the memory cell MCA[1,1] to the memory cell MCA[m,n] and that the wiring SL[1] to the wiring SL[m] are not provided.

In FIG. 90A, the cell array CA includes a plurality of memory cells MCA. Specifically, the plurality of memory cells MCA are arranged in a matrix of m rows and n columns in the cell array CA. For example, a memory cell MCA[1,1], a memory cell MCA[m,1], a memory cell MCA[1,n], and a memory cell MCA[m,n] in the cell array CA are selectively illustrated in FIG. 90A.

For the structure of the memory device MDVA in FIG. 90A common to the memory device MDV in FIG. 3A, the description of the memory device MDV in FIG. 3A can be referred to. Therefore, an operation of writing to the memory cell MCA in the memory device MDVA in FIG. 90A can be performed in a manner similar to that of the memory device MDV in FIG. 3A. An operation of reading from the memory cell MCA can also be performed in a manner similar to that of the memory device MDV in FIG. 3A when the transistor MD can be regarded as a wiring (in the case where the transistor MD is normally on).

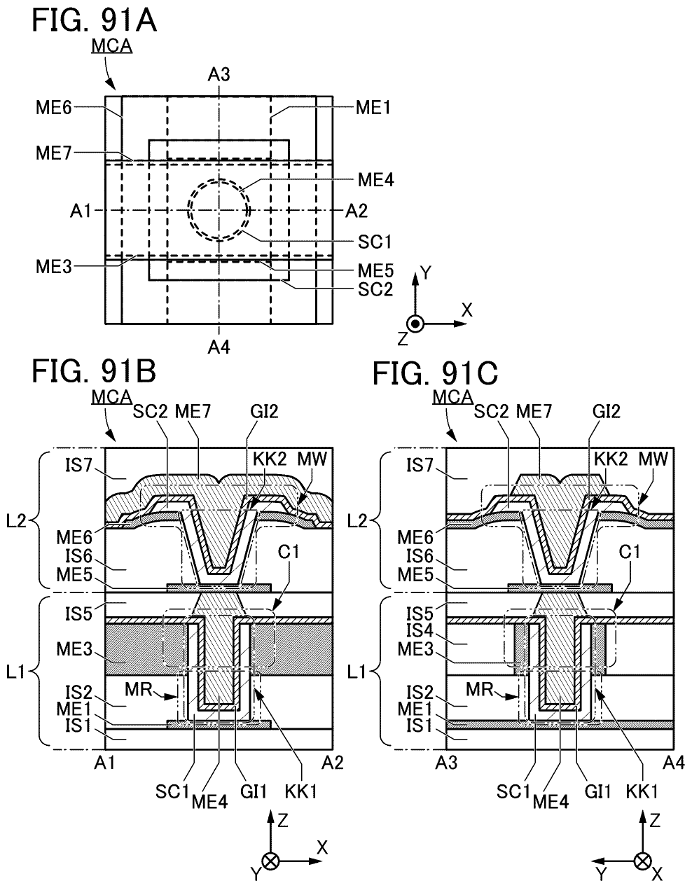

The structure of the memory cell MCA illustrated in FIG. 89A to FIG. 89C can be modified into that of the memory cell MCA illustrated in FIG. 91A to FIG. 91C.

The memory cell MCA illustrated in FIG. 91A to FIG. 91C has a structure in which the conductor ME2 and the insulator IS3 are not provided in the memory cell MCA in FIG. 89A to FIG. 89C. Thus, the transistor MD is not formed in the memory cell MCA illustrated in FIG. 91A to FIG. 91C; accordingly, the memory cell MCA in FIG. 91A to FIG. 91C can perform a reading operation stably.

### Modification Example 2 of Memory Cell

FIG. 88C illustrates a modification example of the memory cell MC in FIG. 1A, which is the semiconductor device of one embodiment of the present invention. A memory cell MCB illustrated in FIG. 88C is an example of a memory cell called a DRAM (Dynamic Random Access Memory) and includes the transistor MW and the capacitor C1. The memory cell MCB in FIG. 88C is different from the memory cell MC in FIG. 1A in that the transistor MR is not provided and that the memory cell MCB is not electrically connected to the wiring SL.

In particular, in this specification and the like, the structure of the memory cell MCB in which an OS transistor is used as the transistor MW is referred to as a DOSRAM (registered trademark) (Dynamic Oxide Semiconductor Random Access Memory) in some cases.

The memory cell MCB illustrated in FIG. 88C includes the transistor MW and the capacitor C1. For the transistor MW and the capacitor C1, the transistor MW and the capacitor C1 included in the memory cell MC in FIG. 1A can be referred to.

The first terminal of the transistor MW is electrically connected to the wiring BL, the second terminal of the transistor MW is electrically connected to the first terminal of the capacitor C1, and the gate of the transistor MW is electrically connected to the wiring WL. The second terminal of the capacitor C1 is electrically connected to a wiring CL.

The wiring BL functions as, for example, a data line (sometimes referred to as a bit line) that transmits write data to be retained in the memory cell MC or data read from the memory cell MC.

The wiring WL functions as a wiring for selecting the memory cell MC to which data is to be written or from which data is to be read (sometimes referred to as a word line).

The wiring CL functions as a wiring for supplying a fixed potential to the second terminal of the capacitor C1, for example. The fixed potential can be, for example, a high-level potential, a low-level potential, a ground potential, or a negative potential. The wiring CL may be a wiring supplying a variable potential (referred to as a pulse potential or a pulse voltage in some cases) instead of a wiring supplying a fixed potential.

Next, plan-view and cross-sectional structure examples of the memory cell MCB in FIG. 88C are described.

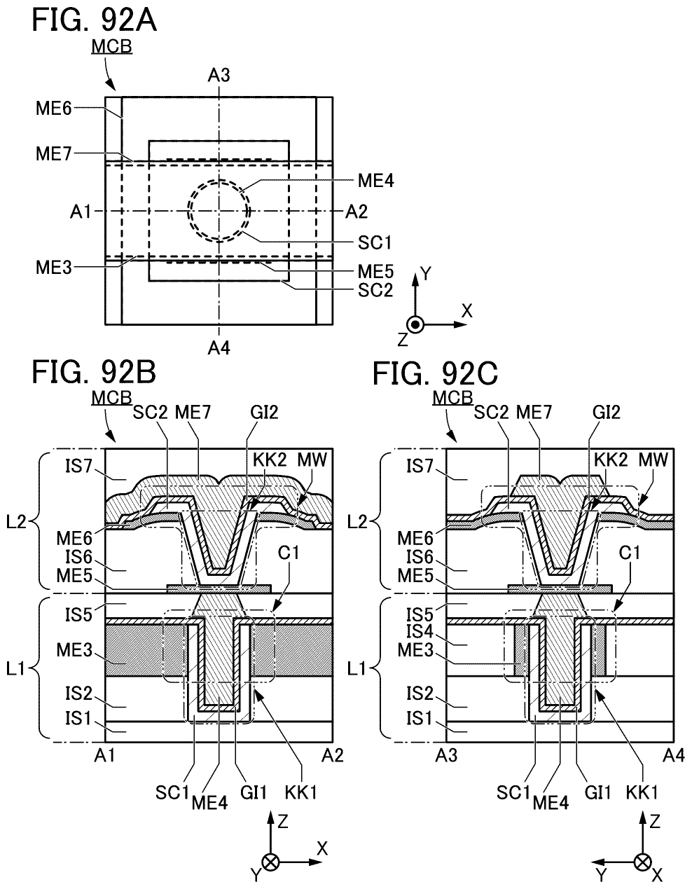

FIG. 92A shows a plan-view structure example of the memory cell MCB in FIG. 88C, and each of FIG. 92B and FIG. 92C shows a cross-sectional structure example of the memory cell MCB in FIG. 88C. FIG. 92B is a cross-sectional view of a portion indicated by the dashed-dotted line A1-A2 in the schematic plan view in FIG. 92A, and FIG. 92C is a cross-sectional view of a portion indicated by the dashed-dotted line A3-A4 in the schematic plan view in FIG. 92A. For clarity of the drawing, some components are omitted in the schematic plan view in FIG. 92A.

Since the memory cell MCB illustrated in FIG. 92A to FIG. 92C is a modification example of the memory cell MC illustrated in FIG. 2A to FIG. 2C, the description on the memory cell MC in FIG. 2A to FIG. 2C can be referred to for the structure of the memory cell MCB in FIG. 92A to FIG. 92C common to the memory cell MC in FIG. 2A to FIG. 2C. A structure in the memory cell MCB in FIG. 92A to FIG. 92C different from that of the memory cell MC in FIG. 2A to FIG. 2C will be described below.

The memory cell MCB illustrated in FIG. 92A to FIG. 92C is different from the memory cell MC illustrated in FIG. 2A to FIG. 2C in that the conductor ME1, the conductor ME2, and the insulator IS3 are not provided.

In FIG. 92A to FIG. 92C, conductor ME3 also functions as the wiring CL, for example, and extends in the X direction in FIG. 92A to FIG. 92C. The conductor ME7 also functions as the wiring WL, for example, and extends in the X direction in FIG. 92A to FIG. 92C. The conductor ME6 also functions as the wiring BL, for example, and extends in the Y direction in FIG. 92A to FIG. 92C.

Next, a structure example of a memory device including the memory cell MCB in FIG. 88C is described.

A memory device MDVB illustrated in FIG. 90B is a memory device of one embodiment of the present invention and includes the cell array CA, the circuit WD, and the circuit BD.

The cell array CA includes a plurality of memory cells MCB. Specifically, the plurality of memory cells MCB are arranged in a matrix of m rows and n columns (m is an integer greater than or equal to 1 and n is an integer greater than or equal to 1) in the cell array CA. For example, a memory cell MCB[1,1], a memory cell MCB[m,1], a memory cell MCB[1,n], and a memory cell MCB[m,n] in the cell array CA are selectively illustrated in FIG. 90B.

In FIG. 90B, the memory cell MCB located in the x-th row and the y-th column is denoted by MCB[x,y].

The memory cell MCB illustrated in FIG. 88C can be used as each of the memory cell MCB[1,1] to the memory cell MCB[m,n] illustrated in FIG. 90B.

In the cell array CA, for example, each of a wiring WL[1] to a wiring WL[m], which corresponds to the wiring WL in FIG. 88C, extends in the row direction. In the cell array CA, for example, each of a wiring CL[1] to a wiring CL[m], which corresponds to the wiring CL in FIG. 1C, extends in the row direction.

In FIG. 90B, the wiring WL extending in the x-th row is denoted by WL[x]. Similarly, the wiring CL extending in the x-th row is denoted by CL[x].

In the cell array CA, for example, each of the wiring BL[1] to the wiring BL[n], which corresponds to the wiring BL in FIG. 88C, extends in the column direction.

In FIG. 90B, the wiring BL extending in the y-th column is denoted by BL[y].

In FIG. 90B, the circuit WD is electrically connected to the wiring WL[1] to the wiring WL[m]. The circuit BD is, for example, electrically connected to a wiring BL[1] to a wiring BL[n].

The circuit WD has a function of selecting the memory cells MC in the row where writing or reading is performed in the cell array CA, for example. The circuit WD has a function of, specifically, transmitting a selection signal to any one of the wiring WL[1] to the wiring WL[m] and transmitting a non-selection signal to the other wirings, for example. In the case where the write transistor included in the memory cell MCB is an n-channel transistor, the selection signal is preferably a high-level potential and the non-selected signal is preferably a low-level potential.

The circuit BD has a function of transmitting data for writing to the memory cell MCB selected by the circuit WD and a function of reading data for reading from the memory cell MCB in the cell array CA, for example. Specifically, the circuit BD transmits data for writing to each of the wiring BL[1] to the wiring BL[n], for example. Thus, data for writing transmitted to each column is written to the memory cells MC in the row selected by the circuit WD. During a reading operation, the circuit BD obtains data, which is read from the memory cell MCB, from each of the wiring BL[1] to the wiring BL[n], for example. After that, the circuit BD amplifies the read data with a sense amplifier or the like (converts the data into digital data) or converts the data into analog data with a current-voltage converter circuit or the like, thereby outputting the data to the outside of the circuit BD.

Since the circuit BD converts the read data into digital data or analog data, the circuit BD preferably includes a current-voltage converter circuit, an analog-digital converter circuit, a digital-analog converter circuit, or a sense amplifier.

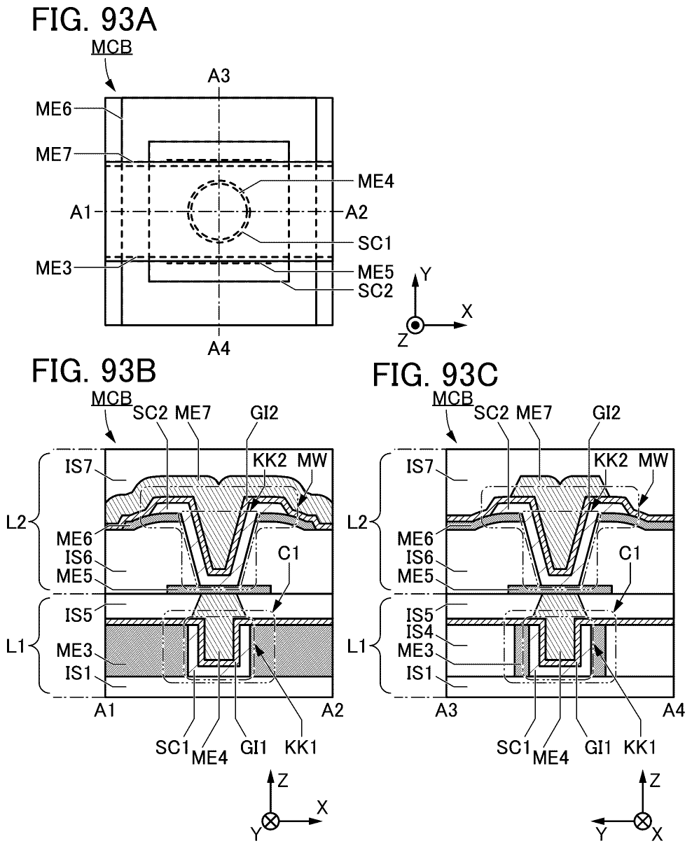

The structure of the memory cell MCB illustrated in FIG. 92A to FIG. 92C can be modified into that of the memory cell MCB illustrated in FIG. 93A to FIG. 93C.

The memory cell MCB illustrated in FIG. 93A to FIG. 93C has a structure in which the insulator IS2 is not provided in the memory cell MCB in FIG. 92A to FIG. 92C. Thus, the step of forming the insulator IS2 in the memory cell MCB illustrated in FIG. 93A to FIG. 93C is unnecessary; accordingly, the memory cell MCB in FIG. 93A to FIG. 93C can be manufactured more simply than the memory cell MCB in FIG. 92A to FIG. 92C.

The structure described in this embodiment can be combined as appropriate with any of the other structures described in this embodiment. For example, the configurations, structures, methods, and the like described in this embodiment can be used in an appropriate combination with any of the other configurations, structures, methods, and the like described in this embodiment.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 4

In this embodiment, a structure example of a memory device including the semiconductor device described in the above embodiment is described.

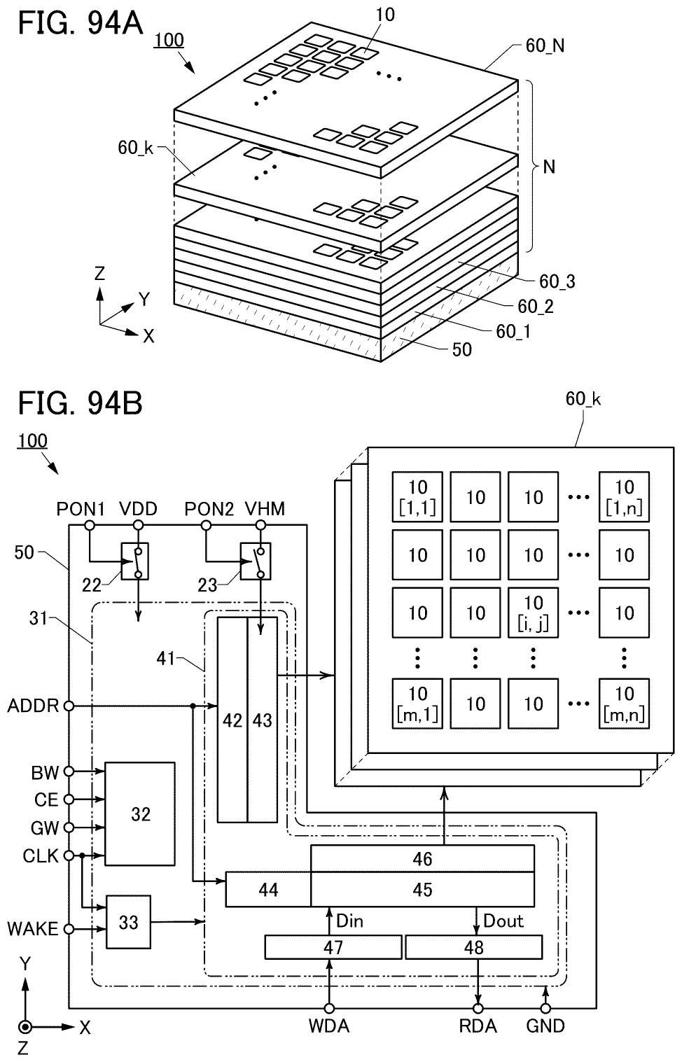

FIG. 94A is a schematic perspective view illustrating a structure example of a memory device 100. FIG. 94B is a block diagram illustrating the structure example of the memory device 100. The memory device 100 includes a driver circuit layer 50 and N (N is a integer of 1 or more) memory layers 60. One memory layer 60 includes a plurality of memory cells 10 arranged in a matrix of m rows and n columns. Note that FIG. 94B illustrates an example where a memory cell 10[1,1], a memory cell 10[m,1] (here, m is an integer of 1 or more), a memory cell 10[1,n] (here, n is an integer of 1 or more), a memory cell 10[m,n], and a memory cell 10[i,j] (here, i is an integer greater than or equal to 1 and less than or equal to m, and j is an integer greater than or equal to 1 and less than or equal to n) are provided in a memory layer 60_k.

The memory layer 60 can be the cell array CA described in Embodiment 1, for example. The memory cell 10 can be the memory cell MC described in Embodiment 1 to Embodiment 3.

The N memory layers 60 are provided over the driver circuit layer 50. Provision of the N memory layers 60 over the driver circuit layer 50 can reduce the area occupied by the memory device 100. Furthermore, memory capacity per unit area can be increased.

In this embodiment and the like, the first memory layer 60 is denoted by a memory layer 60_1, the second memory layer 60 is denoted by a memory layer 60_2, and the third memory layer 60 is denoted by a memory layer 60_3. Furthermore, the k-th memory layer 60 (k is an integer greater than or equal to 1 and less than or equal to N) is denoted by a memory layer 60_k, and the N-th memory layer 60 is denoted by a memory layer 60_N. Note that in this embodiment and the like, the simple term “memory layer 60” is sometimes used in the case of describing a matter related to all the N memory layers 60 or showing a matter common to the N memory layers 60.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs a logical operation on the signal CE, the signal GW, and the signal BW to determine an operation mode (e.g., a writing operation or a reading operation) of the memory device 100. The control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed.

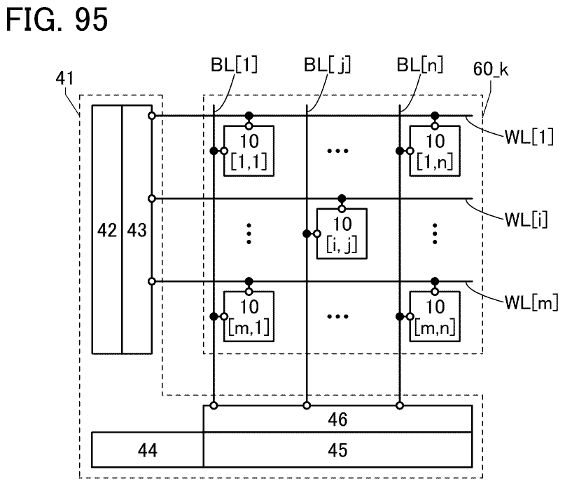

The row driver 43 has a function of selecting a write word line or a read word line (e.g., any one of the wiring WL[1] to the wiring WL[m] illustrated in FIG. 95 described later) specified by the row decoder 42. Specifically, for example, the row driver 43 can be a circuit including the circuit WWD and the circuit CSD described in Embodiment 1. For example, the row driver 43 can be the circuit WD described in Embodiment 3.

The column driver 45 has a function of writing data to the memory cells 10, a function of reading data from the memory cells 10, and a function of retaining the read data. The column driver 45 has a function of selecting a write bit line or a read bit line (e.g., any one of a wiring BL[1] to a wiring BL[n] illustrated in FIG. 95 described later) specified by the column decoder 44. Specifically, for example, the column driver 45 can be a circuit including the circuit WBD and the circuit RBD described in Embodiment 1. For example, the column driver 45 can be the circuit BD described in Embodiment 3.

The input circuit 47 has a function of retaining the signal WDA. Data retained by the input circuit 47 (the first data in the above embodiment) is output to the column driver 45. Data output from the input circuit 47 is data (Din) to be written to the memory cells 10. Data (Dout) read from the memory cells 10 by the column driver 45 is output to the output circuit 48. Note that in the above embodiment, the read data (Dout) is treated as arithmetic operation result data. The output circuit 48 has a function of retaining Dout. In addition, the output circuit 48 has a function of outputting Dout to the outside of the memory device 100. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 100, a high power supply voltage is VDD and a low power supply voltage is GND (a ground potential). In addition, VHM is a high power supply voltage used to set a word line at a high level and is higher than VDD. The on state and the off state of the PSW 22 are switched by the signal PON1, and the on state and the off state of the PSW 23 is switched by the signal PON2. The number of power domains to which VDD is supplied is one in the peripheral circuit 31 in FIG. 94B but can be more than one. In that case, a power switch is provided for each power domain.

Next, electrical connection between the peripheral circuit 41 and the memory layer 60 is described.

FIG. 95 is a block diagram illustrating a structure example of the peripheral circuit 41 and the memory layer 60_k. In FIG. 95, the row decoder 42 and the row driver 43 are electrically connected to each of the wiring WL[1] to the wiring WL[m], and the column decoder 44, the column driver 45, and the sense amplifier 46 are electrically connected to each of the wiring BL[1] to the wiring BL[n].

Note that the wiring WL[1] to the wiring WL[m] are wirings corresponding to the wiring WWL[1] to the wiring WWL[m], the wiring CL[1] to the wiring CL[m], and the wiring SL[1] to the wiring SL[m] described in Embodiment 1. That is, the wiring WL[1] to the wiring WL[m] function as word lines.

The wiring BL[1] to the wiring BL[n] are wirings corresponding to the wiring WBL[1] to the wiring WBL[n] and the wiring RBL[1] to the wiring RBL[n] described in Embodiment 1. That is, the wiring BL[1] to the wiring BL[n] function as bit lines.

The memory cell 10[i,j] located at the i-th row and the j-th column is electrically connected to the wiring WL[i] and the wiring BL[j].

As illustrated in FIG. 95, the memory layer 60_k is electrically connected to the peripheral circuit 41, whereby data writing to the memory layer 60_k and data reading from the memory layer 60_k can be performed.

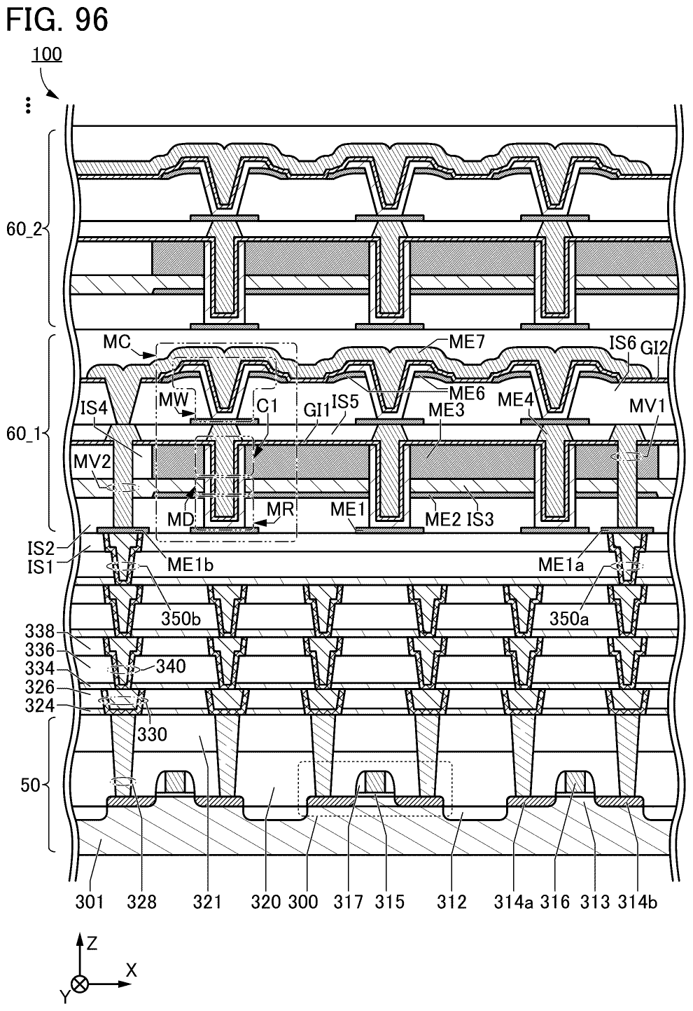

Next, FIG. 96 illustrates a cross-sectional structure example of the memory device 100 of one embodiment of the present invention. The memory device 100 illustrated in FIG. 96 includes a plurality of memory layers 60 (the cell array CA in FIG. 3A described in Embodiment 1) above the driver circuit layer 50. The description of the memory layers 60 in this embodiment is omitted in order to reduce repeated description.

FIG. 96 illustrates a transistor 300 included in the driver circuit layer 50 as an example. The transistor 300 is provided on a substrate 301 and includes an element isolation layer 312, a conductor 316, an insulator 315, an insulator 317, a semiconductor region 313 that is part of the substrate 301, and a low-resistance region 314a and a low-resistance region 314b that function as a source region and a drain region. As the substrate 301, a semiconductor substrate, especially a single crystal substrate containing silicon as a material, can be used, for example. In the case where the substrate 301 is a single crystal substrate using silicon as a material, the transistor 300 can be a Si transistor. An SOI substrate may be used as the substrate 301. In that case, a transistor can be provided by processing the SOI substrate and forming a semiconductor film having a projecting shape.

The transistor 300 can be a fin type when, for example, the top surface of the semiconductor region 313 and the side surface thereof in the channel width direction are covered with the conductor 316 with the insulator 315 functioning as a gate insulator therebetween. The effective channel width can be increased in the fin-type transistor 300, so that the on-state characteristics of the transistor 300 can be improved. In addition, contribution of the electric field of the gate electrode can be increased, so that the off-state characteristics of the transistor 300 can be improved. For example, the transistor 300 may have a planar structure instead of a fin-type structure.

Either a p-channel transistor or an n-channel transistor may be used as each of the plurality of transistors 300 included in the driver circuit layer 50. In such cases, the circuit included in the driver circuit layer 50 is a single-polarity circuit. Alternatively, both a p-channel transistor or an n-channel transistor may be used as each of the plurality of transistors 300 included in the driver circuit layer 50. In this case, the circuit included in the driver circuit layer 50 is a CMOS circuit.

In the transistor 300, a region of the semiconductor region 313 where a channel is formed, a region in the vicinity thereof, and the low-resistance region 314a and the low-resistance region 314b that function as the source region and the drain region preferably contain a semiconductor such as a silicon-based semiconductor, specifically, preferably contain single crystal silicon. Alternatively, each of the regions may be formed using germanium, silicon germanium, gallium arsenide, aluminum gallium arsenide, or gallium nitride, for example. For the transistor 300, a structure may be employed in which silicon whose effective mass is controlled by applying stress to the crystal lattice and thereby changing the lattice spacing. Alternatively, the transistor 300 may be a HEMT (High Electron Mobility Transistor) using gallium arsenide and aluminum gallium arsenide, for example.

For the conductor 316 functioning as a gate electrode, a semiconductor material such as silicon containing an element that imparts n-type conductivity, such as arsenic or phosphorus, or an element that imparts p-type conductivity, such as boron or aluminum, can be used. Alternatively, for the conductor 316, a conductive material such as a metal material, an alloy material, or a metal oxide material can be used, for example.

Since a work function depends on the material of the conductor 316, the threshold voltage of the transistor can be adjusted by selecting the material of the conductor. Specifically, it is preferable to use one or both of titanium nitride and tantalum nitride for the conductor. Moreover, in order to ensure both conductivity and embeddability, it is preferable to use stacked layers of metal materials of one or both of tungsten and aluminum for the conductor, and it is particularly preferable to use tungsten in terms of heat resistance.

Since a work function depends on the material of the conductor, the threshold voltage of the transistor can be adjusted by selecting the material of the conductor. Specifically, it is preferable to use one or both of titanium nitride and tantalum nitride for the conductor. Moreover, in order to ensure both conductivity and embeddability, it is preferable to use stacked layers of metal materials of one or both of tungsten and aluminum for the conductor, and it is particularly preferable to use tungsten in terms of heat resistance.

The element isolation layer 312 is provided to separate a plurality of transistors formed on the substrate 301 from each other. The element isolation layer can be formed by, for example, a LOCOS (Local Oxidation of Silicon) method, an STI (Shallow Trench Isolation) method, or a mesa isolation method.

Note that the transistor 300 illustrated in FIG. 96 is an example and the structure is not limited thereto; an appropriate transistor can be used in accordance with a circuit structure or a driving method.

A wiring layer provided with an interlayer film, a wiring and a plug may be provided between the components. A plurality of wiring layers can be provided in accordance with design. Furthermore, in this specification and the like, a wiring and a plug electrically connected to the wiring may be a single component. That is, part of a conductor may function as a wiring and part of the conductor may function as a plug.

For example, an insulator 320, an insulator 321, an insulator 324, and an insulator 326 are stacked in this order over the transistor 300 as interlayer films. A conductor 328 or the like is embedded in the insulator 320 and the insulator 321. A conductor 330 or the like is embedded in the insulator 324 and the insulator 326. Note that the conductor 328 and the conductor 330 function as a contact plug or a wiring.

For the insulator 320, the insulator 321, and the insulator 326, one or more selected from silicon oxide, silicon oxynitride, silicon nitride oxide, silicon nitride, aluminum oxide, aluminum oxynitride, aluminum nitride oxide, and aluminum nitride can be used, for example.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulator 321 may have a function of a planarization film for planarizing a level difference caused by the transistor 300 or the like covered with the insulator 320. For example, the top surface of the insulator 321 may be planarized by planarization treatment using a chemical mechanical polishing (CMP) method to improve planarity.

For the insulator 324, it is preferable to use an insulating film having a barrier property (referred to as a barrier insulating film) which prevents diffusion of impurities such as water and hydrogen from the substrate 301 or the transistor 300 to a region above the insulator 324 (e.g., the cell array CA where the transistor MW, the transistor MR, and the like are provided). Accordingly, for the insulator 324, it is preferable to use an insulating material that has a function of inhibiting diffusion of impurities such as a hydrogen atom, a hydrogen molecule, and a water molecule (through which the above impurities are less likely to pass). Furthermore, depending on the situation, for the insulator 324, it is preferable to use an insulating material that has a function of inhibiting diffusion of impurities such as a nitrogen atom, a nitrogen molecule, a nitrogen oxide molecule (e.g., N₂O, NO, or NO₂), and a copper atom (through which the above oxygen is less likely to pass). It is preferable that the insulator 324 have a function of inhibiting diffusion of oxygen (e.g., one or both of an oxygen atom and an oxygen molecule).

For the film having a barrier property against hydrogen, silicon nitride deposited by a CVD method can be used, for example.

The amount of released hydrogen can be analyzed by thermal desorption spectroscopy (TDS), for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm² in TDS analysis in a film-surface temperature range of 50° C. to 500° C., for example.

The permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When an insulating material with a low dielectric constant is used for the insulator 326, parasitic capacitance generated between wirings can be reduced.

In addition, the conductor 328 and the conductor 330 that are connected to the memory cell MC and the like provided above the insulator 324 are embedded in the insulator 320, the insulator 321, the insulator 324, and the insulator 326. Note that the conductor 328 and the conductor 330 each have a function of a plug or a wiring. A plurality of conductors each having a function of a plug or a wiring are collectively denoted by the same reference numeral in some cases. Furthermore, in this specification and the like, a wiring and a plug connected to the wiring may be a single component. That is, part of a conductor may function as a wiring and part of the conductor may function as a plug.

As a material for each of plugs and wirings (e.g., the conductor 328 and the conductor 330), a single layer or stacked layers of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

A wiring layer may be provided over the insulator 326 and the conductor 330. FIG. 96 illustrates a structure in which a plurality of wiring layers are provided over the insulator 326 and the conductor 330, for example. In the wiring layers, a plurality of conductors 340 functioning as a contact plug or a wiring are provided.

Specifically, an insulator 334, an insulator 336, and an insulator 338 are stacked in this order as one wiring layer over the insulator 326 and the conductor 330 in FIG. 96. Moreover, the conductor 340 is embedded in the insulator 334, the insulator 336, and the insulator 338. The transistor 300 is electrically connected to any one of the wiring WL[1] to the wiring WL[m] or any one of the wiring BL[1] to the wiring BL[n] through the conductor 328, the conductor 330, and the conductor 340, for example.

Any of the materials that can be used for the insulator 324 can be used as the insulator 334, for example.

For the insulator 336 and the insulator 338, any of the materials that can be used for the insulator 320, the insulator 321, or the insulator 326 can be used, for example.

For the conductor 340, any of the materials usable for the conductor 328 or the conductor 330 can be used, for example.

Next, a structure of the memory layer 60 positioned above the driver circuit layer 50 is described. In FIG. 96, the memory layer 60_1 and the memory layer 60_2 are provided above the wiring layers in which the plurality of conductors 340 functioning as a contact plug or a wiring are provided, for example.

In the memory layer 60_1 illustrated in FIG. 96, the plurality of memory cells MC described with reference to FIG. 2A to FIG. 2C are arranged in a matrix. FIG. 96 illustrates a structure in which, in particular, three memory cells MC are arranged in the X direction, for example.

As described with reference to FIG. 2A to FIG. 2C, the memory cell MC includes the transistor MW, the transistor MR, and the capacitor C1. In some cases, the memory cell MC also includes the transistor MD. The memory cells MC are electrically connected to the conductor ME1, the conductor ME2, the conductor ME3, the conductor ME6, and the conductor ME7 each functioning as a wiring.

The conductor ME2 is provided to extend as the wiring SL in the X direction and to be shared by the plurality of memory cells MC positioned in the same row. Similarly, the conductor ME3 is provided to extend as the wiring CL in the X direction and to be shared by the plurality of memory cells MC positioned in the same row. Similarly, the conductor ME7 is provided to extend as the wiring WWL in the X direction and to be shared by the plurality of memory cells MC positioned in the same row.

The conductor ME1 is provided to extend in the Y direction as the wiring RBL and to be shared by the plurality of memory cells positioned in the same column (not illustrated in FIG. 96). Similarly, the conductor ME6 is provided to extend in the Y direction as the wiring WBL and to be shared by the plurality of memory cells positioned in the same column (not illustrated in FIG. 96).

In FIG. 96, a conductor 350a and a conductor 350b are embedded in the insulator IS1, for example. The conductor 350a and the conductor 350b each function as a contact plug or a wiring and can be formed using any of the materials that can be used for the conductor 328 or the conductor 330, for example. The conductor 350a or the conductor 350b is electrically connected to the conductor 340 in the wiring layer positioned below the memory layer 60_1.

A conductor ME1a is formed over the insulator IS1 and the conductor 350a, for example. A conductor ME1b is formed over the insulator IS1 and the conductor 350b, for example. Note that the conductor ME1a and the conductor ME1b can be formed at the same time in the step of forming the conductor ME1, for example.

In FIG. 96, for example, a conductor MV1 is embedded in regions of the insulator IS2, the conductor ME2, the insulator IS3, the conductor ME3, the insulator GI1, and the insulator IS5, which overlap with the conductor ME1a. For example, a film of the conductor MV1 may be formed in the following manner: the insulator IS2, the conductor ME2, the insulator IS3, the conductor ME3, and the insulator GI1 are processed to form an opening in the regions overlapping with the conductor ME1a, and then the film of the conductor MV1 is formed to fill the opening.

In FIG. 96, for example, a conductor MV2 is embedded in regions of the insulator IS2, the insulator IS3, the insulator IS4, the insulator GI1, and the insulator IS5, which overlap with the conductor ME1b. For example, the conductor MV2 may be formed in the following manner: the insulator IS2, the insulator IS3, the insulator IS4, the insulator GI1, and the insulator IS5 are processed to form an opening in the regions overlapping with the conductor ME1b, and then the conductor MV2 is formed to fill the opening.

Films of the conductor MV1 and the conductor MV2 may be formed at the same time in the film formation step of the conductor ME4. After the film formation of the conductor MV1 and the conductor MV2, the conductor MV1 and the conductor MV2 may be processed at the same time as the processing of the conductor ME4 and the insulator IS5.

The conductor MV1 is electrically connected to the conductor ME2 and the conductor ME3. That is, the wiring SL and the wiring CL in the cell array CA in the memory layer 60_1 are electrically connected to the transistor 300 in the driver circuit layer 50 through the conductor MV1, the conductor ME1a, the conductor 350a, and the conductor 340.

In FIG. 96, an opening, for example, is provided in regions of the insulator IS6 and the insulator GI2, which overlap with the conductor MV2. The conductor ME7 is embedded in the opening.

Thus, the conductor MV2 is electrically connected to the conductor ME7. That is, the wiring WWL in the cell array CA in the memory layer 60_1 is electrically connected to the transistor 300 in the driver circuit layer 50 through the conductor MV2, the conductor ME1b, the conductor 350b, and the conductor 340.

Although not illustrated in FIG. 96, the conductor ME1 (wiring RBL) and the conductor ME6 (wiring WBL) are also electrically connected to the transistor 300 in the driver circuit layer 50 through the contact plug or the wiring.

With the structure illustrated in FIG. 96, the memory layer 60_1 can be provided above the driver circuit layer 50. With the use of a contact plug or a wiring for the memory layer 60_2 to the memory layer 60_N in a similar manner, the memory layer 60_2 to the memory layer 60_N can be provided above the driver circuit layer 50 and the memory layer 60_1.

With the above structure, the memory device including the memory cells MC described in Embodiment 1 and Embodiment 2 can be manufactured.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 5

In this embodiment, a transistor whose channel formation region includes an oxide semiconductor (OS transistor) is described. In the description of the OS transistor, comparison with a transistor whose channel formation region includes silicon (also referred to as Si transistor) is also described briefly.

### [OS Transistor]

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. As examples of the impurity, hydrogen, nitrogen, and the like are given. Note that impurities in an oxide semiconductor refer to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In the OS transistor, a defect that is an oxygen vacancy in the oxide semiconductor into which hydrogen enters (hereinafter sometimes referred to as VoH) may be formed and may generate an electron serving as a carrier. When VoH is formed in the channel formation region, the donor concentration in the channel formation region increases in some cases. As the donor concentration in the channel formation region increases, the threshold voltage might vary. Accordingly, when the channel formation region in the oxide semiconductor includes oxygen vacancies, the transistor tends to have normally-on characteristics (a state where a channel is present and a current flows through the transistor even when no voltage is applied to the gate electrode). Therefore, the impurities, oxygen vacancies, and VoH are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as off leakage current or Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, a short-channel effect does not appear or hardly appears in an OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), an increase in leakage current, and the like. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions in the OS transistor.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for a Si transistor to have a gate length less than or equal to 20 nm or less than or equal to 15 nm because of appearance of a short-channel effect. Therefore, an OS transistor can be suitably used as a transistor having a short channel length as compared with a Si transistor. Note that the gate length refers to the length of a gate electrode in a direction in which carriers move inside a channel formation region during an operation of the transistor and to the width of a bottom surface of the gate electrode in a plan view of the transistor.

Miniaturization of an OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has an effect superior to that of a Si transistor, such as a low off-state current and capability of having a short channel length.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 6

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

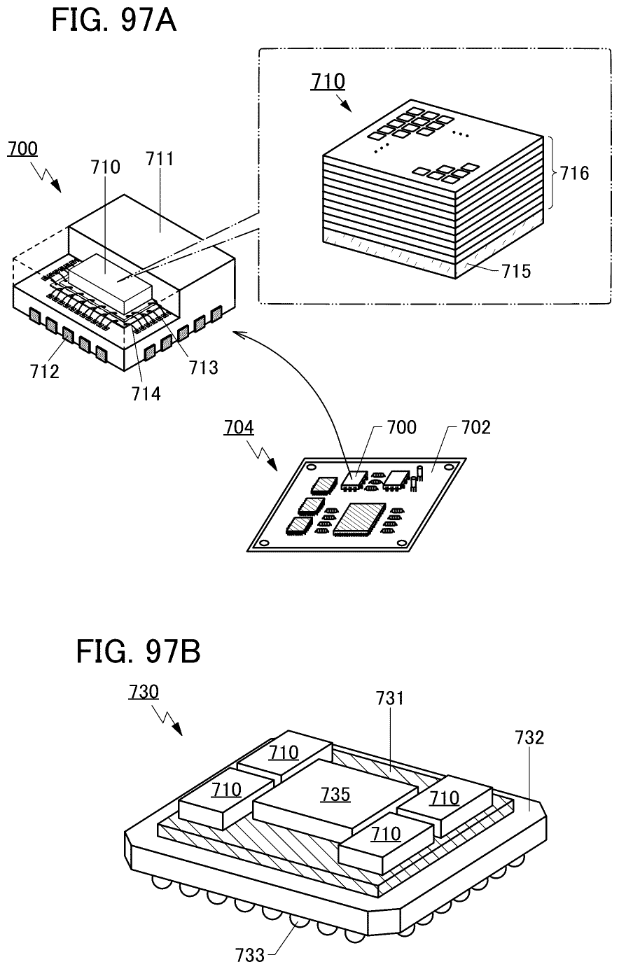

FIG. 97A is a perspective view of a substrate (a circuit board 704) on which an electronic component 700 is mounted. The electronic component 700 illustrated in FIG. 97A includes a semiconductor device 710 in a mold 711. Some components are omitted in FIG. 97A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as TSV (Through Silicon Via), a bonding technique such as Cu-to-Cu direct bonding, or the like. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 97B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer and TSV, a space for the width of the terminal pitches and the like is needed. Thus, in the case where the size of the electronic component 730 is to be reduced, the width of the terminal pitches causes a problem, which sometimes makes it difficult to provide a large number of wirings for achieving a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 97B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

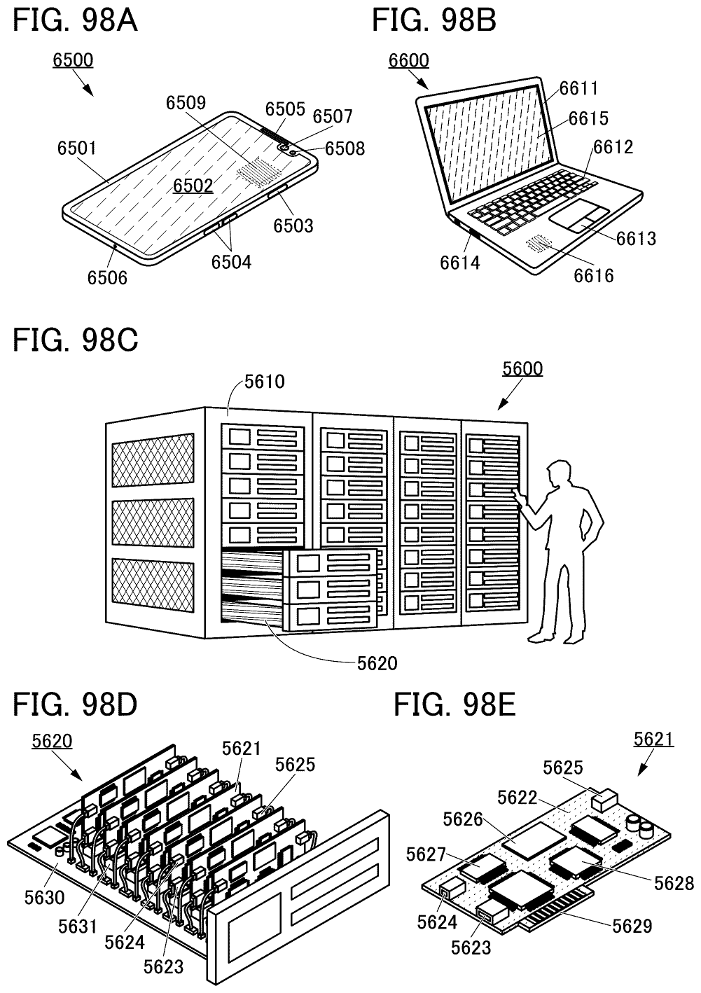

FIG. 98A is a perspective view of an electronic device 6500. The electronic device 6500 illustrated in FIG. 98A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509. One or more selected from a CPU, a GPU, and a memory device are provided as the control device 6509, for example. The semiconductor device of one embodiment of the present invention can be used for the display portion 6502, the control device 6509, and the like.

An electronic device 6600 illustrated in FIG. 98B is an information terminal that can be used as a notebook personal computer. The electronic device 6600 includes a housing 6611, a keyboard 6612, a pointing device 6613, an external connection port 6614, a display portion 6615, and a control device 6616. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616 described above, in which case power consumption can be reduced.

### [Large Computer]

FIG. 98C is a perspective view of a large computer 5600. In the large computer 5600 illustrated in FIG. 98C, a plurality of rack mount computers 5620 are stored in a rack 5610. Note that the large computer 5600 may be referred to as a supercomputer.

The computer 5620 can have a structure in a perspective view of FIG. 98D, for example. In FIG. 98D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 98E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Although FIG. 98E illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment, which is given as an example of equipment for information processing and information storing.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

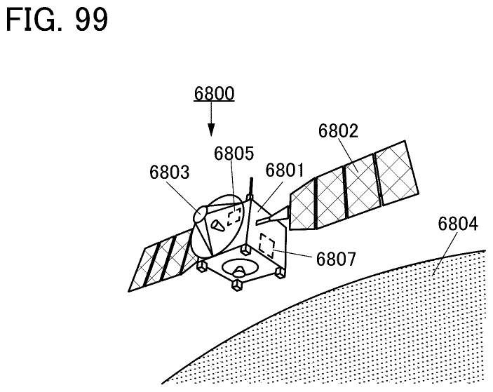

FIG. 99 illustrates an artificial satellite 6800 as an example of space equipment. The artificial satellite 6800 includes a body 6801, a solar panel 6802, an antenna 6803, a secondary battery 6805, and a control device 6807. FIG. 99 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 99, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is illuminated with sunlight, electric power required for an operation of the artificial satellite 6800 is generated. However, for example, in the situation where the solar panel is not illuminated with sunlight or the amount of sunlight with which the solar panel is illuminated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is configured with one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system in a data center, for example. Long-term management of data, such as guarantee of data immutability, is required for the data center. The management of long-term data needs an increase in building size owing to installation of storages and servers for storing an enormous amount of data, stable electric power for data retention, cooling equipment necessary for data retention, and the like.

With the use of the semiconductor device of one embodiment of the present invention for the storage system used in the data center, electric power required for data retention can be reduced and the size of a semiconductor device retaining data can be downsized. Thus, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high-temperature environment. Thus, the reliability of the data center can be increased.

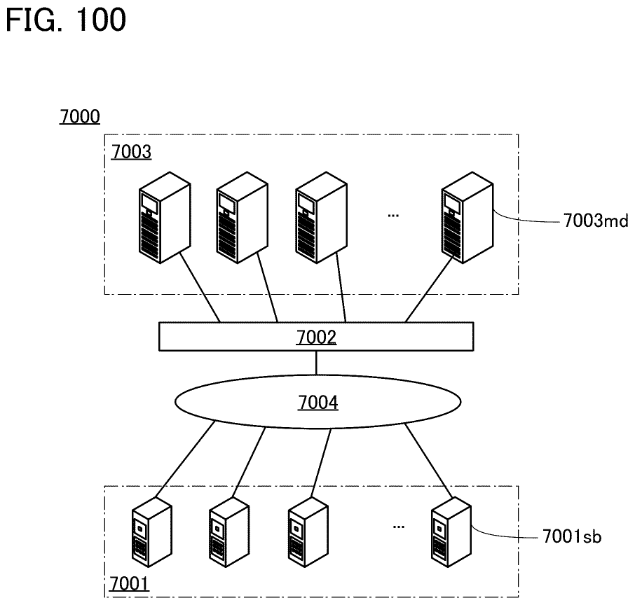

FIG. 100 illustrates a storage system that can be used in a data center. A storage system 7000 illustrated in FIG. 100 includes a plurality of servers 7001sb as a host 7001. The storage system 7000 includes a plurality of memory devices 7003md as a storage 7003). In the illustrated mode, the host 7001 and the storage 7003 are connected to each other through a storage area network 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM (Dynamic Random Access Memory) that can be used as a cache memory in a storage. In the storage system, in order to solve the problem of low access speed of the storage 7003, a cache memory is usually provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. Although demand for energy will increase with increasing performance and integration degree of semiconductor devices, the use of the semiconductor device of one embodiment of the present invention can thus lead to a reduction of the emission amount of greenhouse gas typified by carbon dioxide (CO₂). The semiconductor device of one embodiment of the present invention can be effectively used as one of the global warming countermeasures because of its low power consumption.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 7

In this embodiment, a structure example of a display apparatus for which the stacked-layer structure described in the above embodiment is used and an electronic device including the display apparatus will be described.

### <Structure Example of Display Apparatus>

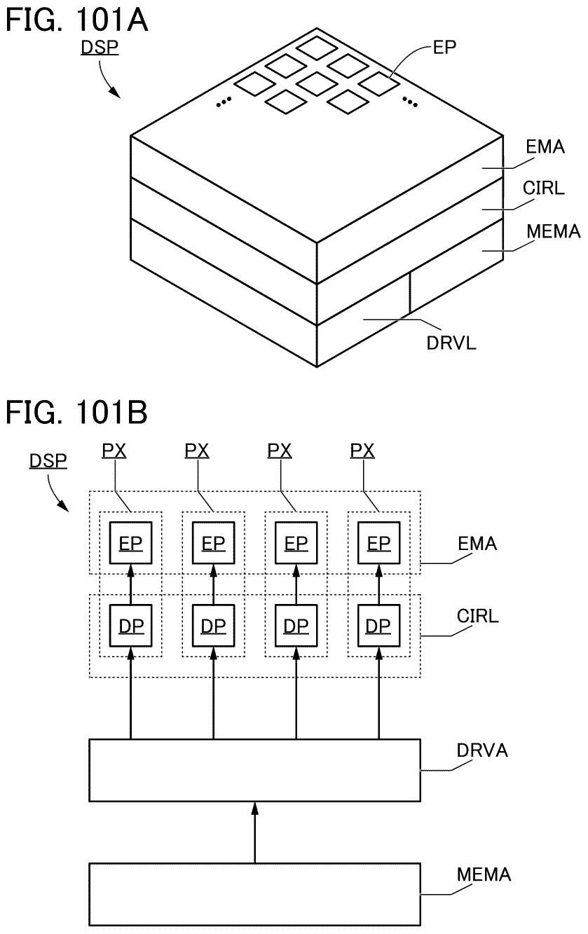

FIG. 101A is a schematic perspective view illustrating a structure example of the display apparatus DSP employing the stacked-layer structure, and FIG. 101B is a block diagram of the display apparatus DSP.

The display apparatus DSP includes a memory circuit region MEMA, a driver circuit region DRVA, the circuit layer CIRL, and a display region EMA. Note that the memory circuit region MEMA and the driver circuit region DRVA are positioned below the circuit layer CIRL, and the display region EMA is positioned above the circuit layer CIRL. That is, in the display apparatus DSP, the memory circuit region MEMA, the driver circuit region DRVA, the circuit layer CIRL, and the display region EMA are stacked in this order from the bottom.

The memory circuit region MEMA has a function of retaining image data for displaying an image on the display region EMA, for example. The memory circuit region MEMA may include a DRAM, an SRAM, an FeRAM, a ReRAM, an MRAM, or a PRAM, for example. In FIG. 101B, the memory circuit region MEMA includes a plurality of memory cells that store image data that is digital data, and each of the plurality of memory cells transmits one-bit or multi-bit data to the circuit layer CIRL, for example.

For example, the memory circuit region MEMA has a function of reading image data from the memory cells included in the memory circuit region MEMA and transmitting the image data to the driver circuit region DRVA described later. Note that the data that can be processed by the memory cell may be data less than 8 bits, such as 1-bit data, 2-bit data, or 4-bit data, for example. Data more than 8 bits, such as 8-bit, 16-bit, 32-bit, 64-bit, 128-bit, or 256-bit data, may be processed, for example.

The driver circuit region DRVA includes a shift register and a plurality of digital-analog converter circuits, for example. The shift register has a function of sequentially distributing and transmitting image data, which is sent from the memory circuit region MEMA, to each row or each column in the display region EMA. The digital-analog converter circuits have a function of converting the image data, which is digital data read from the memory cells included in the memory circuit region MEMA, into analog data. The driver circuit region DRVA has a function of transmitting the converted analog data to the circuit layer CIRL.

The display region EMA includes, for example, a plurality of light-emitting portions EP. In particular, the light-emitting portions EP are preferably arranged in an array in the display region EMA. Note that the light-emitting portion EP includes a light-emitting device, for example. Examples of the light-emitting device include a light-emitting device including an organic EL element (OLED (Organic Light Emitting Diode)), an inorganic EL element, an LED (including a micro LED), a QLED (Quantum-dot Light Emitting Diode), and a semiconductor laser. Note that in the description in this embodiment, a light-emitting device including organic EL is used for the light-emitting portion EP. In particular, the luminance of light emitted from a light-emitting device capable of high luminance light emission can be, for example, higher than or equal to 500 cd/m², preferably higher than or equal to 1000 cd/m² and lower than or equal to 10000 cd/m², further preferably higher than or equal to 2000 cd/m² and lower than or equal to 5000 cd/m².

Alternatively, the display region EMA may include a liquid crystal display device (including a transmissive liquid crystal device or a reflective liquid crystal device, for example). Alternatively, the display region EMA may include a display device using an electrophoretic element or an Electronic Liquid Powder (registered trademark) or an electrowetting display device, for example.

The circuit layer CIRL includes a plurality of driver portions DP, for example. One of the plurality of driver portions DP has a function of driving a light-emitting device included in the corresponding light-emitting portion EP.

The driver portion DP retains the image data transmitted from the driver circuit region DRVA and transmits current corresponding to the image data to the light-emitting portion EP, for example. Accordingly, the light-emitting device included in the light-emitting portion EP is capable of emitting light with luminance corresponding to the current.

By constituting the display apparatus DSP in the above manner, the display apparatus DSP can select image data retained in each of the plurality of memory cells in the memory circuit region MEMA and display the selected image data on one of the plurality of pixel circuits PX in the display region EMA.

Next, a configuration example of the pixel PX is described.

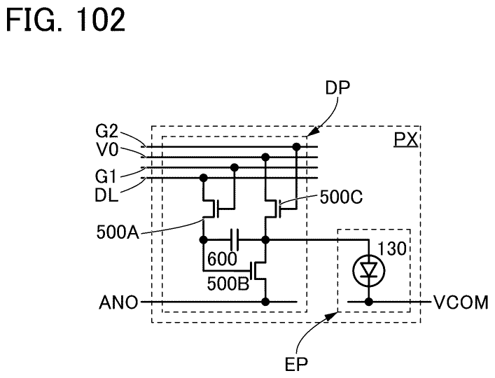

A structure example of the light-emitting portion EP and the driving portion DP that can be included in the pixel circuit PX is illustrated in FIG. 102. FIG. 102 is a diagram illustrating connection of circuit elements included in the pixel circuit PX.

The driving portion DP includes the transistor 500A, a transistor 500B, a transistor 500C, and the capacitor 600. Note that as each of the transistor 500A, the transistor 500B, and the transistor 500C, for example, the transistor that can be used as the transistor MW or the transistor MR described in Embodiment 1 can be used. In particular, each of the transistor 500A, the transistor 500B, and the transistor 500C is preferably an OS transistor.

Although the back gate electrodes of the transistor 500A, the transistor 500B, and the transistor 500C are not illustrated in FIG. 102, a structure may be employed in which the back gate electrodes may be provided in the transistors and the back gate electrode and the gate electrode of each transistor may be supplied with the same or different signals.

The transistor 500B includes a gate electrode electrically connected to the transistor 500A, a first electrode electrically connected to the light-emitting device 130, and a second electrode electrically connected to a wiring ANO. The wiring ANO is a wiring for supplying a potential for supplying current to the light-emitting device 130.

The transistor 500A includes a first terminal electrically connected to the gate electrode of the transistor 500B, a second terminal electrically connected to the wiring DL functioning as a source line, and a gate electrode having a function of controlling switching of the on state and the off state on the basis of the potential of a wiring G1 functioning as a gate line.

Since the wiring DL functions as a source line in the pixel circuit PX, the image data transmitted to the wiring DL is image data output from the circuit layer CIRL.

The transistor 500C includes a first terminal electrically connected to a wiring V0, a second terminal electrically connected to the light-emitting device 130, and a gate electrode having a function of controlling switching of the on state and the off state on the basis of the potential of a wiring G2 functioning as a gate line. The wiring V0 has a function as a wiring for supplying a reference potential and a function as a wiring for outputting current flowing through the driver portion DP to the driver circuit region DRVA.

The capacitor 600 includes a conductive film electrically connected to the gate electrode of the transistor 500B and a conductive film electrically connected to a second electrode of the transistor 500C.

The light-emitting device 130 included in the light-emitting portion EP includes a first electrode electrically connected to the first electrode of the transistor 500B and a second electrode electrically connected to a wiring VCOM. The wiring VCOM is a wiring for supplying a potential for supplying current to the light-emitting device 130.

Accordingly, the intensity of light emitted from the light-emitting device 130 can be controlled in accordance with an image signal supplied to the gate electrode of the transistor 500B. Furthermore, variations in the gate-source voltage of the transistor 500B can be inhibited by the reference potential of the wiring V0 supplied through the transistor 500C.

A current value that can be used for setting of pixel parameters can be output from the wiring V0. Specifically, the wiring V0 can function as a monitor line for outputting a current flowing through the transistor 500B or a current flowing through the light-emitting device 130 to the outside. A current output to the wiring V0 is converted into a voltage by, for example, a source follower circuit and is output to the outside. Alternatively, for example, a current output to the wiring V0 can be converted to a digital signal by an analog-digital converter circuit and output to a circuit for performing dimming and toning processing. Note that the above-described source follower circuit, analog-digital converter circuit, and circuit for performing dimming and toning processing may be included in the driver circuit region DRVA, for example.

Some of the circuit elements included in the driver portion DP can be the circuit element included in the memory cell MC illustrated in FIG. 1A and FIG. 2A to FIG. 2C described in Embodiment 1. For example, the transistor 500A can be the transistor MW illustrated in FIG. 1A and FIG. 2A to FIG. 2C, the transistor 500B can be the transistor MR illustrated in FIG. 1A and FIG. 2A to FIG. 2C, and the capacitor 600 can be the transistor C1 illustrated in FIG. 1A and FIG. 2A to FIG. 2C. The wiring DL can be the wiring WBL illustrated in FIG. 1A and FIG. 2A to FIG. 2C, the wiring G1 can be the wiring WWL illustrated in FIG. 1A and FIG. 2A to FIG. 2C, and the wiring ANO can be the wiring RBL illustrated in FIG. 1A and FIG. 2A to FIG. 2C. The wiring SL and the wiring CL illustrated in FIG. 1A and FIG. 2A to FIG. 2C are wirings connected to the first electrode of the light-emitting device 130 or the second electrode of the transistor 500C in FIG. 102. That is, the memory cell MC illustrated in FIG. 1A and FIG. 2A to FIG. 2C can be used as part of the driving portion DP described in this embodiment.

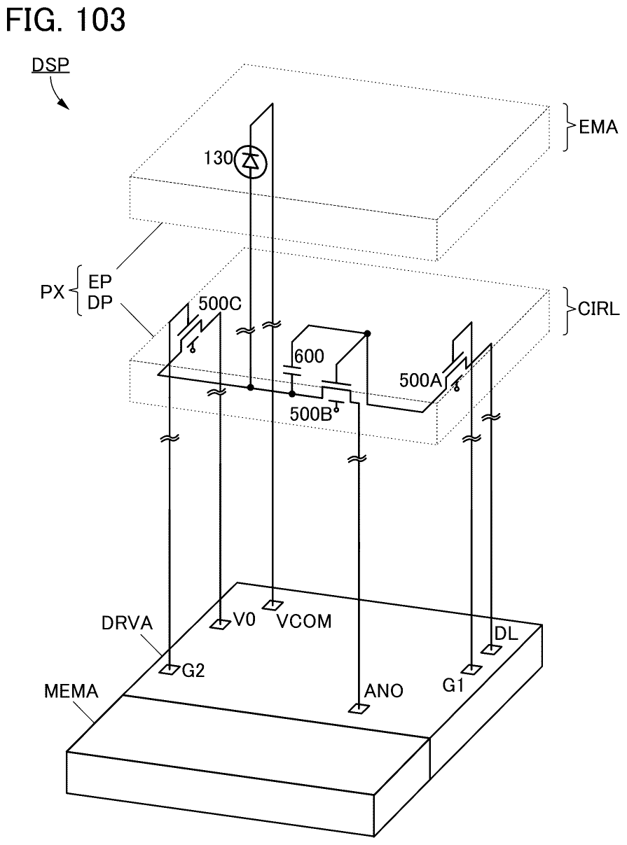

FIG. 103 schematically illustrates the vertical relation between the driver circuit region DRVA, the memory circuit region MEMA, the circuit layer CIRL, the driving portion DP including the plurality of transistors and the light-emitting portion EP including the light-emitting device 130 which are included in the pixel circuit PX. In the display apparatus DSP illustrated in FIG. 103, for example, the display region EMA includes the light-emitting portion EP and the circuit layer CIRL includes the driver portion DP.

In the structure illustrated as an example in FIG. 103, the wirings electrically connecting the driver portion DP and the driver circuit region DRVA can be shortened, so that wiring resistance of the wirings can be reduced. Thus, data can be written at high speed, which enables high-speed driving of the display apparatus DSP. Therefore, even when the number of pixel circuits PX included in the display apparatus DSP is large, a sufficiently long frame period can be ensured and thus the pixel density of the display apparatus DSP can be increased. In addition, the increased pixel density of the display apparatus DSP can increase the resolution of an image displayed by the display apparatus DSP. For example, the pixel density of the display apparatus DSP can be greater than or equal to 500 ppi, preferably greater than or equal to 1000 ppi, further preferably greater than or equal to 3000 ppi, still further preferably greater than or equal to 5000 ppi, still further preferably greater than or equal to 6000 ppi. Thus, the display apparatus DSP can be, for example, a display apparatus for XR (Extended Reality or Cross Reality) such as AR (augmented reality) or VR (virtual reality), and suitably used in an electronic device with a short distance between a user and a display portion such as an HMD (head-mounted display).

### <Structure Example of Electronic Device>

Next, examples of electronic devices in which the above-described display apparatus DSP can be used are described.

The electronic device includes the display apparatus and one or more selected from an antenna, a battery, a housing, a camera, a speaker, a microphone, a touch sensor, and an operation button, for example.

The electronic device may include a secondary battery, and it is preferable that the secondary battery be capable of being charged by contactless power transmission.

Examples of the secondary battery include a lithium ion secondary battery (e.g., a lithium polymer battery using a gel electrolyte (lithium ion polymer battery)), a nickel-hydride battery, a nickel-cadmium battery, an organic radical battery, a lead-acid battery, an air secondary battery, a nickel-zinc battery, or a silver-zinc battery.

The electronic device may include an antenna. When a signal is received by the antenna, the electronic device can display a video, data, or the like on a display portion. When the electronic device includes the antenna and a secondary battery, the antenna may be used for contactless power transmission.

A display region in an electronic device can display a video with a definition of, for example, full high definition, 4K2K, 8K4K, 16K8K, or higher.

Examples of the electronic devices include electronic devices with relatively large screens, such as a television device, a laptop personal computer, a monitor device, digital signage, a pachinko machine, and a game machine. Examples of the electronic devices further include a digital camera, a digital video camera, a digital photo frame, a mobile phone, a portable game machine, a portable information terminal, and an audio reproducing device.

The electronic device can be incorporated along a flat surface or a curved surface of an inside wall or an outside wall of a house or a building. The electronic device can be incorporated along a flat surface or a curved surface of an interior or an exterior of a car or the like.

### [Mobile Phone]

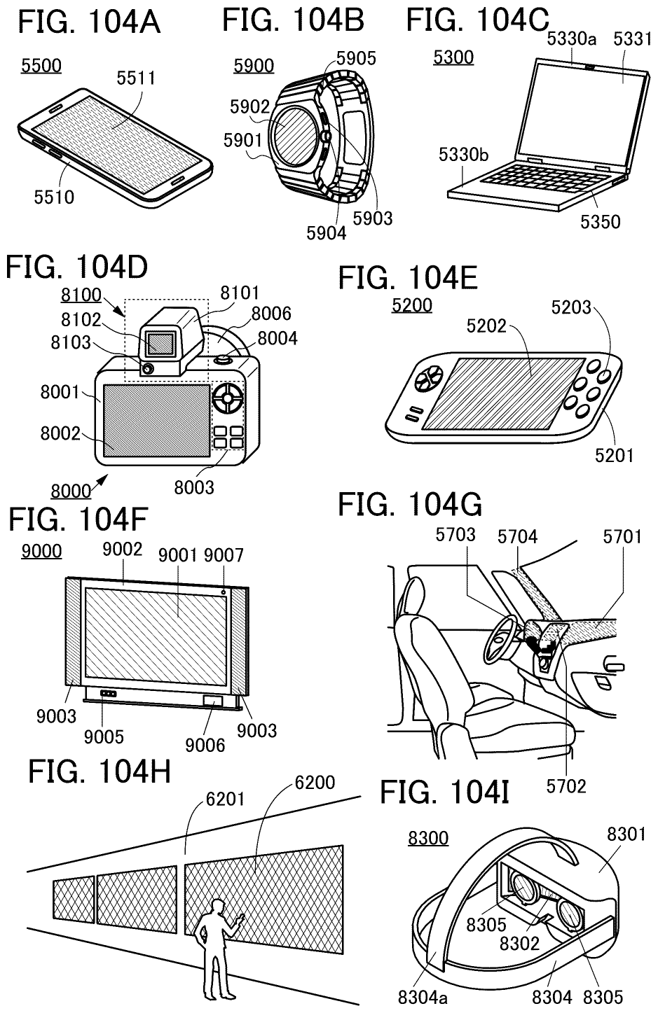

An information terminal 5500 illustrated in FIG. 104A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

### [Wearable Terminal]

FIG. 104B is an external view of an information terminal 5900 that is an example of a wearable terminal. The information terminal 5900 includes a housing 5901, a display portion 5902, an operation button 5903, a crown 5904, and a band 5905.

### [Information Terminal]

FIG. 104C illustrates a laptop information terminal 5300. The laptop information terminal 5300 illustrated in FIG. 104C includes, for example, a display portion 5331 in a housing 5330a and a keyboard portion 5350 in a housing 5330b.

Although the smartphone, the wearable terminal, and the laptop information terminal are respectively illustrated in FIG. 104A to FIG. 104C as examples of the electronic devices, one embodiment of the present invention can be used for information terminals other than a smartphone, a wearable terminal, and a laptop information terminal. Examples of information terminals other than a smartphone, a wearable terminal, and a laptop information terminal include a PDA (Personal Digital Assistant), a desktop information terminal, and a workstation.

### [Camera]

FIG. 104D is an external view of a camera 8000 to which a finder 8100 is attached. The camera 8000 includes a housing 8001, a display portion 8002, operation buttons 8003, and a shutter button 8004. In addition, a detachable lens 8006 is attached to the camera 8000. The finder 8100 includes a housing 8101, a display portion 8102, and a button 8103.

Note that the lens 8006 and the housing may be integrated with each other in the camera 8000.

The camera 8000 can take images by the press of the shutter button 8004 or touch on the display portion 8002 functioning as a touch panel.

The housing 8001 includes a mount including an electrode, so that, in addition to the finder 8100, for example, a stroboscope can be connected to the housing.

The housing 8101 is attached to the camera 8000 with the mount engaging with a mount of the camera 8000. In the finder 8100, a video received from the camera 8000 can be displayed on the display portion 8102.

The button 8103 has a function of a power button.

The display apparatus of one embodiment of the present invention can be used for the display portion 8002 of the camera 8000 and the display portion 8102 of the finder 8100. Note that a finder may be incorporated in the camera 8000.

### [Game Machine]

FIG. 104E is an external view of a portable game machine 5200 which is an example of a game machine. The portable game machine 5200 includes a housing 5201, a display portion 5202, and a button 5203.

Videos displayed on the portable game machine 5200 can be output with a display apparatus provided in a television device, a personal computer display, a game display, or a head-mounted display.

The portable game machine 5200 with low power consumption can be provided by applying the display apparatus described in the above embodiment to the portable game machine 5200. Moreover, heat generation from a circuit can be reduced owing to low power consumption; thus, the influence of heat generation on the circuit itself, a peripheral circuit, and a module can be reduced.

Although FIG. 104E illustrates the portable game machine as an example of a game machine, the electronic device of one embodiment of the present invention is not limited thereto. Examples of the electronic device of one embodiment of the present invention include a stationary game machine, an arcade game machine installed in entertainment facilities (e.g., a game center and an amusement park), and a throwing machine for batting practice installed in sports facilities.

### [Television Device]

FIG. 104F is a perspective view illustrating a television device. A television device 9000 includes a housing 9002, a display portion 9001, speakers 9003, an operation key 9005 (e.g., including a power switch or an operation switch), a connection terminal 9006, and a sensor 9007 (e.g., a sensor having a function of measuring force, displacement, a position, speed, acceleration, angular velocity, rotational frequency, distance, light (e.g., visible or invisible light rays), liquid, magnetism, temperature, a chemical substance, sound, time, hardness, an electric field, current, voltage, power, radiation, a flow rate, humidity, gradient, oscillation, or an odor. Alternatively, a smell or light (including infrared rays), for example). The storage device of one embodiment of the present invention can be provided in the television device. The television device can include the display portion 9001 of, for example, 50 inches or more or 100 inches or more.

The television device 9000 with low power consumption can be provided by applying the display apparatus described in the above embodiment to the television device 9000. Moreover, heat generation from a circuit can be reduced owing to low power consumption; thus, the influence of heat generation on the circuit itself, a peripheral circuit, and a module can be reduced.

### [Moving Vehicle]

The display apparatus of one embodiment of the present invention can be used around a driver's seat in a car, which is a moving vehicle.

FIG. 104G is a diagram illustrating an area around a windshield inside a car. FIG. 104G illustrates a display panel 5701, a display panel 5702, and a display panel 5703 that are attached to a dashboard and a display panel 5704 that is attached to a pillar.

The display panel 5701 to the display panel 5703 is capable of displaying one or more selected from navigation information, a speedometer, a tachometer, a mileage, a fuel meter, a gearshift indicator, and air-condition settings. The display content and layout displayed on the display panels can be changed appropriately to suit the user's preferences, so that the design can be improved. The display panel 5701 to the display panel 5703 can also be used as lighting devices.

The display panel 5704 can compensate for the view obstructed by the pillar (blind areas) by showing a video taken by an imaging unit provided for the car body. That is, showing an image taken by an imaging unit provided on the outside of the car body leads to elimination of blind areas and enhancement of safety. Display of a video that complements for a portion that cannot be seen makes it possible to confirm safety more naturally and comfortably. The display panel 5704 can also be used as a lighting device.

The display apparatus of one embodiment of the present invention can be used for the display panel 5701 to the display panel 5704, for example.

Although a car is described above as an example of a moving vehicle, the moving vehicle is not limited to a car. Examples of moving vehicles include a train, a monorail train, a ship, and a flying object (e.g., a helicopter, an unmanned aircraft (a drone), an airplane, and a rocket), and these moving vehicles can include the display apparatus of one embodiment of the present invention.

### [Digital Signage]

FIG. 104H illustrates an example of digital signage that can be attached to a wall. FIG. 104H illustrates a state where digital signage 6200 is attached to a wall 6201. The display apparatus of one embodiment of the present invention can be used in a display portion of the digital signage 6200, for example. An interface such as a touch panel may be provided in the digital signage 6200, for example.

Although the electronic device attachable to a wall is described above as an example of digital signage, the kind of digital signage is not limited thereto. Examples of the digital signage include digital signage attached to a pillar, freestanding digital signage placed on the ground, and digital signage mounted on a rooftop or a side wall of a building.

### [Head-Mounted Display]

FIG. 104I is a diagram illustrating the appearance of an electronic device 8300 that is a head-mounted display. The electronic device 8300 includes a housing 8301, a display portion 8302, a band-shaped fixture member 8304, a fixture member 8304a worn on a head, and a pair of lenses 8305.

Although not illustrated in FIG. 104I, the electronic device 8300 may include an interface such as an operation button or a power button.

A user can perceive display on the display portion 8302 through the lenses 8305. Note that the display portion 8302 is preferably placed in the curved state, in which case the user can feel a high realistic sensation. Another image displayed on another region of the display portion 8302 is seen through the lenses 8305, so that three-dimensional display using parallax can be performed. Note that the structure is not limited to the structure where one display portion 8302 is provided; two display portions 8302 may be provided and one display portion may be provided per eye of the user.

For the display portion 8302, a display apparatus with an extremely high resolution is preferably used, for example. When a high-resolution display apparatus is used for the display portion 8302, it is possible to display a more realistic video that does not allow the user to perceive pixels even when the displayed image is magnified using the lenses 8305.

The head-mounted display, which is an electronic device, may be an electronic device which is a glasses-type head-mounted display, instead of the electronic device 8300 in FIG. 104I, which is a goggle-type head-mounted display.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### REFERENCE NUMERALS

MC: memory cell, MCA: memory cell, MCB: memory cell, MW: transistor, MR: transistor, MD: transistor, C1: capacitor, FN: node, WWL: wiring, WBL: wiring, CL: wiring, SL: wiring, RBL: wiring, WL: wiring, T01: Time, T02: Time, T03: Time, T04: Time, T05: Time, T06: Time, T07: Time, L1: layer, L2: layer, ME1: conductor, ME1A: conductive film, MS1: conductor, ME2: conductor, ME2B: conductive film, ME2S: conductor, ME3: conductor, ME3A: conductive film, ME4: conductor, ME4A: conductive film, ME4B: conductive film, ME4S: conductor, ME5: conductor, MESA: conductive film, ME6: conductor, ME6A: conductive film, ME6B: conductive film, ME6C: conductive film, ME6S: conductor, ME7: conductor, ME7A: conductive film, ME7S: conductor, ME8: conductor, MEP: conductor, MEQ: conductor, MT3: conductor, MT3B: conductive film, MB3: conductor, MB3B: conductive film, IS1: insulator, IS2: insulator, IS2A: insulating film, IS3: insulator, IS3A: insulating film, IS4: insulator, IS4A: insulating film, IS4B: insulating film, IS5: insulator, IS5A: insulating film, IS6: insulator, IS6A: insulating film, IS6B: insulating film, IS7: insulator, IS8: insulator, ISP: insulator, IB1: insulator, IB3: insulator, IB5: insulator, GI1: insulator, GI2: insulator, SC1: semiconductor, SC1A: semiconductor film, SC2: semiconductor, SC2A: semiconductor film, KK1: opening, KK2: opening, KK3: opening, MDV: memory device, MDVA: memory device, MDVB: memory device, WBD: circuit, WWD: circuit, CSD: circuit, CSE: circuit, RBD: circuit, WD: circuit, BD: circuit, CA: cell array, PON1: signal, PON2: signal, ADDR: signal, BW: signal, CE: signal, GW: signal, CLK: signal, WAKE: signal, WDA: signal, RDA: signal, BL: wiring, DSP: display apparatus, CIRL: circuit layer, EMA: display region, DRVA: driver circuit region, MEMA: memory circuit region, PX: pixel circuit, EP: light-emitting portion, DP: driver portion, G1: wiring, G2: wiring, DL: wiring, ANO: wiring, VCOM: wiring, V0: wiring, 10: memory cell, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 60: memory layer, 60_1: memory layer, 60_2: memory layer, 60_3: memory layer, 60_k: memory layer, 60_N: memory layer, 100: memory device, 130: light-emitting device, 300: transistor, 301: substrate, 312: element isolation layer, 313: semiconductor region, 314a: low-resistance region, 314b: low-resistance region, 315: insulator, 316: conductor, 317: insulator, 320: insulator, 321: insulator, 324: insulator, 326: insulator, 328: conductor, 330: conductor, 334: insulator, 336: insulator, 338: insulator, 340: conductor, 350a: conductor, 350b: conductor, 500A: transistor, 500B: transistor, 500C: transistor, 600: capacitor, 710: semiconductor device, 715: driver circuit layer, 716: memory layer, 735: semiconductor device, 5200: portable game machine, 5201: housing, 5202: display portion, 5203: button, 5300: notebook information terminal, 5330a: housing, 5330b: housing, 5331: display portion, 5350: keyboard portion, 5500: information terminal, 5510: housing, 5511: display portion, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5900: information terminal, 5901: housing, 5902: display portion, 5903: operation button, 5904: crown, 5905: band, 6200: digital signage, 6201: wall, 6500: electronic device, 6501: housing, 6502: display portion, 6503: power supply button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6805: secondary battery, 6807: control device, 7000: storage system, 7001: host, 7001sb: server, 7002: storage control circuit, 7003: storage, 7003md: storage device, 7004: storage area network, 8000: camera, 8001: housing, 8002: display portion, 8003: operation button, 8004: shutter button, 8006: lens, 8100: finder, 8101: housing, 8102: display portion, 8103: button, 8300: electronic device, 8301: housing, 8302: display portion, 8304: fixture member, 8304a: fixture member, 8305: lens, 9000: television device, 9001: display portion, 9002: housing, 9003: speaker, 9006: connection terminal, 9007: sensor

1. A semiconductor device comprising:
a first layer comprising a first opening and a second layer comprising a second opening,
wherein the second layer is positioned above the first layer,
wherein the first layer comprises a first conductor, a second conductor, a third conductor, a fourth conductor, a first insulator, a second insulator, a third insulator, a fourth insulator, a fifth insulator, and a first semiconductor,
wherein the second layer comprises a fifth conductor, a sixth conductor, a seventh conductor, a sixth insulator, a seventh insulator, and a second semiconductor,
wherein the first opening is positioned above the first conductor,
wherein the first insulator is positioned on a top surface of the first conductor and an outer side surface of the first opening,
wherein the second conductor is positioned on a top surface of the first insulator and an outer side surface of the first opening,
wherein the second insulator is positioned on a top surface of the second conductor and an outer side surface of the first opening,
wherein the third conductor is positioned on a top surface of the second insulator and an outer side surface of the first opening,
wherein the third insulator is positioned on a top surface of the second insulator and a side surface of the third conductor,
wherein the first semiconductor is positioned on a top surface of the first conductor, a side surface of the first insulator, a side surface of the second conductor, a side surface of the second insulator, and a side surface of the third conductor in an inner part of the first opening,
wherein the fourth insulator is positioned on a top surface of the third insulator, a top surface of the third conductor, and a top surface of the first semiconductor,
wherein the fourth conductor is positioned on a top surface of the fourth insulator and is in the inner part of the first opening and above the first opening,
wherein the fifth insulator is positioned above the fourth insulator and on a side surface of the fourth conductor,
wherein the fifth conductor is positioned on a top surface of the fourth conductor and a top surface of the fifth insulator,
wherein the second opening is positioned above the fifth conductor,
wherein the sixth insulator is positioned on a top surface of the fifth insulator, a top surface of the fifth conductor, and an outer side surface of the second opening,
wherein the sixth conductor is positioned on a top surface of the sixth insulator and an outer side surface of the second opening,
wherein the second semiconductor is positioned on a top surface of the fifth conductor, a side surface of the sixth insulator, and a side surface of the sixth conductor in an inner part of the second opening,
wherein the second semiconductor is positioned on a top surface of the sixth conductor in an outer part of the second opening,
wherein the seventh insulator is positioned on a top surface of the sixth insulator, a top surface of the sixth conductor, and a top surface of the second semiconductor, and
wherein the seventh conductor is positioned on a top surface of the seventh insulator and the top surface is partly in the inner part of the second opening.

2. The semiconductor device according to claim 1,
wherein the first semiconductor and the second semiconductor each comprise one or more selected from indium, zinc, and an element M, and
wherein the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.

3. The semiconductor device according to claim 2,
wherein a taper angle of a side surface of the second opening is greater than or equal to 45° and less than or equal to 90°.

4. The semiconductor device according to claim 3,
wherein the first conductor and the sixth conductor extend in a first direction, and
wherein the second conductor, the third conductor, and the seventh conductor extend in a second direction.

5. A semiconductor device comprising:
a first layer comprising a first opening and a second layer comprising a second opening,
wherein the second layer is positioned above the first layer,
wherein the first layer comprises a first conductor, a second conductor, a third conductor, a fourth conductor, a first insulator, a second insulator, a third insulator, a fourth insulator, a fifth insulator, and a first semiconductor,
wherein the second layer comprises a sixth conductor, a seventh conductor, a sixth insulator, a seventh insulator, and a second semiconductor,
wherein the first opening is positioned above the first conductor,
wherein the first insulator is positioned on a top surface of the first conductor and an outer side surface of the first opening,
wherein the second conductor is positioned on a top surface of the first insulator and an outer side surface of the first opening,
wherein the second insulator is positioned on a top surface of the second conductor and an outer side surface of the first opening,
wherein the third conductor is positioned on a top surface of the second insulator and an outer side surface of the first opening,
wherein the third insulator is positioned on a top surface of the second insulator and a side surface of the third conductor,
wherein the first semiconductor is positioned on a top surface of the first conductor, a side surface of the first insulator, a side surface of the second conductor, a side surface of the second insulator, and a side surface of the third conductor in an inner part of the first opening,
wherein the fourth insulator is positioned on a top surface of the third insulator, a top surface of the third conductor, and a top surface of the first semiconductor,
wherein the fourth conductor is positioned on a top surface of the fourth insulator and is in the inner part of the first opening and above the first opening,
wherein the fifth insulator is positioned above the fourth insulator and on a side surface of the fourth conductor,
wherein the second opening is positioned above the fourth conductor,
wherein the sixth insulator is positioned on a top surface of the fifth insulator, a top surface of the fourth conductor, and an outer side surface of the second opening,
wherein the sixth conductor is positioned on a top surface of the sixth insulator and an outer side surface of the second opening,
wherein the second semiconductor is positioned on a top surface of the fourth conductor, a side surface of the sixth insulator, and a side surface of the sixth conductor in an inner part of the second opening,
wherein the second semiconductor is positioned on a top surface of the sixth conductor in an outer part of the second opening,
wherein the seventh insulator is positioned on a top surface of the sixth insulator, a top surface of the sixth conductor, and a top surface of the second semiconductor, and
wherein the seventh conductor is positioned on a top surface of the seventh insulator and the top surface is partly in the inner part of the second opening.

6. The semiconductor device according to claim 5,
wherein the first semiconductor and the second semiconductor each comprise one or more selected from indium, zinc, and an element M, and
wherein the element M is one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

7. The semiconductor device according to claim 6,
wherein a taper angle of a side surface of the second opening is greater than or equal to 45° and less than or equal to 90°.

8. The semiconductor device according to claim 7,
wherein the first conductor and the sixth conductor extend in a first direction, and
wherein the second conductor, the third conductor, and the seventh conductor extend in a second direction.

9. A memory device comprising the semiconductor device according to claim 1 and a driver circuit,
wherein the driver circuit is positioned below the semiconductor device,
wherein the driver circuit is formed on a semiconductor substrate comprising silicon, and
wherein the driver circuit comprises a transistor comprising the silicon in a channel formation region.

10. An electronic device comprising the memory device according to claim 9 and a housing.

11. A memory device comprising the semiconductor device according to claim 5 and a driver circuit,
wherein the driver circuit is positioned below the semiconductor device,
wherein the driver circuit is formed on a semiconductor substrate comprising silicon, and
wherein the driver circuit comprises a transistor comprising the silicon in a channel formation region.

12. An electronic device comprising the memory device according to claim 11 and a housing.
